(19) United States
(12) Patent Application Publication
(10) Pub. No.: US 2019/0157599 A1
(43) Pub. Date: May 23, 2019

(54) THIN FILM AND ORGANIC ELECTROLUMINESCENT ELEMENT

(71) Applicant: KONICA MINOLTA, INC., Chiyoda-ku Tokyo (JP)

(72) Inventors: Yuta NAKAMURA, Hino-shi, Tokyo (JP); Satoru INOUE, Kunitachi-shi, Tokyo (JP); Masato NISHIZEKI, Hachioji-shi, Tokyo (JP)

(21) Appl. No.: 16/068,808

(22) PCT Filed: Nov. 22, 2016
(86) PCT No.: PCT/JP2016/084664

§ 371 Date: Jul. 9, 2018

(30) Foreign Application Priority Data
Jan. 8, 2016 (JP) 2016-002899

(51) Int. Cl. H01L 51/50; C09K 11/06; C07F 15/00

(52) U.S. Cl. CPC H01L 51/5016; C09K 11/06; C07F 15/00; H01L 51/5092; H01L 51/5072; H01L 51/5036; H01L 51/5004; H01L 51/506

(57) ABSTRACT

The objective of the invention is to provide a thin film having a long light-emitting life span, and an organic electroluminescence element. The above problem is solved by the thin film containing a light-emitting metallic complex and a host, the light-emitting metallic complex being represented by general formula (1) and satisfying formula (1), and the host being: a nonmetallic organic compound demonstrating phosphorescent light-emission at room temperature; a compound demonstrating heat activated-type delayed fluorescence; or a compound exhibiting an inverse intersystem crossing phenomenon between a singlet excitation state demonstrating a level higher than the lowest singlet excitation state, and a triplet excitation state demonstrating a level higher than the lowest triplet excitation state.

### FIELD OF INVENTION

The present invention relates to a thin film and an organic electroluminescent element.

### BACKGROUND ART

A light-emitting thin film used for an organic electronic device represented by an organic electroluminescent element (hereinafter, appropriately refer to as an “organic EL element”) contains at least two kinds of compounds, that is, a dopant and a host.

As a dopant, usually used is a metal complex containing a heavy atom such as Ir, Ru, and Pt. The reason is that such a metal complex can conduct spin inversion by a heavy atom effect, while the spin inversion is originally forbidden from a singlet excited state to a triplet excited state, principally allowing realization of the maximum 100% of internal quantum efficiency.

In contrast, a host mainly plays the following two roles, and is selected or designed in consideration of these roles.

The first role is to efficiently transport a carrier from a host to a dopant. This role is important for an increase in a recoupling probability of a carrier on the dopant, that is, an increase in a formation probability of an exciton on the dopant when an organic EL element or the like is driven in an electric field.

The second role is to efficiently transfer energy of the exciton from the host to the dopant. This role is to transport the energy of the exciton generated via recoupling of the carrier on the host to the dopant without any waste. This role is important in view of realizing the high internal quantum efficiency.

So far, many examples have been present in which a thin film containing the above described dopant and host is applied to an organic electronic device, especially, a thin film containing a metal complex emitting a green color or a red color is reported to exert a practical level of an emission lifetime.

On the other hand, a thin film containing a metal complex emitting phosphorescence in a blue color (hereinafter, appropriately refer to as a “blue phosphorescent metal complex”) achieves an insufficient emission lifetime. The reason is that an energy level (hereinafter, simply refer to as “a level”) of the blue phosphorescent metal complex is higher than those of the red and green phosphorescent metal complexes. This feature allows the energy of the blue one to be easily transformed to a quencher having a low energy level generated via agglomeration/decomposition of the dopant and host.

Here, a quenching phenomenon of the dopant when a quencher is generated may be explained by the following Stem-Volmer expression (Expression (1)).

$$\frac{PL ( withQuencher )}{PL 0 ( withoutQuencher )} = \frac{1}{1 + Kq \times [ Q ] \times τ0} = \frac{1}{1 + Kq \times ( Kd \times t ) \times τ0} \qquad ( Expression 1 )$$

In Expression (1), PL (without Quencher) is an emission intensity in the presence of a quencher, PLO (without quencher) is an emission intensity in the absence of a quencher, Kq is an energy transfer rate, [Q](=Kd×t) is a concentration of quencher, Kd is a generation rate of quencher through agglomeration/decomposition, t is an accumulated excitation time via light or current, and Do is a phosphorescence lifetime in the absence of quencher.

Note, a blue phosphorescent metal complex using Ir is disclosed, for example, in Patent Document 1.

### DOCUMENTS OF PRIOR ART

### Patent Documents

Patent Document 1: International Publication No. 2006/121811.

### SUMMARY OF INVENTION

### Problems to be Solved by Invention

A blue phosphorescence metal complex has a phosphorescence lifetime (t) being from about several □s to about several □s, which is principally longer in the order of 2˜3 than that of a fluorescent material. Further, a blue phosphorescence metal complex has a high level of triplet excitation state, and thus an emission spectrum of the dopant and an absorption spectrum of the quencher are easily overlapped, resulting in an increase in the energy transfer rate (Kq).

When the above evidences are applied to the above described Equation (1), it is clearly understood that a blue phosphorescence metal complex tends to principally cause quenching, and has a insufficient emission lifetime.

Further, a technology of Patent Document 1 provides an insufficient emission lifetime (i.e., a detailed reason will be described later), remaining enough room for improving an emission lifetime.

The present invention has been made in view of the above described circumstances. An object of the present invention is to provide a thin film and an organic electroluminescent element both having a long emission lifetime.

### Means for Solving Problems

Namely, the above disadvantages targeted by the present invention are solved via the following formations of a thin film and an organic electroluminescent element.

1. A thin film containing a light-emitting metal complex and a host. The light-emitting metal complex is represented by the following General Formula (1) and satisfies Equation (1) as described below. The host is a non-metallic organic compound showing phosphorescence at room temperature, a compound showing thermally activated delayed fluorescence, or a compound expressing an inverse intersystem crossing phenomenon between a singlet excited state showing a level higher than the lowest singlet excited state and a triplet excited state showing a level higher than the lowest triplet excited state.

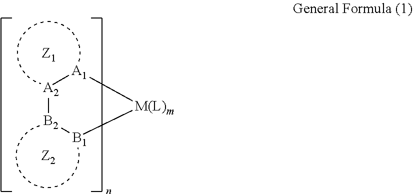

[In General Formula (1), M represents Ir or Pt; A₁, A₂, B₁, B₂ respectively represent a carbon atom or a nitrogen atom; ring Z₁ represents a 6-membered aromatic hydrocarbon ring formed with A₁ and A₂, a 5- or 6-membered aromatic heterocyclic ring, or an aromatic fused ring including at least one of the aromatic hydrocarbon ring and the aromatic heterocyclic rings. Further, ring Z₂ is a 5- or 6-membered aromatic heterocyclic ring formed with B₁ and B₂, or an aromatic fused ring including at least one of the aromatic heterocyclic rings. One of the bond between A₁ and M and the bond between B₁ and M represents a coordinate bond, and the other is a covalent bond. Ring Z₁ and ring Z₂ may independently have a substituent, but at least one substituent represented by the following General Formula (2). A fused ring structure may be formed by a substituent of the ring Z₁ and a substituent of the ring Z₂ being bound to each other, or ligands represented by the ring Z and the ring Z₂ may be bound to each other. L represents a monoanionic bidentate ligand coordinated with M, and may have a substituent. m represents an integer from 0 to 2, and n represents an integer from 1 to 3. When M is Ir, m+n is 3. When M is Pt, m+n is 2. When m or n is 2 or more, L or ligands represented by the ring Z₁ or the ring Z₂ may be the same or different respectively. Further, L and the ligands represented by the ring Z₁ and the ring Z₂ may be bound to each other.]

*-L′-(CR₂)_{n′}-A General Formula (2)

[In General Formula (2), * represents a binding position with the ring Z₁ or the ring Z₂ in General Formula (1). L′ represents a single bond or a linker. R represents a hydrogen atom or a substituent. n′ represents an integer of 3 or more. A plurality of R(s) may be the same or different. A represents a hydrogen atom or a substituent.]

$$\frac{{V}_{all}}{{V}_{core}} > 2 \qquad Equation ( 1 )$$

[In Equation (1), Vₐₗₗ represents a molecular volume of the structure including a substituent bound to the ring Z₁ and the ring Z₂, assuming that n=3 and m=0 when M is Ir, and n=2 and m=0 when M is Pt. V_{core} represents a molecular volume of the structure where the substituent bound to the ring Z₁ and the ring Z₂ in the structure having the molecular volume of Vₐₗₗ is replaced by a hydrogen atom. Note, when there are a plurality of ligands represented by the ring Z₁ and the ring Z₂, Vₐₗₗ and V_{core} both satisfy Equation (1) in all the cases represented by the above described assumptions.]

2. A thin film including a light-emitting metal complex and 2 kinds of hosts. Herein, the light-emitting metal complex is represented by the following General Formula (1) and satisfies Equation (1) and the 2 kinds of hosts are combined to form an excited complex.

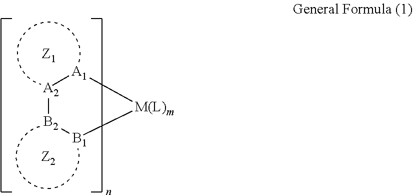

[In General Formula (1), M represents Ir or Pt; A₁, A₂, B₁, B₂ respectively represent a carbon atom or a nitrogen atom; ring Z₁ represents a 6-membered aromatic hydrocarbon ring formed with A₁ and A₂, a 5- or 6-membered aromatic heterocyclic ring, or an aromatic fused ring including at least one of the aromatic hydrocarbon ring and the aromatic heterocyclic rings. One of the bond between A₁ and M and the bond between B₁ and M represents a coordinate bond, and the other is a covalent bond. Ring Z₁ and ring Z₂ may independently have a substituent, but at least one substituent represented by the following General Formula (2). A fused ring structure may be formed by a substituent of the ring Z₁ and a substituent of the ring Z₂ being bound to each other, or ligands represented by the ring Z₁ and the ring Z₂ may be bound to each other.

L represents a monoanionic bidentate ligand coordinated with M, and may have a substituent. m represents an integer from 0 to 2, and n represents an integer from 1 to 3. When M is Ir, m+n is 3. When M is Pt, m+n is 2. When m or n is 2 or more, L or ligands represented by the ring Z₁ or the ring Z₂ may be the same or different respectively. Further, L and the ligands represented by the ring Z₁ and the ring Z₂ may be bound to each other.]

*-L′-(CR₂)_{n′}-A General Formula (2)

[In General Formula (2), * represents a binding position on the ring Z₁ or the ring Z₂ in General Formula (1). L′ represents a single bond or a linker. R represents a hydrogen atom or a substituent. n′ represents an integer of 3 or more. A plurality of R(s) may be the same or different. A represents a hydrogen atom or a substituent.]

$$\frac{{V}_{all}}{{V}_{core}} > 2 \qquad Equation ( 1 )$$

[In Equation (1), Vₐₗₗ represents a molecular volume of the structure including a substituent bound to the ring Z₁ and the ring Z₂, assuming that n=3 and m=0 when M is Ir, and n=2 and m=0 when M is Pt. V_{core} represents a molecular volume of the structure where the substituent bound to the ring Z₁ and the ring Z₂ in the structure having the molecular volume of Vₐₗₗ is replaced by a hydrogen atom. Note, when there are a plurality of ligands represented by the ring Z₁ and the ring Z₂, Vₐₗₗ and V_{core} both satisfy Equation (1) in all the cases represented by the above described assumption.]

3. A thin film in which L′ in General Formula (2) is a non-covalent linker according to the above formations 1 and 2.

4. A thin film in which a ligand represented by the ring Z₁ or the ring Z₂ in General Formula (1) has 3 or more substituents according to any one of the formations 1-3.

5. A thin film containing a light-emitting metal complex and a host. The light-emitting metal complex is represented by any one of the following General Formulae (3)˜(5) and satisfies Equation (1). The host is a non-metallic organic compound showing phosphorescence at room temperature, a compound showing thermally activated delayed fluorescence, or a compound expressing an inverse intersystem crossing phenomenon between a singlet excited state showing a level higher than the lowest singlet excited state and a triplet excited state showing a level higher than the lowest triplet excited state.

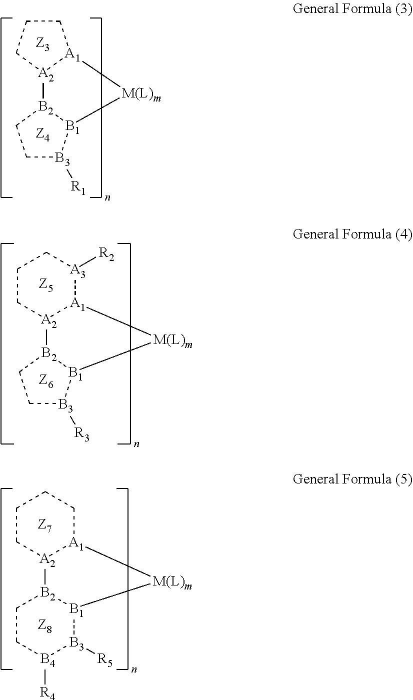

[In General Formulae (3)˜(5), M represents Ir or Pt; A₁˜A₃ and B₁˜B₄ respectively represent a carbon atom or a nitrogen atom. One of the bond between A₁ and M and the bond between B₁ and M represents a coordinate bond, and the other is a covalent bond. L represents a monoanionic bidentate ligand coordinated with M, and may have a substituent. m represents an integer from 0 to 2, and n represents an integer from 1 to 3. When M is Ir, m+n is 3. When M is Pt, m+n is 2. When m or n is 2 or more, L, or a ligand represented by ring Z₃ and ring Z₄, or a ligand represented by ring Z₅ and ring Z₆, a ligand represented by ring z₇ and ring Z₈ may be the same or different respectively. L and those ligands may be bound to each other.

In General Formula (3), the ring Z₃ represents a 5-membered aromatic heterocyclic ring formed with A₁ and A₂ or an aromatic fused ring including the 5-membered aromatic heterocyclic ring. The ring Z₄ represents a 5-membered aromatic heterocyclic ring formed with B₁˜B₃ or an aromatic fused ring including the 5-membered aromatic heterocyclic ring. R₁ represents a substituent having 2 or more carbon atoms. The ring Z₃ and the ring Z₄ may include a substituent besides R₁. A fused ring structure may be formed by a substituent of the ring Z₅ and a substituent of the ring Z₆ being bound to each other. Further, ligands represented by the ring Z₅ and the ring Z₆ may be bound to each other.

In General Formula (5), the ring Z₇ represents a 6-membered aromatic hydrocarbon ring formed with A₁ and A₂, a 6-membered aromatic heterocyclic ring, or an aromatic fused ring including at least one of the 6-membered aromatic hydrocarbon ring and 6-membered aromatic heterocyclic ring. The ring Z₈ represents a 6-membered aromatic hydrocarbon ring formed with B₁˜B₄, a 6-membered aromatic heterocyclic ring, or an aromatic fused ring including the 6-membered aromatic hydrocarbon and heterocyclic rings. R₄ and R₅ respectively represent a hydrogen atom or a substituent, and at least either of R₄ and R₅ represents a substituent having 2 or more carbon atoms. The ring Z₇ and the ring Z₈ may include a substituent besides R₄ and R₅. A fused ring structure may be formed by a substituent of the ring Z₇ and a substituent of the ring Z₈ being bound to each other. Further, ligands represented by the ring Z₇ and the ring Z₈ may be bound to each other.

$$\frac{{V}_{all}}{{V}_{core}} > 2 \qquad Equation ( 1 )$$

[In Equation (1), Vₐₗₗ represents a molecular volume of the structure including a substituent bound to the ring Z₃˜the ring Z₈, assuming that n=3 and m=0 when M is Ir, and n=2 and m=0 when M is Pt. V_{core} represents a molecular volume of the structure where the substituent bound to the ring Z₃˜the ring Z₈ in the structure having the molecular volume of Vₐₗₗ is replaced by a hydrogen atom. Note, when there are a plurality of ligands represented by the ring Z₃ and the ring Z₄, represented by the ring Z₅ and the ring Z₆, represented by the ring Z₇ and the ring Z₈, Vₐₗₗ and V_{core} both satisfy Equation (1) in all the cases represented by the above described assumption.]

6. A thin film containing a light-emitting metal complex and two kinds of hosts. The light-emitting metal complex is represented by any one of the following General Formulae (3) (5) and satisfies General Formula (1). The two kinds of hosts are combined to form an excited complex.

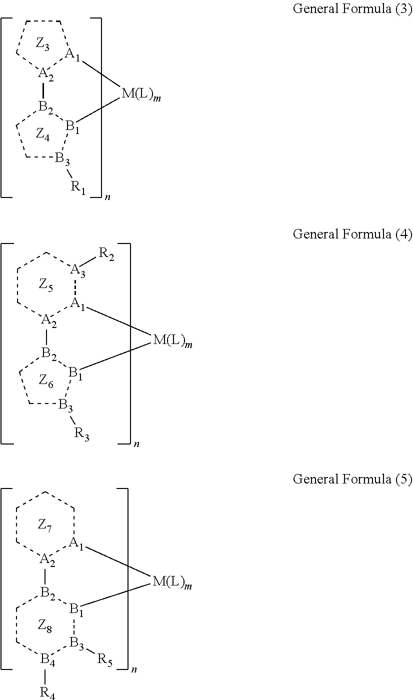

[In General Formulae (3)˜(5), M represents Ir or Pt; A₁˜A₃ and B₁˜B₄ respectively represent a carbon atom or a nitrogen atom. One of the bond between A₁ and M and the bond between B₁ and M represents a coordinate bond, and the other represents a covalent bond. L represents a monoanionic bidentate ligand coordinated with M, and may have a substituent. m represents an integer from 0 to 2, and n represents an integer from 1 to 3. When M is Ir, m+n is 3. When M is Pt, m+n is 2. When m or n is 2 or more, L, or a ligand represented by ring Z₃ and ring Z₄, Or a ligand represented by ring Z₈ and ring Z₆, a ligand represented by ring Z₇ and ring Z₈ may be the same or different respectively. L and those ligands may be bound to each other.

In General Formula (3), the ring Z₃ represents a 5-membered aromatic heterocyclic ring formed with A₁ and A₂ or an aromatic fused ring including the 5-membered aromatic heterocyclic ring. The ring Z₄ represents a 5-membered aromatic heterocyclic ring formed with B₁˜B₃ or an aromatic fused ring including the 5-membered aromatic and heterocyclic rings. R₁ represents a substituent having 2 or more carbon atoms. The ring Z₃ and the ring Z₄ may include a substituent besides R₁. A fused ring structure may be formed by a substituent of the ring Z₈ and a substituent of the ring Z₆ being bound to each other. Further, ligands represented by the ring Z₈ and the ring Z₆ may be bound to each other.

In General Formula (4), the ring Z₅ represents a 6-membered aromatic hydrocarbon ring formed with A₁˜A₃, a 6-membered aromatic heterocyclic ring formed with A₁˜A₃, or an aromatic fused ring including at least one of the 6-membered aromatic hydrocarbon ring and the 6-membered aromatic heterocyclic ring;

The ring Z₆ represents a 5-membered aromatic heterocyclic ring formed with B₁˜B₃, or an aromatic fused ring including the 5-membered aromatic heterocyclic ring;

R₂ and R₃ independently represent a hydrogen atom or a substituent, and at least either of R₂ and R₃ represents a substituent having 2 or more carbon atoms;

The ring Z₅ and the ring Z⁶ may have a substituent besides R₂ and R₃; and

A fused ring structure may be formed by a substituent of the ring Z₅ and a substituent of the ring Z₆ being bound to each other, and ligands represented by the ring Z₅ and the ring Z₆ may be bound to each other.

In General Formula (5), the ring Z₇ represents a 6-membered aromatic hydrocarbon ring formed with A₁ and A₂, a 6-membered aromatic heterocyclic ring, formed with A₁ and A₂ or an aromatic fused ring including at least one of the 6-membered aromatic hydrocarbon ring and 6-membered aromatic heterocyclic ring. The ring Z₈ represents a 6-membered aromatic hydrocarbon ring formed with B₁˜B₄, a 6-membered aromatic heterocyclic ring formed with B₁˜B₄, or an aromatic fused ring including the 6-membered aromatic hydrocarbon and heterocyclic rings. R₄ and R₅ respectively represent a hydrogen atom or a substituent, and at least either of R₄ or R₅ represents a substituent having 2 or more carbon atoms. The ring Z₇ and the ring Z₈ may include a substituent besides R₄ and R₅. A fused ring structure may be formed by a substituent of the ring Z₇ and a substituent of the ring Z₈ being bound to each other. Further, ligands represented by the ring Z₇ and the ring Z₈ may be bound to each other.

$$\frac{{V}_{all}}{{V}_{core}} > 2 \qquad Equation ( 1 )$$

[In Equation (1), Vₐₗₗ represents a molecular volume of the structure including a substituent bound to the rings Z₃˜Z₈, assuming that n=3 and m=0 when M is Ir, and n=2 and m=0 when M is Pt. V_{core} represents a molecular volume of the structure where the substituent bound to the rings Z₃˜Z₈ in the structure having the molecular volume of Vₐₗₗ is replaced by a hydrogen atom. Note, when there are a plurality of ligands represented by the ring Z₃ and the ring Z₄, represented by the ring Z₅ and the ring Z₆, and represented by the ring Z₇ and the ring Z₈, Vₐₗₗ and V_{core} both satisfy Equation (1) in all the cases represented by the above described assumptions.]

7. A thin film in which a ligand represented by the ring Z₃ and the ring Z₄ in General Formula (3), a ligand represented by the ring Z₅ and the ring Z₆ in General Formula (4), or a ligand represented by the ring Z₇ and the ring Z₈ in General Formula (5) has 3 or more substituents according to the formation 5 or 6.

8. An organic electroluminescent element including at least one luminescent layer between an anode and a cathode. Herein, the organic electroluminescent element includes any one of the thin films according to the formations 1-7.

9. An organic electroluminescent element in which the luminescent layer is a single layer consisting of any one of the thin films according to the formations 1-7.

### Effect of Invention

According to the present invention, provided are a thin film and an organic electroluminescent element both having a long emission lifetime.

### BRIEF DESCRIPTION OF DRAWINGS

FIG. 1 is a schematic diagram showing a relationship between a core-shell type dopant and a quencher.

FIG. 2 is a schematic diagram showing a relationship between a core-shell type dopant and a host.

FIG. 3 is a diagram showing energy levels of a host and a core-shell type dopant when a conventional host is used.

FIG. 4 is a diagram showing energy levels of a host and a core-shell type dopant when a host of the first embodiment is used.

FIG. 5 is a diagram showing energy levels of a host and a core-shell type dopant when hosts of the second and fourth embodiment are used.

FIG. 6 is a diagram showing energy levels of a host and a core-shell type dopant when a host of the third embodiment is used.

FIG. 7 is a schematic perspective view showing an example of the formation of a display using an organic electroluminescent element of the present invention.

FIG. 8 is a schematic perspective view showing an example of the structure of a display A illustrated in FIG. 7.

FIG. 9 is a schematic perspective view showing an example of a lighting apparatus using an organic electroluminescent element of the present invention.

FIG. 10 is a schematic cross-sectional view showing an example of a lighting apparatus using an organic electroluminescent element of the present invention.

FIG. 11 is a schematic cross-sectional view showing an example of a lighting apparatus using an organic electroluminescent element of the present invention.

### EMBODIMENTS FOR CARRYING OUT INVENTION

Hereinafter, the present invention, components thereof, and embodiments and aspects for carrying out the present invention will be described in detail. In the present invention, a preferable embodiment may be optionally modified in the range without departing from the scope of the claims and equivalent thereof. Note, the mark of “˜” is used meaning that numerals described before and after the mark are included as a lower limit and an upper limit.

First, a “generation mechanism of elongating an emission lifetime” of a thin film of the present invention will be described specifically.

<<Generation Mechanism of Elongating Emission Lifetime>>

According to the Stern-Volmer equation as mentioned before, a method for suppressing a decrease in the emission intensity of the dopant in the thin film, and elongating the lifetime includes three processes: (1) shortening an emission lifetime (0) of the dopant; (2) decreasing an amount of quencher (Q); and (3) suppressing an energy transfer rate (Kq) to the quencher thus formed.

The present inventors focused on the process (3) for suppressing Kq among all the processes. Thus, in the present invention, the inventors investigated to use a dopant provided with a core unit and a shell unit (hereinafter, appropriately refer to as a “core-shell type dopant”) as a light-emitting metal complex in order to suppress Kq.

<Advantage and Disadvantage of Core-Shell Type Dopant>

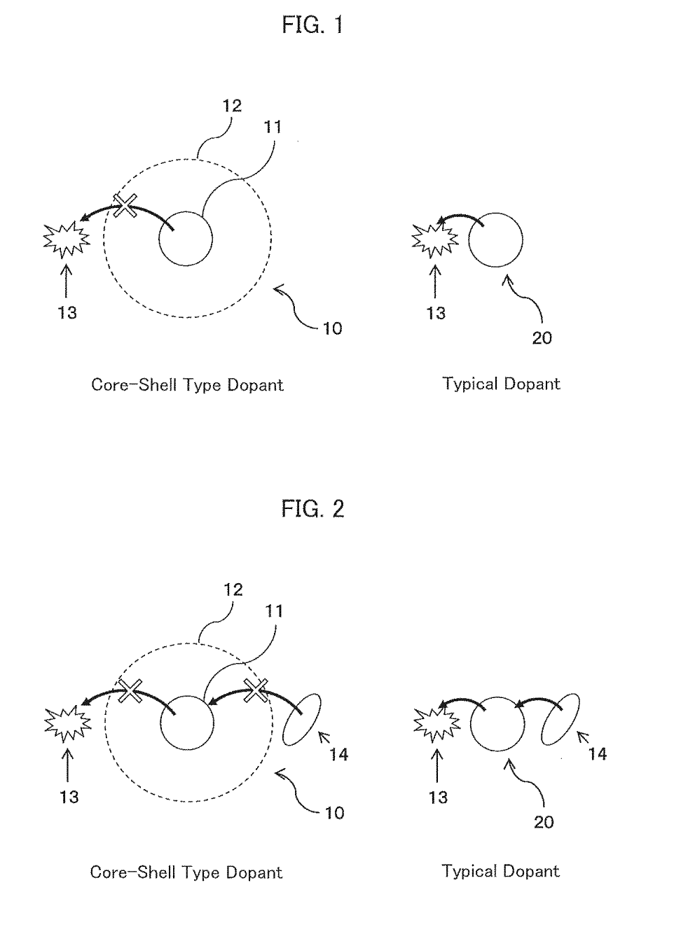

As shown in FIG. 1, a core-shell type dopant 10 is provided with a shell unit 12 around a core unit 11. Therefore, the core-shell type dopant 10 provides a physical distance between the core unit 11 serving as an emission center and the quencher 13. Accordingly, this distance suppresses a rate (Kq) of energy transfer from the core unit 11 to the quencher 13.

However, the present inventors found out that the core-shell type dopant 10 has the following disadvantage.

As shown in FIG. 2, although the core-shell type dopant 10 suppresses Kq due to presence of the shell unit 12, carrier transfer from the host 14 to the core unit 11 that is conducted by a conventional dopant without any problem as well as energy transfer of an exciton are prevented.

When reception of the carrier becomes difficult from the host 14 to the core-shell type dopant 10, a recombination probability of the carrier on the host is increased when the thin film is exited in an electric field, facilitating generation of an exciton on the host 14. Further, as mentioned above, since the energy transfer to the core-shell type dopant 10 is suppressed, this allows the energy of the exciton thus generated on the host 14 to be easily deactivated on the host 14, resulting in a decrease in the emission lifetime of the thin film.

Here, it is construed that failure in achieving a desired emission lifetime by the commonly known core-shell type dopant resides in the disadvantage of the core-shell type dopant as mentioned above.

<Investigation of Disadvantage in Core-Shell Type Dopant and Solution Thereof>

Since a typical host has a small emission rate constant of a triplet exciton with a forbidden spin transition, it is thought that an energy transfer of the triplet exciton to a dopant is not caused by a Forster type transfer involving a long transfer distance, but preferentially caused is a Dexter type transfer occurring between adjacent molecules.

Here, an influence suppressing the energy transfer caused when the core-shell type dopant is used is distinctively observed on the Dexter type transfer involving a short distance rather than the Forester type transfer involving a long transfer distance.

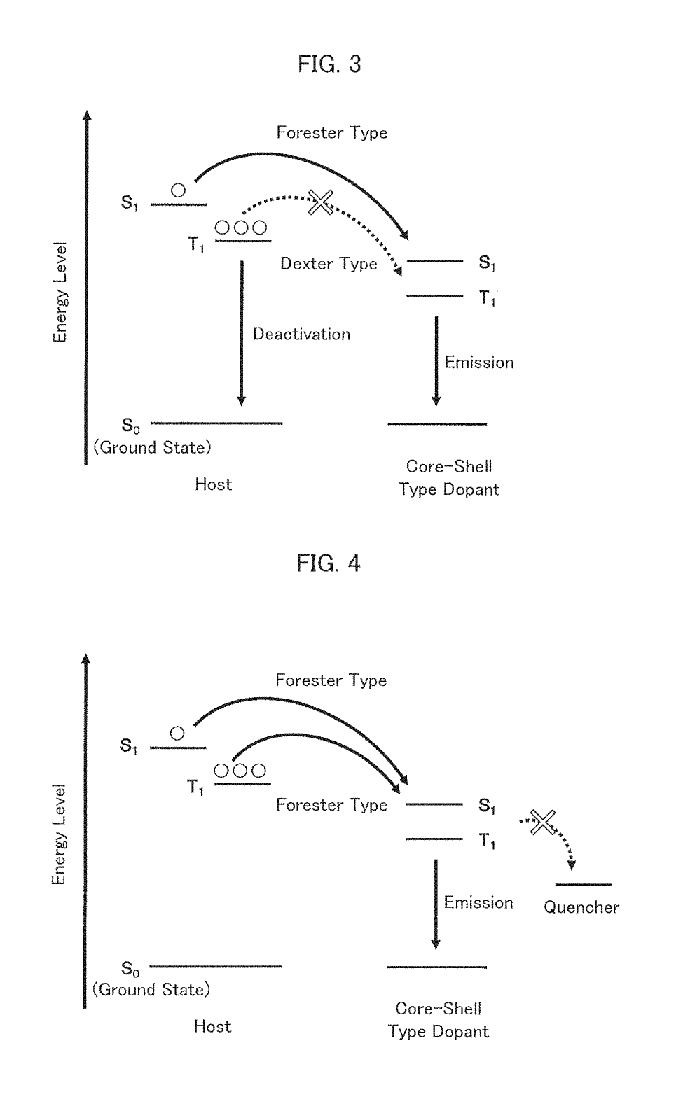

As a result, as shown in FIG. 3, when a typical host and core-shell-type dopant are used, triplet excitons occupying 75% of host excitons generated by excitation in an electric field become deactivated on the host due to suppression of the Dexter type transfer to the core-shell type dopant.

In view of the above, the present inventors focused on the Forester type transfer having a long transfer distance and rarely influenced by the presence of the shell unit among the energy transfers of the excitons from the host to the core-shell type dopant. Hereby, the present inventors have found that a thin film with a long emission lifetime is realized by including the core-shell type dopant and the host performing the energy transfer of the excitons via the Forester type transfer therein.

<<Thin Film>>

A thin film of the present invention includes a light-emitting metal complex and a host. Contents of the light-emitting metal complex and the host of the present invention may be optionally determined based on the conditions required for a product to which the thin film is applied. Further, the light-emitting metal complex and the host each may be included at a uniform concentration in the film thickness direction, or may have an optional concentration distribution.

However, when mass of the thin film is defined in 100 mass %, a content of the light-emitting metal complex in the thin film of the present invention is set to preferably 1˜50 mass %, more preferably 1˜30 mass %, in order to suitably generate an emission phenomenon. Further, a content of the host in the thin film of the present invention may be set to preferably 50˜99 mass %, more preferably 70˜99 mass %, when mass of the thin film is defined in 100 mass %. Next, a “light-emitting metal complex” and a “host” contained in the thin film of the present invention will be described in detail.

<<Light-Emitting Metal Complex>>

A light-emitting metal complex of the present invention is a “core-shell type dopant” including a core unit and a shell unit, represented by predetermined General Formula and satisfying Equation (1).

In the present invention, the light-emitting metal complex (i.e., a core-shell type dopant) is either of a “compound represented by General Formula (1)” or a “compound represented by General Formulae (3)˜(5)”.

Hereinafter, the light-emitting metal complexes will be respectively described appropriately as a “light-emitting metal complex in the first embodiment” or the like in the order of the description.

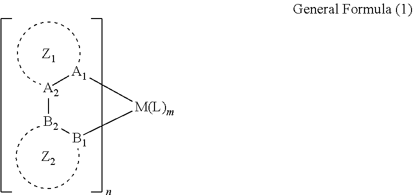

In General Formula (1), M represents Ir or Pt; A₁, A₂, B₁, B₂ respectively represent a carbon atom or a nitrogen atom; ring Z₁ represents a 6-membered aromatic hydrocarbon ring formed with A₁ and A₂, a 5- or 6-membered aromatic heterocyclic ring formed with A₁ and A₂, or an aromatic fused ring including at least one of the aromatic hydrocarbon ring and the aromatic heterocyclic rings. Ring Z₂ represents a 5- or 6-membered aromatic heterocyclic ring formed with B₁ and B₂, or an aromatic fused ring including at least one of the aromatic heterocyclic rings.

One of a bond between A₁ and M and a bond between B₁ and M represents a coordinate bond, and the other is a covalent bond. Ring Z₁ and ring Z₂ may independently have a substituent, but at least one substituent represented by the following General Formula (2). A fused ring structure may be formed by a substituent of the ring Z₁ and a substituent of the ring Z₂ being bound to each other, or ligands represented by the ring Z₁ and the ring Z₂ may be bound to each other.

L represents a monoanionic bidentate ligand coordinated with M, and may have a substituent. m represents an integer from 0 to 2, and n represents an integer from 1 to 3. When M is Ir, m+n is 3. When M is Pt, m+n is 2. When m or n is 2 or more, L(s) or ligands represented by the ring Z₁ and the ring Z₂ may be the same or different respectively. Further, L and the ligands represented by the ring Z₁ and the ring Z₂ may be bound to each other.]

*-L′-(CR₂)_{n′}-A General Formula (2)

In General Formula (2), the mark of * represents a binding position onto the ring Z₁ or the ring Z₂ shown in General Formula (1). L′ represents a single bond or a linker. R represents a hydrogen atom or a substituent. n′ represents an integer of 3 or more. A plurality of R(s) may be the same or different. A represents a hydrogen atom or a substituent.

The light-emitting metal complex in the first embodiment has a linear alkylene structure having 3 or more carbon atoms in the ring Z₁ or the ring Z₂ shown in General Formula (2). This structural feature enables placement of a physical distance between the core unit serving as an emission center and the quencher, resulting in suppression of the energy transfer to the quencher. Here, n′ in General Formula (2) is set to preferably an integer of 4 or more, more preferably an integer of 6 or more in order to more suppress the energy transfer to the quencher.

Preferably, the light-emitting metal complex in the first embodiment has L′ that is a non-conjugated linker in General Formula (2). L′ of the non-conjugated linker facilitates localization of HOMO and LUMO electrons into the center metal, the rings Z₁ and Z₂. In other words, L′ of the non-conjugated linker can suppress delocalization of HOMO and LUMO electrons into a substituent moiety forming the shell unit. As a result, a sufficient physical distance can be provided between the core unit serving as an emission center and the quencher. Here, a non-conjugated linker means a case that the linker cannot be represented by repetition of a single bond and a double bond, or a case that conjugation between aromatic rings forming the linker is sterically cleaved. For example, the non-conjugated linker includes an alkylene group, a cycloalkylene group, an ether group and a thioether group.

The light-emitting metal complex in the first embodiment preferably has a ligand that is represented by the ring Z₁ and the ring Z₂ in General Formula (1) and includes 3 or more substituents (i.e., when n is 2 or more, each ligand has 3 or more substituents). The above structural feature enables 3-dimensional formation of the shell unit around the core unit serving as an emission center, thereby to provide a physical distance in omnidirection to the quencher.

Here, a substituent in General Formula (1) (i.e., a substituent other than the substituents represented by General Formula (2)), a substituent of R in General Formula (2), and a substituent of A include, for example, an alkyl group (e.g., a methyl group, an ethyl group, a propyl group, an isopropyl group, a tert-butyl group, a pentyl group, a hexyl group, an octyl group, a dodecyl group, a tridecyl group, a tetradecyl group, and a pentadecyl group); a cycloalkyl group (e.g., a cyclopentyl group and a cyclohexyl group); an alkenyl group (e.g., a vinyl group and an allyl group); an alkynyl group (e.g., an ethynyl group and a propargyl group); an aromatic hydrocarbon group (i.e., also refer to as an aromatic hydrocarbon ring group, an aromatic carbon ring group or an aryl group, including, for example, a phenyl group, a p-chlorophenyl group, a mesityl group, a tolyl group, a xylyl group, a naphthyl group, an anthryl group, an azulenyl group, an acenaphthenyl group, a fluorenyl group, a phnenthryl group, an indenyl group, a pyrenyl group, and a biphenyl group); an aromatic heterocyclic ring group (e.g., a pyridyl group, a pyrazyl group, a pyrimidyl group, a triazyl group, a furyl group, a pyrrolyl group, an imidazolyl group, a benzoimidazolyl group, a pyrazolyl group, a pyrazinyl group, and triazolyl group (e.g., a 1,2,4-triazole-1-yl group and 1,2,3-triazole-1-yl group), an oxazolyl group, a bonzoxazolyl group, a thiazolyl group, an isoxazolyl group, an isothiazolyl group, a furazanyl group, a thienyl group, a quinolyl group, a benzofuryl group, a dibenzofuryl group, a benzothienyl group, a dibenzothienyl group, an indolyl group, a carbazolyl group, an azacarbazolyl group (i.e., at least optional one carbon atom of the carbazole ring in the carbazolyl group is replaced by a nitrogen atom), a quinoxallinyl group, a pyridazinyl group, a triazinyl group, a qunazolinyl group, and a phthalazinyl group); a heterocyclic group (e.g., a pyrroridyl group, an imidazollidinyl group, a morpholyl group, and an oxazolidinyl group); an alkoxy group (e.g., a methoxy group, an ethoxy group, a propyloxy group, a pentyloxy group, a hexyloxy group, an octyloxy group, and dodecyloxy group); a cycloalkoxy group (e.g., a cyclopentyloxy group and a cyclohexyloxy group); an aryloxy group (e.g., a phenoxy group and a naphthyloxy group); an alkylthio group (e.g., a methylthio group, an ethylthio group, a propylthio group, a pentylthio group, a hexylthio group, an octylthio group, and a dodecylthio group); a cycloalkylthio group (e.g., a cyclopentylthio group and a cyclohexylthi group); an arylthio group (e.g., a phenylthio group and a naphthylthio group); an alkoxycarbonyl group (e.g., a methyloxycarbonyl group, an ethyloxycarbonyl group, a butyloxycarbonyl group, an octyloxycarbonyl group, and a dodecyloxycarbonyl group); an aryloxycarbonyl group (e.g., a phenyloxycarbonyl group and a naphthyloxycarbonyl group); sulfamoyl group (e.g., an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, and a 2-pyridylaminosulfonyl group); an acyl group (e.g., an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, and a pyridylcarbonyl group); an acyloxy group (e.g., an acetyloxy group, an ethylcarbonyloxy group, a butylcarbonyloxy group, an octylcarbonyloxy group, a dodecylcarbonyloxy group, and a phenylcarbonyloxy group); an amide group (e.g., a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, and a naphthylcarbonylamino group); a carbamoyl group (e.g., an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, and a 2-pyridylaminocarbonyl group); an ureide group, (e.g., a methylureide group, an ethylureide group, a pentylureide group, a cyclohexylureide group, an octylureide group, a dodecylureide group, a phenylureide group, a naphthylureide group, and a 2-pyridylureide group); a sulfinyl group (e.g., a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, and a 2-pyridylsulfinyl group); an arylsulfonyl group or a heteroarylsulfonyl group (e.g., a phenylsulfinyl group, a naphthylsulphonyl group and a 2-pyridylsulfonyl group); an amino group (e.g., an amino group, an ethylamino group, a dimethylamino group, a butylamino group, a cyclopentylamino group, a 2-ethylhexylamino group, a dodecylamino group, an anilino group, a naphthylamino group, a 2-pyridylamino group); a halogen atom (e.g., a fluorine atom, a chlorine atom and a bromine atom); a fluorohydrocarbon group (e.g., a fluoromethyl group, a trifluoromethyl group, a pentafluoroethyl group and a pentafluorophenyl group); a cyano group; a nitro group; a hydroxy group, a mercapto group, a silyl group (e.g., a trimethylsilyl group, a triisopropylsilyl group, a triphenylsilyl group and a phenyl diethylsilyl group), and a phosphono group or the like.

Those substituents may be further substituted by the above substituents. Moreover, a plurality of the above substituents may be bound to each other to form a ring structure.

The linker of L′ in General Formula (2) includes, for example, a substituted or non-substituted alkylene group having 1˜12 carbon atoms; a substituted or non-substituted arylene group having ring formation 6˜30 carbon atoms; a heteroarylene group having ring formation 5˜30 atoms; and a bivalent linker formed by combination of those groups.

Further, the alkylene group having 1˜12 carbon atoms may have a linear or a branched structure, or a cyclic structure like a cycloalkylene group. Moreover, the arylene group having ring formation 6˜30 carbon atoms may be a non-fused or a fused ring.

The arylene group having ring forming 6˜30 carbon atoms includes, for example, a o-phenylene group, a m-phenylene group, a p-phenylene group, a naphthalenediyl group, a phenanthrenediyl group, a biphenylene group, a terphenylene group, a quaterphenylene group, a triphenylenediyl group, and a fluorenediyl group.

The heteroarylene group having ring forming 5˜30 carbon atoms includes, for example, a bivalent group that is formed by removing 2 hydrogen atoms from the following ring system: a pyridine ring, a pyrazine ring, a pyrimidine ring, a piperidine ring, a triazine ring, a pyrrole ring, an imidazole ring, a pyrazole ring, a triazole ring, an indole ring, an isoindole ring, a benzimidazole ring, a furan ring, a benzofuran ring, a thiophene ring, a benzothiophene ring, a silole ring, a benzosilole ring, a dibenzosilole ring, a quinoline ring, an isoquinoline ring, a quinoxaline ring, a phenanthridine ring, a phenanthroline ring, an acridine ring, a phenazine ring, a phenoxyazine ring, a phenothiazine ring, a phenoxathiin ring, a a pyridazine ring, an acridine ring, an oxazole ring, an oxadiazole ring, a benzoxazole ring, a thiazole ring, a thiadiazole ring, a benzothiazole ring, a benzodifuran ring, a thienothiophene ring, a dibenzothiophene ring, a benzodithiophene ring, a cyclazine ring, a quindoline ring, a tepenidine ring, a quinindoline ring, a triphenodithiazine ring, triphenodioxazine ring, phenanthrazine ring, an anthrazine ring, a perimidine ring, a naphthofuran ring, a naphthothiophene ring, a benzodithiophene ring, a naphthodifuran ring, a naphthothiophene ring, a carbazole ring, a carboline ring, a diazacarbazole ring (i.e., optional 2 or more carbon atoms forming the carbazole ring are replaced by a nitrogen atom), an azabenzofuran ring (i.e., at least optional one carbon atom forming the dibenzofuran ring is replaced by a nitrogen atom), an azadibenzothiophene ring (i.e., at least optional one carbon atom forming the dibenzothiophene ring is replaced by a nitrogen atom), an indolocarbazole ring, and an indenoindole ring.

More preferable heteroarylene group includes, for example, a bivalent group that is formed by removing 2 hydrogen atoms from the following ring systems: a pyridine ring, a pyrazine ring, a pyrimidine ring, a piperidine ring, a dibenzofuran ring, a dibenzothiophene ring, a carbazole ring, a carboline ring, and a diazacarbazole ring.

Those linkers may be substituted by the above described substituents.

<Structures of Light-Emitting Metal Complexes in Second Embodiment>

The light-emitting metal complexes in the second embodiment are represented by the following General Formulae (3)˜(5).

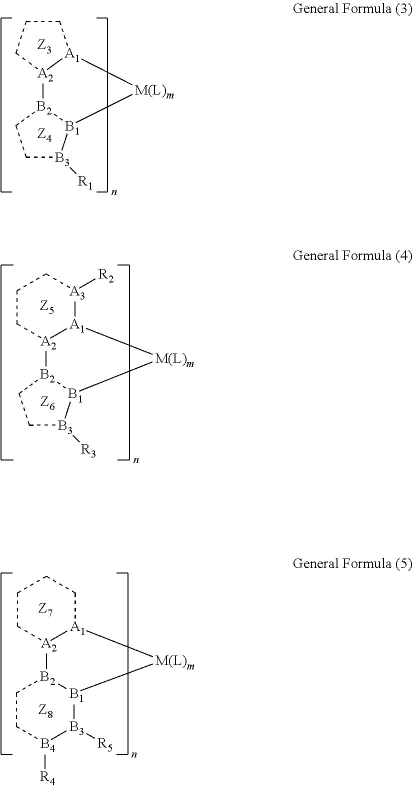

In General Formulae (3)˜(5), M represents Ir or Pt; A₁˜A₃ and B₁˜B₄ respectively represent a carbon atom or a nitrogen atom. One of a bond between A₁ and M and a bond between B₁ and M represents a coordinate bond, and the other is a covalent bond. L represents a monoanionic bidentate ligand coordinated with M, and may have a substituent. m represents an integer of from 0 to 2, and n represents an integer of from 1 to 3. When M is Ir, m+n is 3. When M is Pt, m+n is 2. When m or n is 2 or more, L(s), a ligand represented by ring Z₃ and ring Z₄, a ligand represented by ring Z₅ and ring Z₆, or a ligand represented by ring Z₇ and ring Z₈ may be the same or different respectively. L and those ligands may be bound to each other.

In General Formula (3), the ring Z₃ represents a 5-membered aromatic heterocyclic ring formed with A₁ and A₂. The ring Z₄ represents a 5-membered aromatic heterocyclic ring formed with B₁˜B₃ or an aromatic fused ring including the 5-membered aromatic heterocyclic ring. R₁ represents a substituent having 2 or more carbon atoms. The ring Z₃ and the ring Z₄ may include a substituent besides R₁. A fused ring structure may be formed by a substituent of the ring Z₃ and a substituent of the ring Z₄ being bound to each other. Further, ligands represented by the ring Z₃ and the ring Z₄ may be bound to each other.

In General Formula (4), the ring Z₅ represents a 6-membered aromatic hydrocarbon ring formed with A₁˜A₃, a 6-membered aromatic heterocyclic ring formed with A₁˜A₃, or an aromatic fused ring including at least one of the 6-membered aromatic hydrocarbon ring and the 6-membered aromatic heterocyclic ring. The ring Z₆ represents a 6-membered aromatic hydrocarbon ring formed with B₁˜B₃, or an aromatic fused ring including the 5-membered aromatic heterocyclic ring. R₂ and R₃ respectively represent a hydrogen atom or a substituent, and at least either of R₂ or R₃ represents a substituent having 2 or more carbon atoms. The ring Z₅ and the ring Z₆ may include a substituent besides R₂ and R₃. A fused ring structure may be formed by a substituent of the ring Z₅ and a substituent of the ring Z₆ being bound to each other. Further, ligands represented by the ring Z₅ and the ring Z₆ may be bound to each other.

In General Formula (5), the ring Z₇ represents a ₆-membered aromatic hydrocarbon ring formed with A₁ and A₂, a 6-membered aromatic heterocyclic ring formed with A₁ and A₂, or an aromatic fused ring including at least one of the 6-membered aromatic hydrocarbon ring and 6-membered aromatic heterocyclic ring. The ring Z₈ represents a 6-membered aromatic hydrocarbon ring formed with B₁˜B₄, a 6-membered aromatic heterocyclic ring formed with B₁˜B₄, or an aromatic fused ring including the 6-membered aromatic hydrocarbon and heterocyclic rings. R₄ and R₅ respectively represent a hydrogen atom or a substituent, and at least either of R₄ or R₅ represents a substituent having 2 or more carbon atoms. The ring Z₇ and the ring Z₈ may include a substituent besides R₄ and R₅. A fused ring structure may be formed by a substituent of the ring Z₇ and a substituent of the ring Z₈ being bound to each other. Further, ligands represented by the ring Z₇ and the ring Z₈ may be bound to each other.

The light-emitting metal complex in the second embodiment has 2 or more carbon atoms in R₁˜R₆ in General Formula (3). This structural feature enables placement of a physical distance between the core unit serving as an emission center and the quencher, thereby suppressing the energy transfer to the quencher.

Preferably, the substituent is a substituent having 3 or more carbon atoms, more preferably a substituent having 4 or more carbon atoms in order to more suppress the energy transfer to the quencher.

Further, preferably a ligand represented by the ring Z₃ and the ring Z₄ in General Formula (3), a ligand represented by the ring Z₅ and the ring Z₆ in General Formula (4), and a ligand represented by the ring Z₇ and the ring Z₈ in General Formula (5) respectively include 3 or more substituents (i.e., when n is 2 or more, each ligand has 3 or more substituents), in the light-emitting metal complex in the second embodiment.

The above structural feature enables 3-dimensional formation of the shell unit around the core unit serving as an emission center, thereby providing a physical distance in omnidirection to the quencher.

Note, the substituents in General Formulae (3)˜(5) include the same ones as exemplified of the substituents in General Formula (1).

<Molecular Volumes of Light-Emitting Metal Complexes in First and Second Embodiments>

The light emitting metal complexes of the present invention (i.e., light-emitting metal complexes in the first and second embodiments) satisfy the following Equation (1).

$$\frac{{V}_{all}}{{V}_{core}} > 2 \qquad Equation ( 1 )$$

In Equation (1), Vₐₗₗ represents a molecular volume of the structure including a substituent bound to the rings Z₁˜Z₈, assuming that n=3 and m=0 when M is Ir, and n=2 and m=0 when M is Pt, in respective General Formulae (1) and (3)˜(5).

On the other hand, V_{core} represents a molecular volume of the structure where substituents bound to the rings Z₁˜Z₈ in the structure having the molecular volume of Vₐₗₗ are replaced by hydrogen atoms. Note, when the rings Z₁˜Z₈ are aromatic fused rings, V_{core} represents a molecular volume of the structure where substituents bound to the aromatic fused rings are replaced by hydrogen atoms.

Note, when there are a plurality of ligands represented by the rings Z₁ and Z₂, the rings Z₅ and Z₆, and the rings Z₇ and Z₈, Vₐₗₗ and V_{core} both are required to satisfy Equation (1) in all the cases represented by the above described assumption. More specifically, see the following explanation.

As shown in the following example (1), a structure where n=3 and m=0 is assumed is construed to fall in the 2 structures as shown in the following example (3), if ligands represented by the ring Z₅ and Z₆ in General Formula (4) and the rings Z₇ and Z₈ in General Formula (5) are respectively present in a light-emitting metal complex. Herein, a molecular volume of the structure of the following example (2) is defined as Vₐn, and a molecular volume of the structure of the following example (3) is defined as Vₐₗₗ₂, V_{core} of the structure of the example (2) is represented by the following example (4), and V_{core} of the structure of the example (3) is represented by the following example (5) (i.e., defined as V_{core2}). Further, both Vₐₗₗ/V_{core} and Vₐₗₗ₂/V_{core2} are required to satisfy Equation (1) as defined hereinbefore.

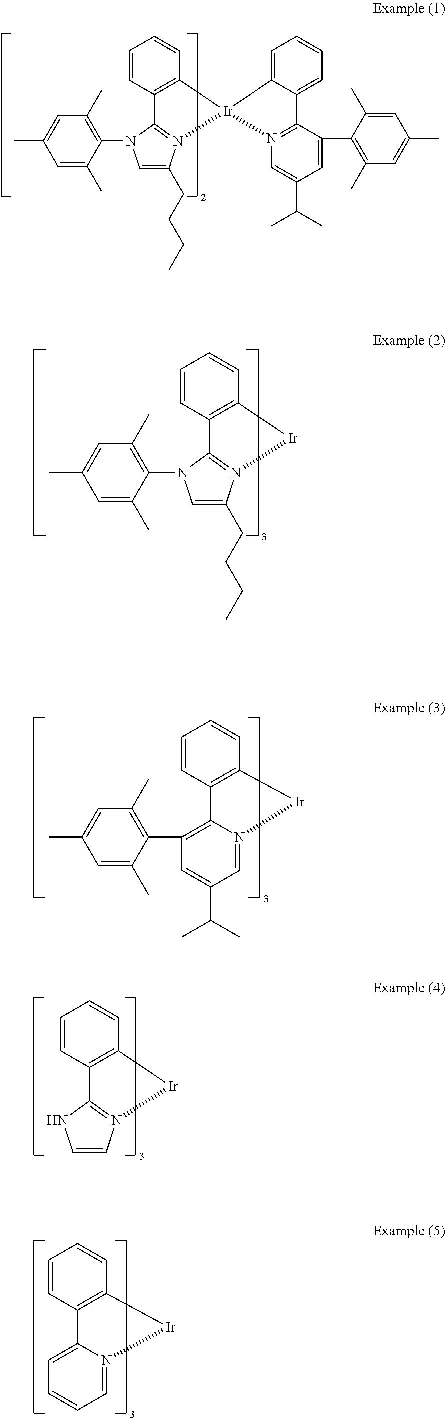

Note, Vₐₗₗ and V_{core} specifically represent van der Waals molecular volumes, and calculated by a molecular graphic software, for example, Winmostor (X-Ability Co., Ltd.).

The light-emitting metal complex of the present invention has a volume ratio of Vₐₗₗ to V_{core} thus set to more than 2, preferably 2.5 or more.

Designing the light-emitting metal complex to have the above defined volume ratio larger can preferably suppress an energy transfer from the core-shell type dopant 10 to the quencher 3 as shown in FIG. 1.

An upper limit of the volume rate is not particularly limited. However, preferably the volume rate is set to 5 or less, more preferably 3 or less, from the viewpoint of easiness for production.

For example, as shown in the following example (6), Ir(ppy)₃ that is known as a complex of emitting green phosphorescence has no shell unit. Thus, Vₐₗₗ/V_{core} thereof is 2 or less. More specifically, Vₐₗₗ=V_{core}=450.04 Å³, and thus Vₐₗₗ/V_{core}=1.

On the contrary, as shown in the following example (7), a metal complex provided with the shell unit in which the substituent satisfying General Formula (2) is introduced to Ir(ppy)3 has Vₐₗₗ/V_{core} is more than 2. More specifically, Vₐₗₗ=960.05 Å³, V_{core}=450.04 Å³, and therefore Vₐₗₗ/V_{core}=2.1.

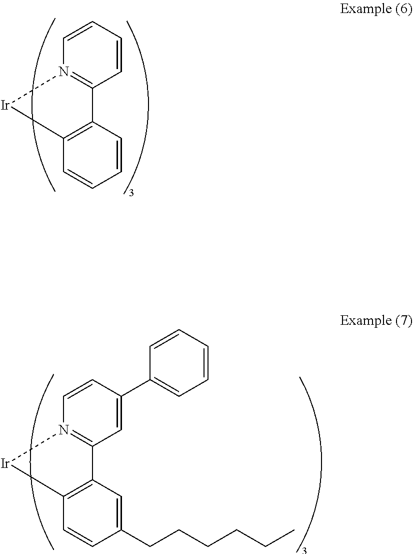

Next, examples of the light-emitting metal complex of the present invention will be illustrated. However, the present invention is not limited to those examples.

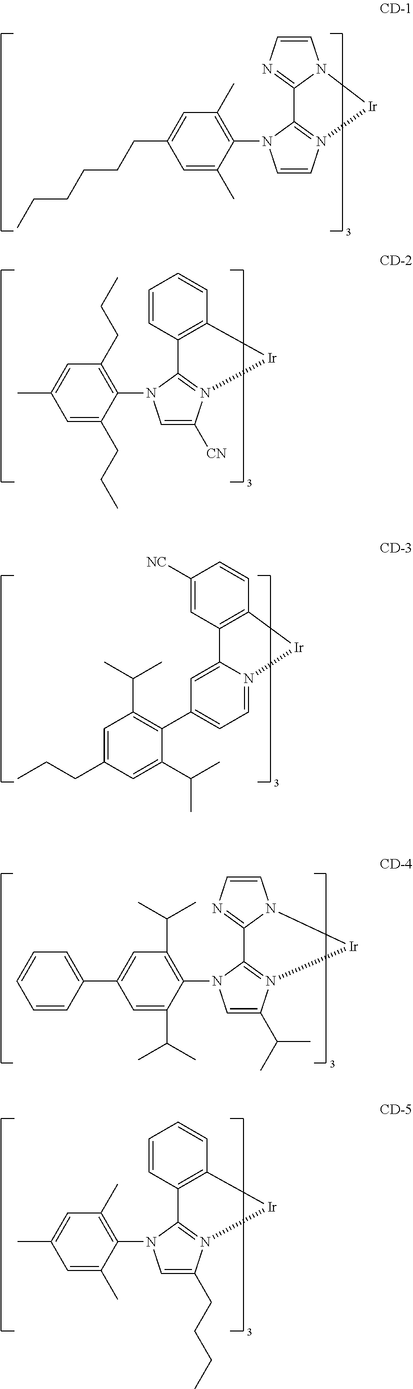

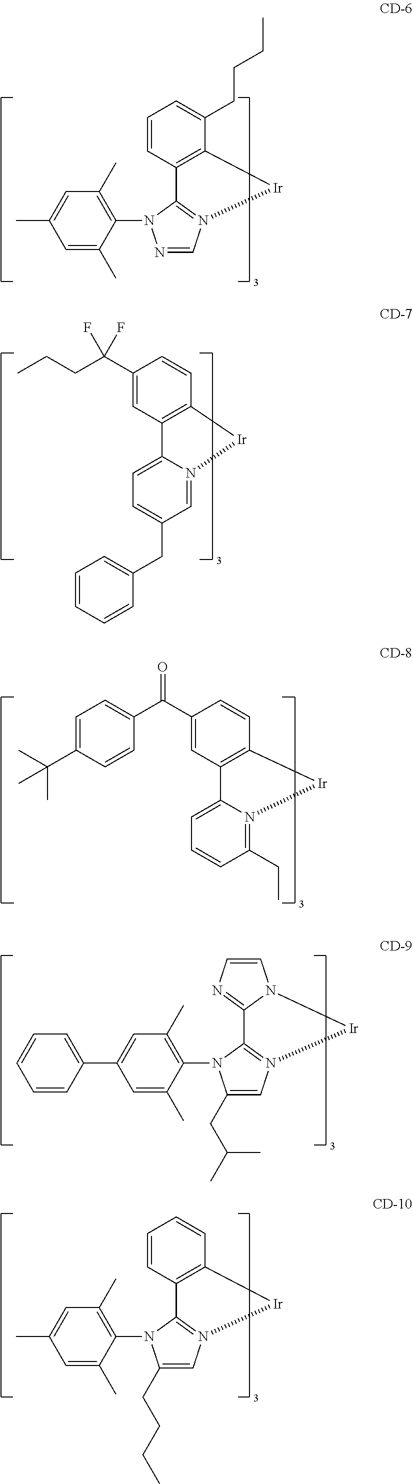

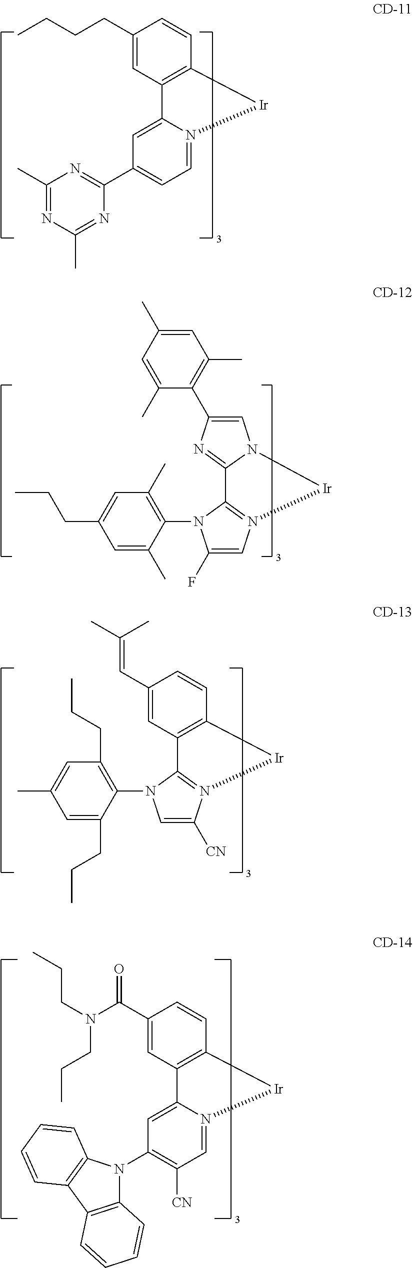

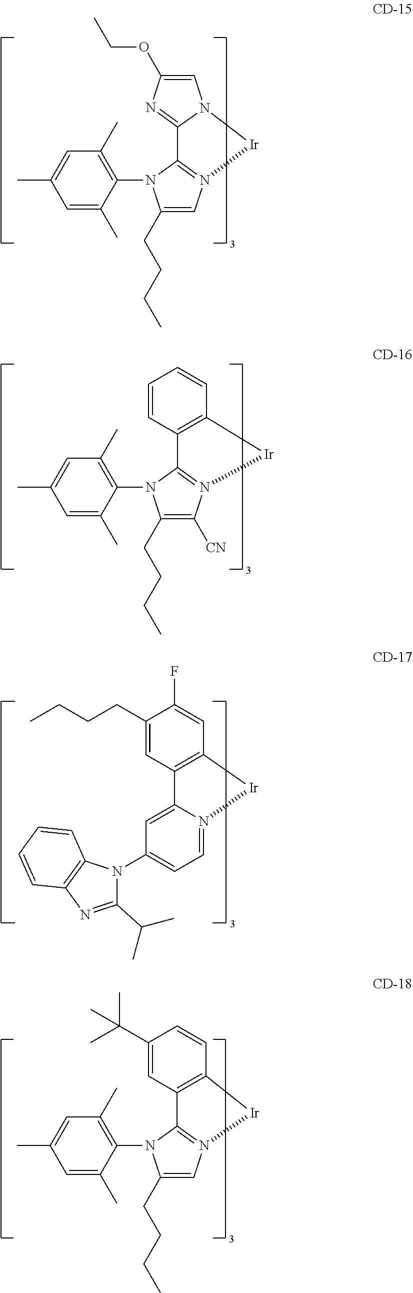

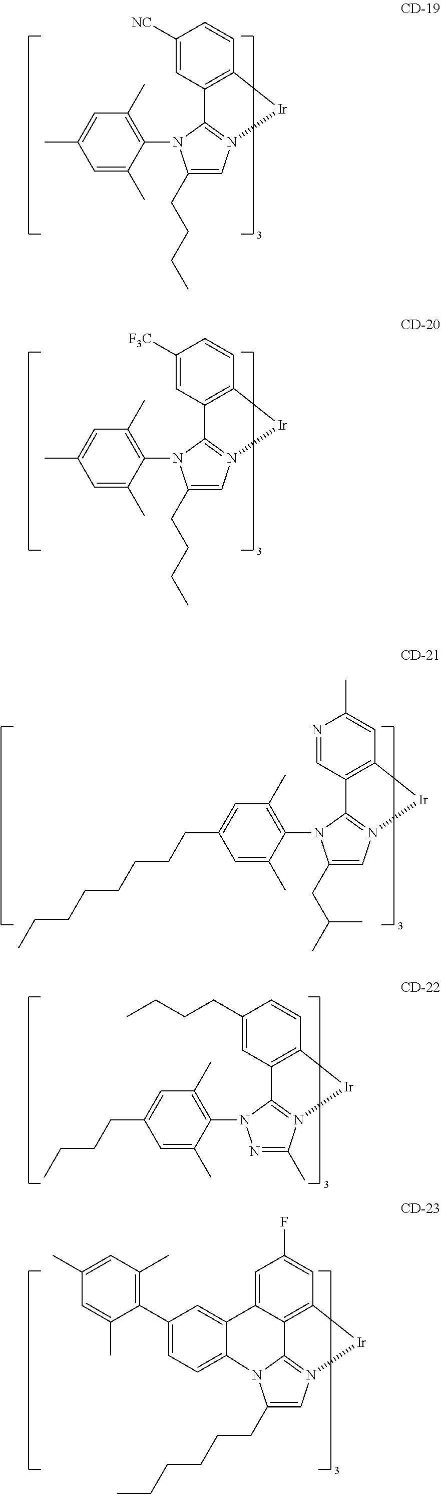

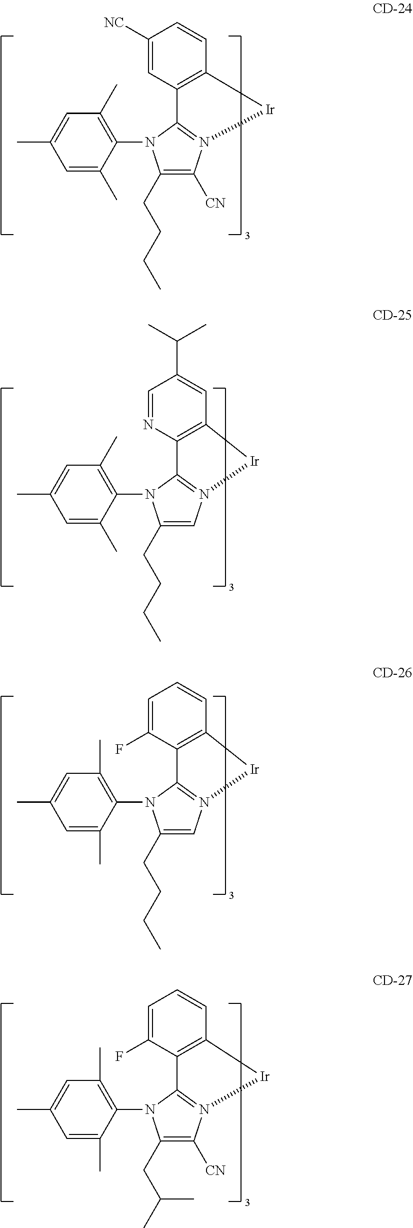

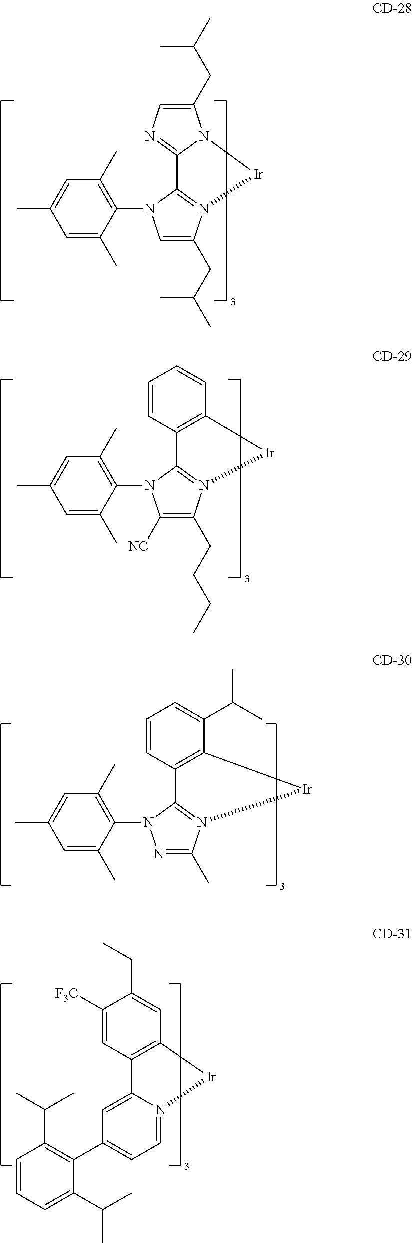

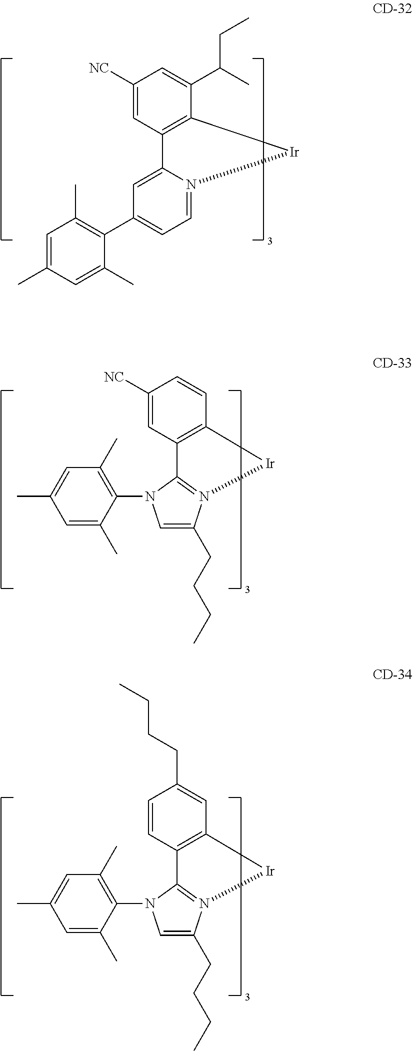

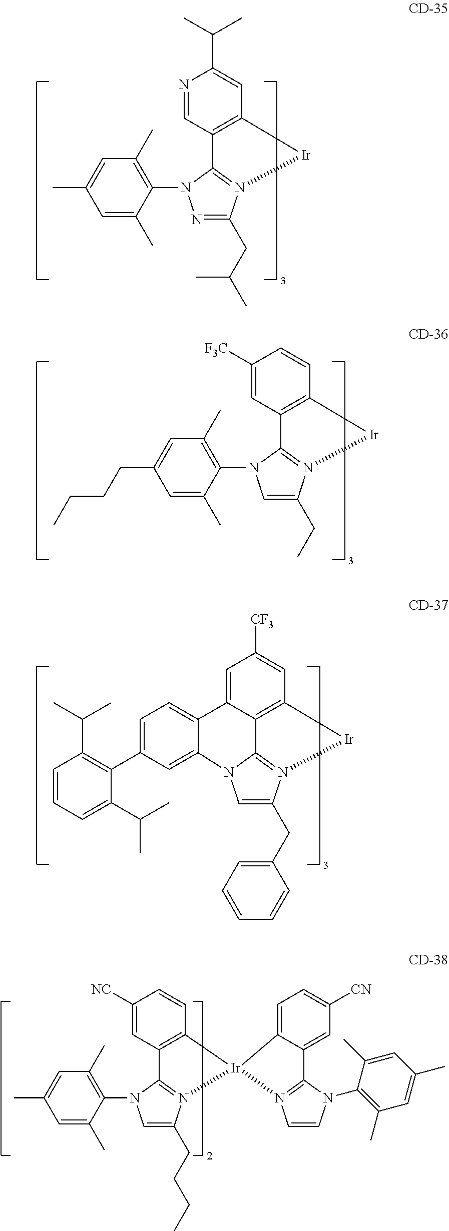

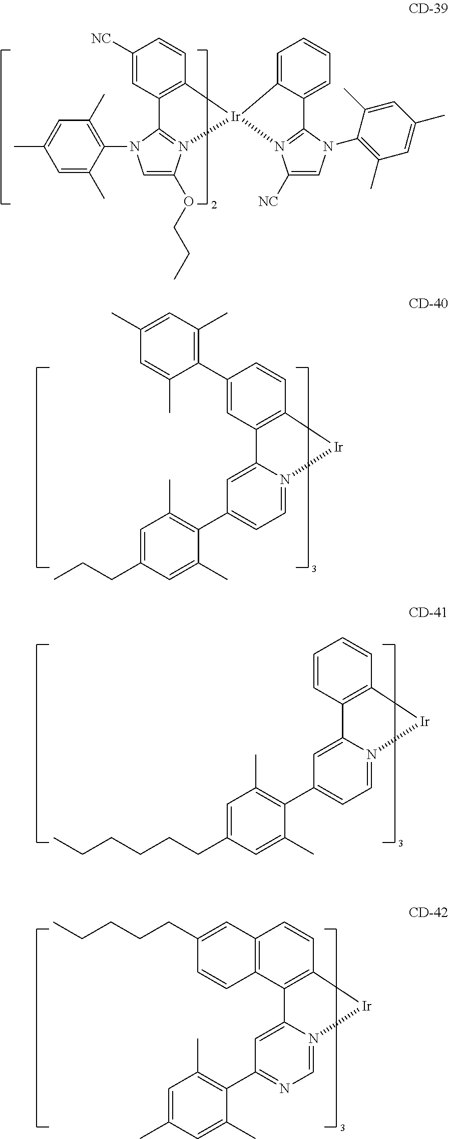

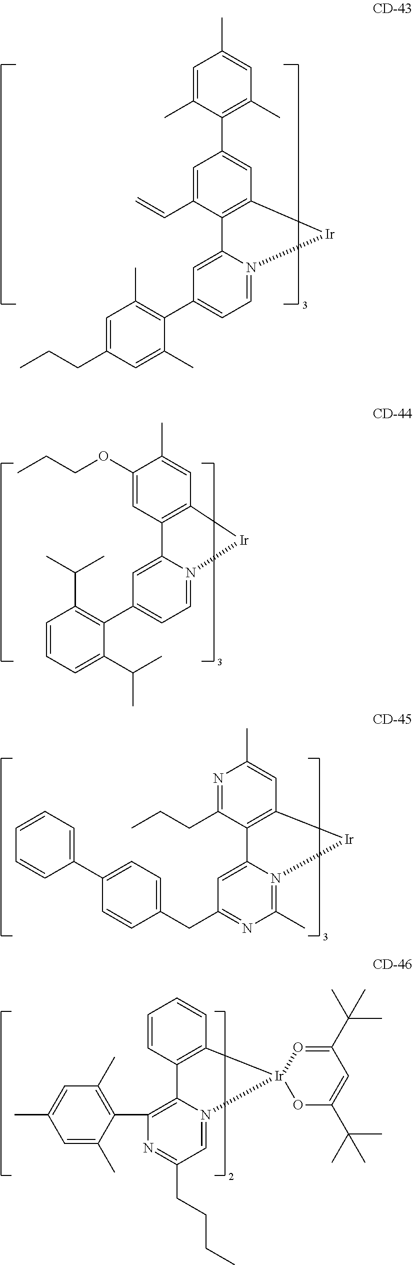

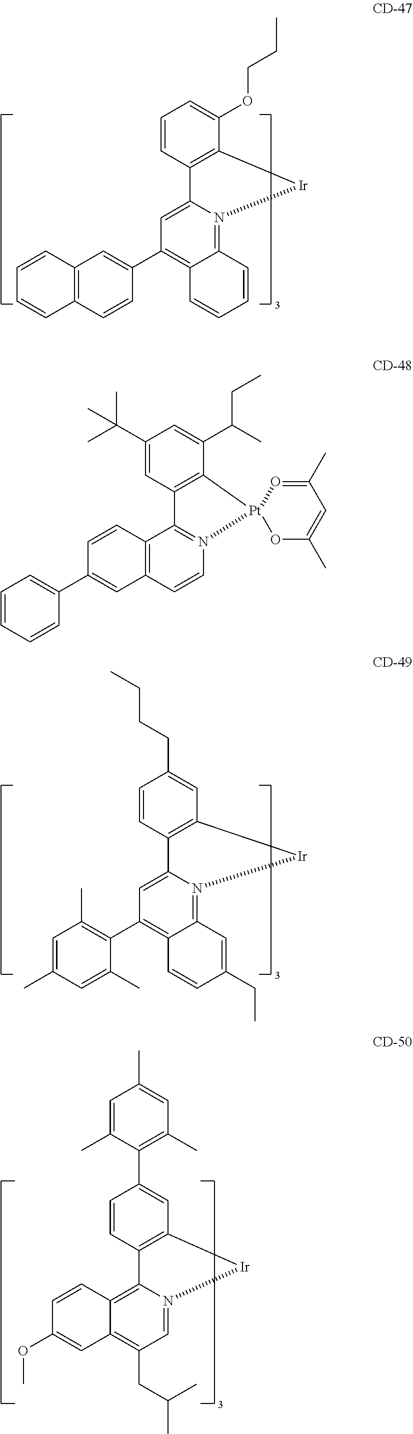

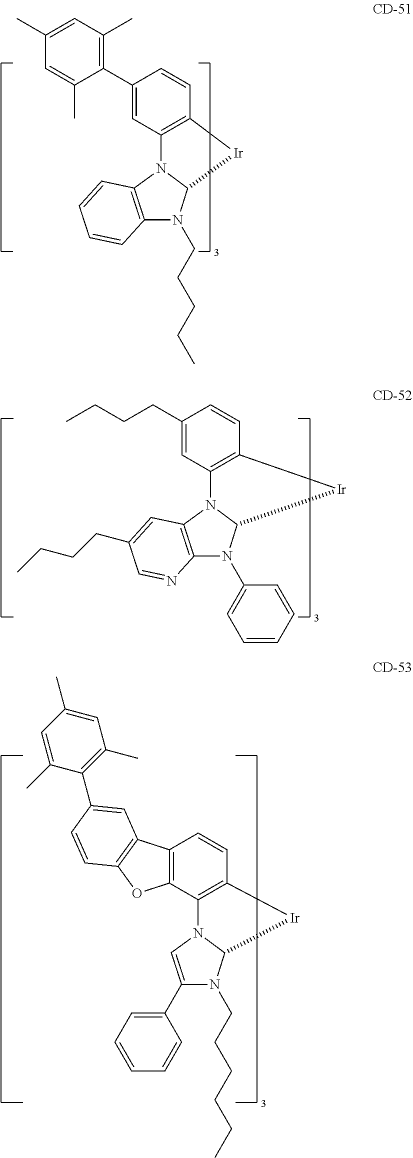

<<Host>>

The host of the present invention is a “Forster type host” that efficiently performs Forster energy transfer of exciton energy to the light-emitting metal complex serving as a core-shell type dopant.

When a type of the host is one, the host of the present invention is a “non-metallic organic compound showing phosphorescence at room temperature”, a “compound showing thermally activated delayed fluorescence”, or a “compound expressing an inverse intersystem crossing phenomenon between a singlet excited state showing a level higher than the lowest singlet excited state and a triplet excited state showing a level higher than the lowest triplet excited state”. When types of the host are two, the host of the present invention is a “combination of excited complexes formed by the two types of hosts”.

Hereinafter, the respective hosts will be appropriately described as “hosts in the first embodiment” in the order of description.

<Hosts in First Embodiment>

Hosts in the first embodiment is a non-metallic organic compound showing phosphorescence at an ambient temperature, more specifically, a compound having a phosphorescence quantum yield of 0.01 or more (preferably, 0.1 or more) at 25° C. Further, since the hosts in the first embodiment show phosphorescence at an ambient temperature, the hosts of the first embodiment have a large emission rate constant of a triplet exciton different from a typical host, allowing Forester energy transfer even of the triplet exciton energy.

Accordingly, as shown in FIG. 4, use of the hosts in the first embodiment enables Forester energy transfer of not only the triplet exciton energy but also the singlet exciton energy, into the core-shell type dopant.

A non-metallic organic compound showing phosphorescence at an ambient temperature includes, but which is not particularly limited, a compound having a benzophenone structure disclosed in Japanese Unexamined Patent Application Publication No. 2006-66562, Japanese Unexamined Patent Application Publication No. H11-256148; and a compound described in Nature Materials, 6 Apr. 2015, DO1: 10, 1038/NMAT4259.

Note, a non-metallic organic compound showing phosphorescence at an ambient temperature does not necessarily show phosphorescence in an isolated molecular state, but may be a compound in a thin film state from which phosphorescence is just observed.

Next, examples of the hosts in the first embodiment of the present invention will be described more specifically. However, the present invention is not limited to those examples.

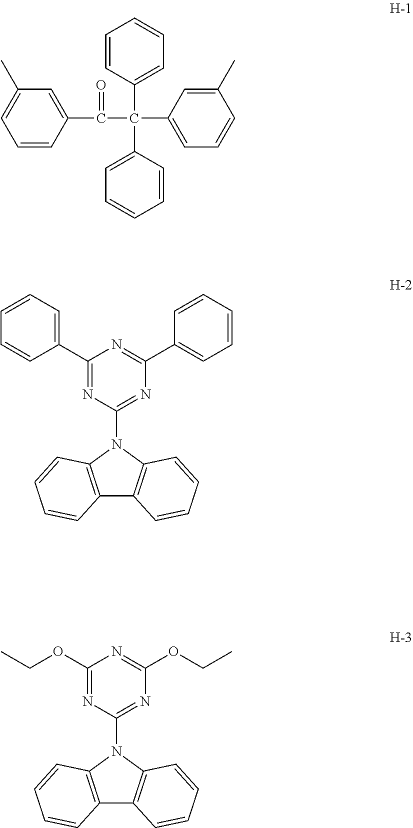

<Hosts in Second Embodiment>

Hosts in the second embodiment are a compound showing thermally activated delayed fluorescence (TADF).

Further, since the hosts in the second embodiment show thermally activated delayed fluorescence, a gap between a level of the lowest triplet excited state and a level of the lowest singlet excited state is small, resulting in expression of an inverse intersystem crossing phenomenon between the two states.

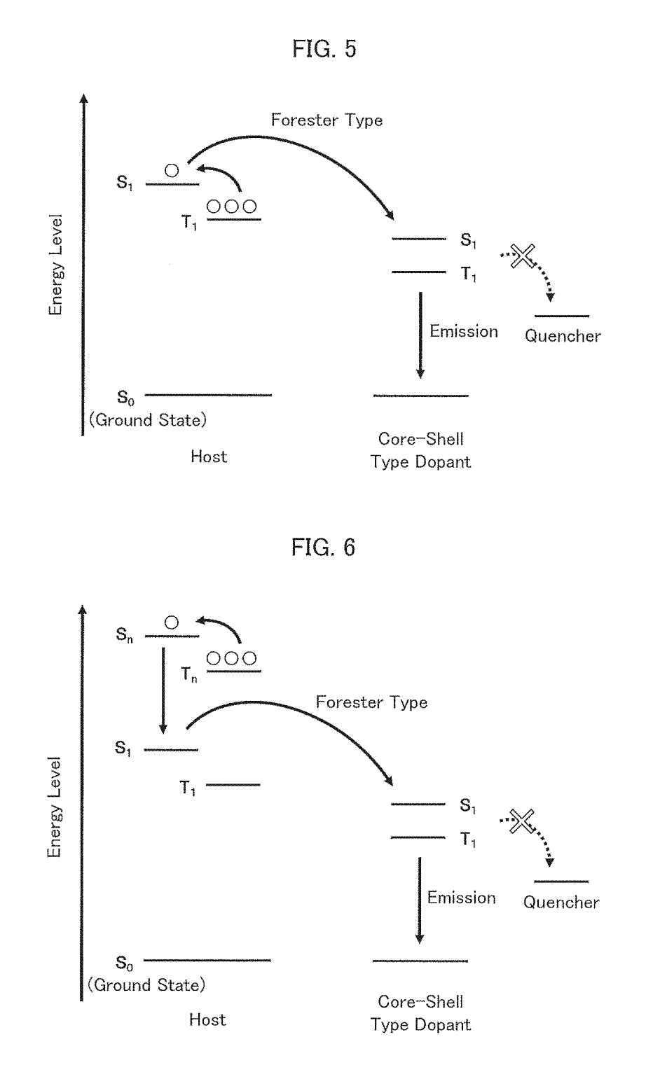

Therefore, as shown in FIG. 5, use of the hosts in the second embodiment enables transfer of the triplet exciton energy (i.e., all or a part) of the lowest triplet excited state (Ti) to the lowest singlet excited state (Si). Further, the exciton energy is transferred via Forster energy transfer from the lowest singlet excited sate to the core-shell type dopant.

Here, a compound showing thermally activated delay fluorescence is not particularly limited, but includes a compound described in Adv. Mater., 2014, DOI:10, 1002/adma., 2014. 02532.

Next, examples of the hosts in the second embodiment of the present invention will be described. However, the present invention is not limited to those examples.

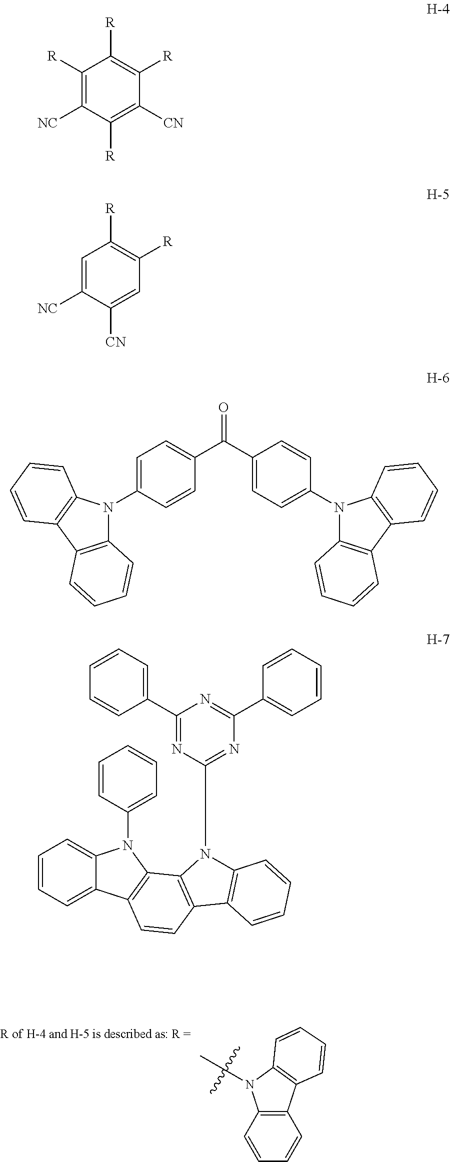

<Hosts in Third Embodiment>

Hosts in the third embodiment is a compound expressing an inverse intersystem crossing phenomenon between the singlet excited state showing a level higher than the lowest singlet excited state and the triplet excited state showing a level higher than the lowest triplet excited state (i.e., iST compound (inverted Singlet-Triplet).

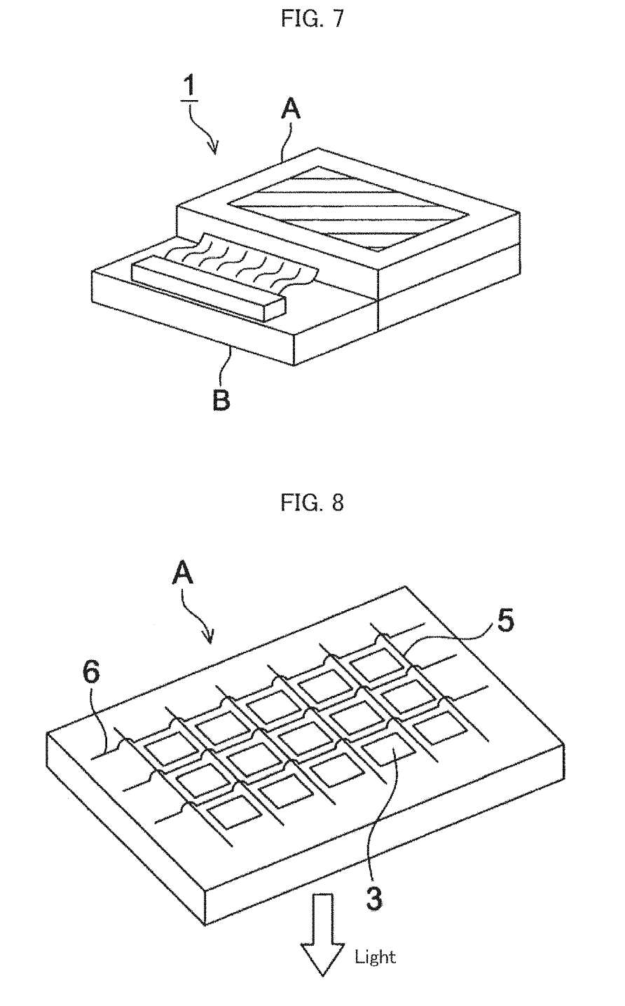

As shown in FIG. 6, use of the hosts in the third embodiment makes the triplet exciton energy (i.e., all or a part) in the triplet excited state (Tn) transfer to the singlet excited state (Sn), and transfer to the lowest singlet excited state (Si). After that, the resulting energy of the exciton further transfers in the Forester energy transfer from the lowest singlet excited state to the core-shell type dopant.

An iST compound is not particularly limited, but includes, for example, a compound described in J. Mater. Chem., C, 2015, 3, 870-878.

Next, examples of the hosts in the third embodiment will be described more specifically. However, the present invention is not limited to those examples.

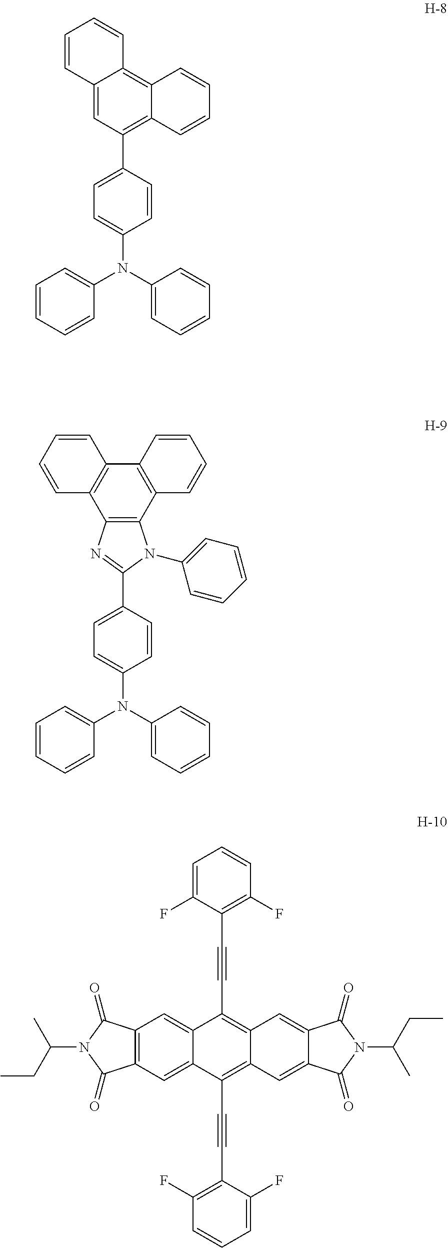 [SMILES: c1ccc(N(c2ccccc2)c2ccc(-c3cc4ccccc4c4ccccc34)cc2)cc1 ; c1ccc(N(c2ccccc2)c2ccc(-c3nc4c5ccccc5c5ccccc5c4n3-c3ccccc3)cc2)cc1 ; CCC(C)n1c(=O)c2cc3c(C#Cc4c(F)cccc4F)c4cc5c(=O)n(C(C)CC)c(=O)c5cc4c(C#Cc4c(F)cccc4F)c3cc2c1=O]

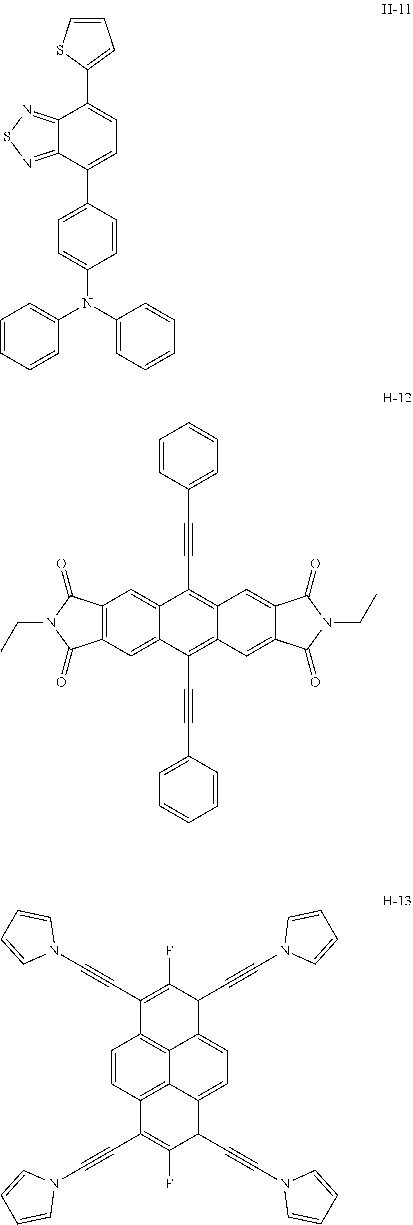 [SMILES: c1ccc(N(c2ccccc2)c2ccc(-c3ccc(-c4cccs4)c4nsnc34)cc2)cc1 ; CCn1c(=O)c2cc3c(C#Cc4ccccc4)c4cc5c(=O)n(CC)c(=O)c5cc4c(C#Cc4ccccc4)c3cc2c1=O ; FC1=C(C#Cn2cccc2)c2ccc3c4c(ccc(c24)C1C#Cn1cccc1)C(C#Cn1cccc1)C(F)=C3C#Cn1cccc1]

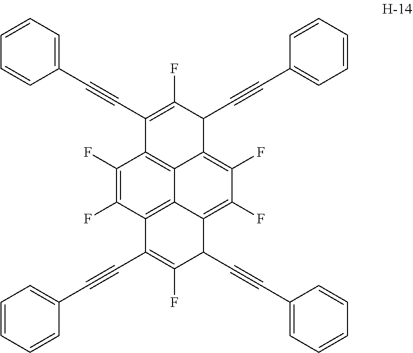 [SMILES: FC1=C(C#Cc2ccccc2)c2c(F)c(F)c3c4c(c(F)c(F)c(c24)C1C#Cc1ccccc1)C(C#Cc1ccccc1)C(F)=C3C#Cc1ccccc1]

Hosts in the fourth embodiment include two types of hosts, and the two types of hosts are combined to form an excited complex (i.e., refer to as an exciplex).

Further, the excited complex formed of the hosts in the fourth embodiment, has a small gap between a level of the lowest triplet excited state and a level of the lowest singlet excited state, similarly to the hosts in the second embodiment showing thermally activated delay fluorescence. Thus, the excited complex in the fourth embodiment expresses an inverse intersystem crossing phenomenon between the two excited stages.

Accordingly, as shown in FIG. 5, use of the hosts in the fourth embodiment makes the triplet exciton energy (i.e., all or a part) in the lowest triplet excited state (Ti) transfer to the lowest singlet excited state (Si), and further the exciton energy transfer in the Forester energy transfer from the lowest singlet excited state to the core-shell type dopant.

A combination of forming the excited complex is not particularly limited, but includes, for example, a combination of compounds described in Adv. Mater., 2014, 26, 4730-4734, and a combination of compounds described in Adv. Mater., 2015, 27, 2378-2383.

Next, examples of the hosts in the fourth embodiment will be described more specifically. However, the present invention is not limited to those examples.

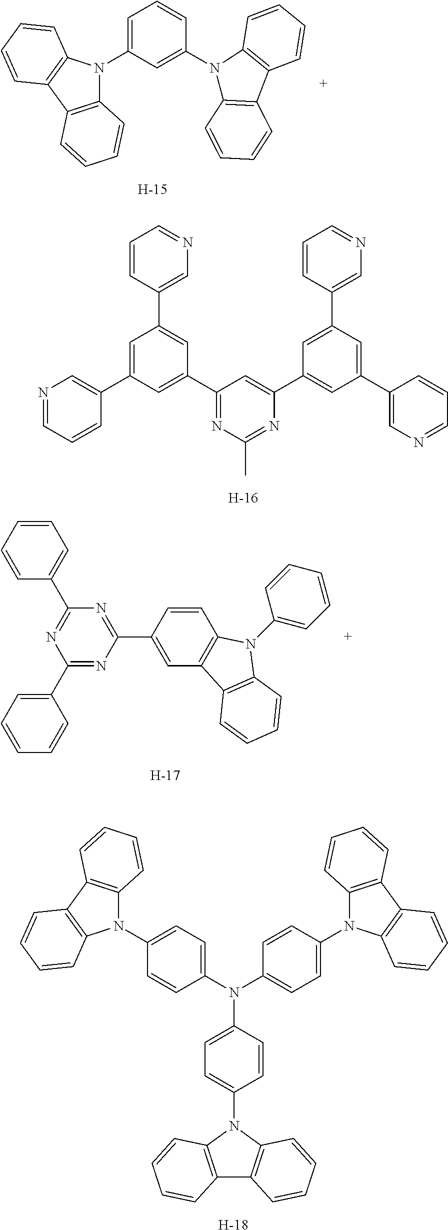

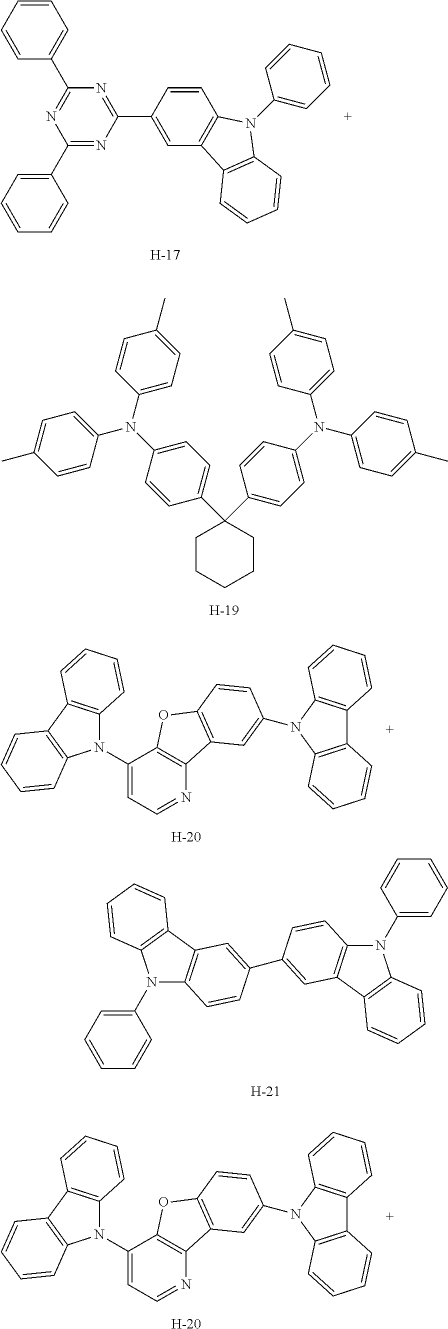

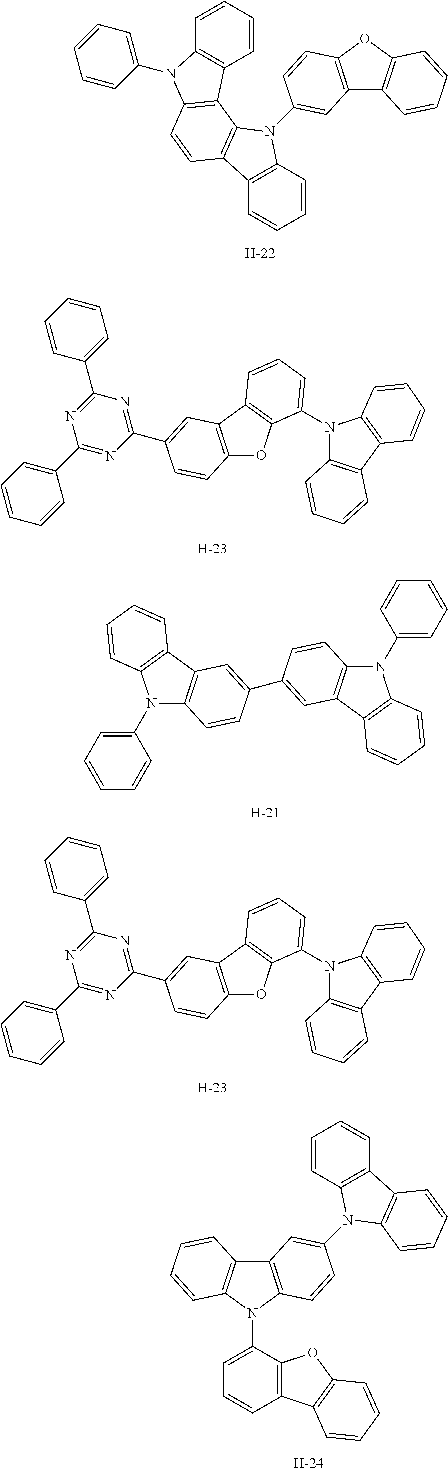

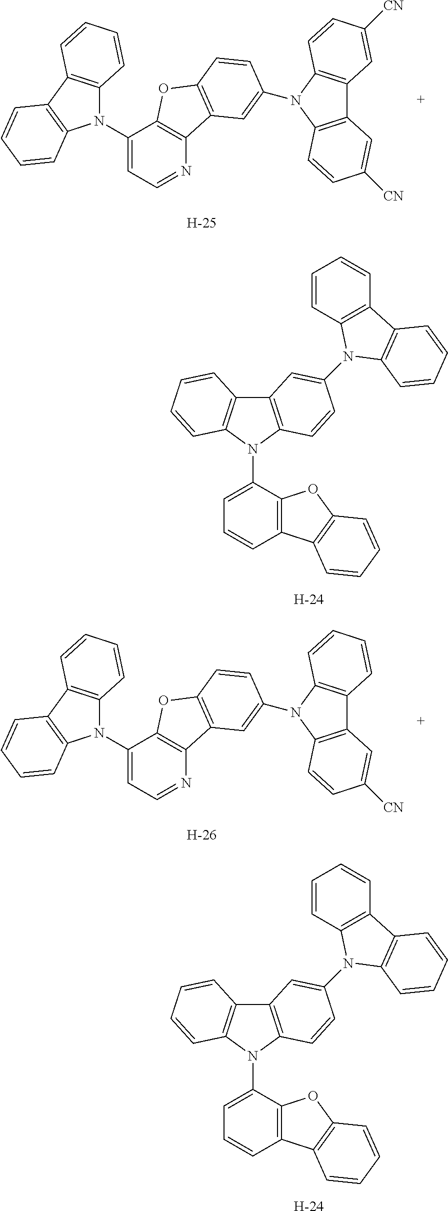

As mentioned above, the “light-emitting metal complexes” and the “hosts” contained in the thin film of the present invention have been described as divided in the plurality of embodiments. Herein, a combination of any “light-emitting metal complex” and any “host” may be usable. Further, the “light-emitting metal complexes” in the above plurality of embodiments may be used in combination, and the “hosts” in the plurality of embodiments may be also used in combination.

Moreover, the thin films of the present invention are applicable to various products, for example, an organic electroluminescent element described hereinafter, and an organic thin film solar cell. Note, the thin films of the present invention may further contain a known compound usually used when applied to each product, besides the above described “light-emitting metal complexes” and “hosts”.

<< >Layers Forming Organic Electroluminescent Element>

A representative formation of element in the organic EL element of the present invention may include the following formations. However, the present invention is not limited to those examples.

(1) Anode/Luminescent Layer/Cathode

(2) Anode/Luminescent Layer/Electron Transport layer/Cathode

(3) Anode/Hole Transport layer/Luminescent Layer/Cathode

(4) Anode/Hole Transport layer/Luminescent Layer/Electron Transport layer/Cathode

(5) Anode/Hole Transport layer/Luminescent Layer/Electron Transport layer/Electron Injection Layer/Cathode

(6) Anode/Hole Injection Layer/Hole Transport layer/Luminescent Layer/Electron Transport layer/Cathode

(7) Anode/Hole Injection Layer/Hole Transport layer/(Electron Blocking Layer)/Luminescent Layer/(Hole Blocking Layer)/Electron Transport layer/Electron Injection Layer/Cathode

Among the above formations, the formation (7) is preferably used. However, the present invention is not limited to thereto.

A luminescent layer of the present invention is formed of a single layer or multiple layers. When there are multiple luminescent layers, a non-luminescent intermediate layer may be provided between the luminescent layers.

Where necessary, a hole blocking layer (or refer to as a hole barrier layer) and an electron injection layer (or refer to as a cathode buffer layer) may be provided between the luminescent layer and the cathode. Further, an electron blocking layer (or refer to as an electron barrier layer) and a hole injection layer (or refer to as an anode buffer layer) may be provided between the luminescent layer and the anode.

An electron transport layer of the present invention is a layer having a function for transporting electrons. In a brad definition, an electron injection layer and a hole blocking layer are included in an electron transport layer. Further, the electron transport layers may be formed of multiple layers.

A hole transport layer of the present invention is a layer having a function for transporting holes. In a broad definition, a hole injection layer and an electron blocking layer are included in a hole transport layer. Further, the hole transport layer may be formed of multiple layers.

In the representative formation of element, a layer other than the anode and cathode is also referred to an “organic layer”.

(Tandem Structure) Further, an organic EL element of the present invention may be an element with a so-called tandem structure in which a luminescent unit including at least one luminescent layer is repeatedly stacked.

A representative formation of element with a tandem structure includes, for example, the following formations.

Anode/First Luminescent Unit/Second Luminescent Unit/Third Luminescent Unit/Cathode

Anode/First Luminescent Unit/Intermediate layer/Second Luminescent Layer/Intermediate layer/Third luminescent Layer/Cathode

Here, the first luminescent unit, the second luminescent unit and the third luminescent unit all may be the same or different each other. Further, two luminescent units may be the same and the remaining one may be different.

Further, the third luminescent layer may not be provided, while another luminescent unit or intermediate layer may be provided between the third luminescent layer and an electrode.

Multiple luminescent layers may be directly stacked, or stacked via an intermediate layer. The intermediate layer generally is referred to an intermediate electrode, an intermediate conductive layer, a charge generation layer, an electron withdrawing layer, a connection layer, and an intermediate insulation layer. As long as such an intermediate layer has a function for feeding holes to an adjacent layer at the cathode side, a known material may be used for the intermediate layer.

A material used for the intermediate layer includes, for example, an electric conductive inorganic layer made of ITO (indium.tin oxides), IZO (indium.inc oxides), Zno₂, Tin N, ZrN, HfN, TiOₓ, VOₓ, CuI, InN, GaN, CuAlO₂, CuGaO₂, SrCu₂O₂, LaB₆, RuO₂, and Al or the like; a bilayer such as Au/Bi₂O₃; SnO₂/Ag/SnO₂, ZnO/Ag/ZnO, Bi₂O₃/Au/Bi₂O₃, TiO₂/TiN/TiO₂, and a multilayer such as TiO₂/ZrN/TiO₂ or the like; an electric conductive organic substance layer such as a fullerlen like C₆₀ and an oligothiophene; and an electric conductive organic compound layer such as a metallo-phthalocyanine; a metal-free phthalocyanine; a metalloporphyrin and a metal-free porphyrin. However, the present invention is not limited to the above materials.

A preferable formation of the luminescent unit includes, for example, a formation in which the cathode and anode are removed from each of the formations (1)˜(7) thus shown as the representative formations of element. However, the present invention is not limited to the above examples.

Examples of tandem type organic EL elements include, for example, formations of elements and constructing materials described in: U.S. Pat. Nos. 6,337,492, 7,420,203, 7,473,923, 6,872,472, 6,107,734, 6,337,492, International Publication No. 2005/009087, Japanese Unexamined Application Publication No. 2006-228712, Japanese Unexamined Application Publication No. 2006-49394, Japanese Unexamined Application Publication No. 2006-49396, Japanese Unexamined Application Publication No. 2011-96679, Japanese Unexamined Application Publication No. 2005-340187, Japanese Patent Publication No. 4711424, Japanese Patent Publication No. 3496681, Japanese Patent Publication No. 3884564, Japanese Patent Publication No. 4213169, Japanese Patent Application Publication No. 2010-192719, Japanese Patent Application Publication No. 2009-076929, Japanese Patent Application Publication No. 2008-078414, Japanese Patent Application Publication No. 2007-059848, International Publication No. 2005/094130. Note, the present invention is not limited to the above examples.

Next, the respective layers forming the organic EL element of the present invention will be described more specifically.

<<Luminescent Layer>>

A luminescent layer used in the present invention is a layer in which electrons and holes injected from an electrode or an adjacent layer are recombined, thereby providing a luminescent field via excitons. A luminescent part may be present inside a luminescent layer, or on an interface between a luminescent layer and an adjacent layer. Here, the luminescent layer of the present invention is formed of the above described “thin film”.

Note, a formation of the luminescent layer used in the present invention is not specifically limited as long as the luminescent layer satisfies requirements for the thin film thus defined hereinbefore in the present invention.

A total thickness of the luminescent layer is not particularly limited. However, preferably the total thickness is adjusted into the range from 2 nm to 5 □m, more preferably from 2 nm to 500 nm, and further more preferably from 5 nm to 200 nm, from the viewpoint of securing homogeneity of the thin film to be formed, preventing an unnecessary high voltage at the time of emission from being applied thereto, and simultaneously improving stability of a luminescent color against a driven current.

Further, a thickness of each luminescent layer in the present invention is preferably adjusted into the range from 2 nm to 1 □m, more preferably from 2 to 200 nm, and further more preferably from 3 nm to 150 nm.

The luminescent layer of the present invention is formed containing the above described “light-emitting metal complex” (i.e., a core-shell type dopant) and “host”. Note, the luminescent layer of the present invention may contain “(1) a luminescent dopant, (1.1) a phosphorescent dopant, (1.2) a fluorescent dopant” and “(2) a host compound”, in the range without deteriorating effects of the present invention.

(1) Luminescent Dopant

Next, a luminescent dopant used in the present invention will be described more specifically.

As the luminescent dopant, a phosphorescence emitting dopant (also refer to as a phosphorescent dopant or a phosphorescent compound), and a fluorescence emitting dopant (also refer to as a fluorescent dopant or a fluorescent compound) may be used.

Further, as the luminescent dopant used in the present invention, multiple types of dopants may be used in combination. A combination of dopants having different structures, and a combination of a fluorescence emitting dopant and a phosphorescence emitting dopant may be used. Those combinational usages enable the dopant to provide an optional luminescent color.

Luminescent colors of the organic EL element and the thin film in the present invention are determined by the color thus obtained when data measured by the spectral radiance meter CS-1000 (Konica Minolta, Inc.) are applied to the CIE chromaticity coordinate via referring to FIG. 4.16, in p. 108 of “The Color Science Handbook, New Edition” (edited by The Color Science Association of Japan, The University of Tokyo Press, 1985).

In the present invention, it is preferable that a single or multiple luminescent layer(s) contain multiple luminescent dopants displaying different luminescence color, thereby to display white luminescence.

Here, a combination of luminescent dopants displaying a white color is not specifically limited. However, such a combination includes, for example, a combination of luminescent dopants displaying blue and orange colors, and a combination of those displaying blue, green and red colors.

A white color of the organic EL element in the present invention is not specifically limited, and may be an orangish-white or a bluish white color. However, preferably the chromaticity in the CIE1931 colorimetric system at 1000 cd/m² when front luminescence at a 2-degree viewing angle is measured by the above mentioned method is in the range of x=0.39±0.09, and y=0.38±0.08.

(1.1) Phosphorescence Emitting Dopants

Next, a phosphorescence emitting dopant used in the present invention (hereinafter, also refer to as a “phosphorescent dopant”) will be described more specifically.

A phosphorescent dopant used in the present invention is a compound from which luminescence with respect to a triplet excited state is observed. More specifically, the phosphorescent dopant is defined as a compound emitting phosphorescence at room temperature (25° C.) and a phosphorescence quantum yield thereof is 0.01 or more at 25° C. Herein, a preferable phosphorescence quantum yield is 0.1 or more.

A phosphorescence quantum yield in the present invention is measured by the method described in The Experimental Chemistry Course, 4^{th} edition, Spectroscopy II, p. 398 (1992, Maruzen Publishing Co., Ltd.). A phosphorescence quantum yield in a solution is measured using various solvents. Here, the phosphorescent dopant of the present invention just has to achieve the above mentioned phosphorescence quantum yield (i.e., 0.01 or more) in any one of optional solvents.

Principally, there are two types of luminescence of the phosphorescent dopant. One is an energy transfer type in which recombination of carriers occurs on a host compound to which carries are transferred, thereby generating an excited state of the host compound. Then, transfer of energy thus generated from the excited state affords luminescence from the phosphorescent dopant.

The other is a carrier trap type in which a phosphorescent dopant becomes a carrier trap so as to cause recombination of carriers on the phosphorescent dopant. Then, the resulting phosphorescent dopant affords luminescence. Either of the types has to satisfy the conditions that energy in the excited state of the phosphorescent dopant is lower than that of the host compound.

A phosphorescent dopant usable in the present invention may be appropriately selected from known dopants used for a luminescent layer of typical organic EL elements.

Examples of known phosphorescent dopants usable in the present invention include the compounds described in the following documents:

Nature, 395, 151 (1998), Appl. Phys. Lett., 78, 1622 (2001); Adv. Mater., 19, 739 (2007); Chem. Mater., 17, 3532 (2005); Adv. Mater., 17, 1059 (2005); International Publication No. 2009/100991; International Publication No. 2008/101842; International Publication No. 2003/040257; US Patent Application Publication No. 2006/835496; US Patent Application Publication No. 2006/0202194; US Patent Application Publication No. 2007/0087321; US Patent Application Publication No. 2005/0244673; Inorg. Chem., 40, 1704 (2001); Chem. Mater., 16, 2480 (2004); Adv. Mater., 16, 2003 (2004); Angew. Chem. Int. Ed., 2006, 45, 7800; Appl. Phys. Lett., 86, 153505 (2005); Chem. Lett., 34, 592 (2005); Chem. Commun., 2906 (2005); Inorg. Chem., 42, 1248 (2003); International Publication No. 2009/050290; International Publication No. 2002/015645; International Publication No. 2009/000673; US Patent Application Publication No. 2002/0034656; U.S. Pat. No. 7,332,232; US Patent Application Publication No. 2009/0108373; US Patent Application Publication No. 2009/0039776; US Patent Publication U.S. Pat. Nos. 6,921,915; 6,687,266; US Patent Application Publication No. 2007/0190359; US Patent Application Publication No. 2006/0008670; US Patent Application Publication No. 2009/0165846; US Patent Application Publication No. 2008/0015355; U.S. Pat. Nos. 7,250,226; 7,396,598; US Patent Application Publication No. 2006/0263635; US Patent Application Publication No. 2003/01386357; US Patent Application Publication No. 2003/0152802; U.S. Pat. No. 7,090,928; Angew. Chem. Int. Ed., 47, 1 (2008); Chem. Mater., 18, 5119 (2006); Inorg. Chem., 46, 4308 (2007); Organometallics 23, 3745 (2004); Appl. Phys. Lett., 74, 1361 (1999); International Publication No. 2002/002714; International Publication No. 2006/009024; International Publication No. 2006/056418; International Publication No. 2005/123873; International Publication No. 2007/004380; International Publication No. 2006/082742; US Patent Application Publication No. 2005/0260441; U.S. Pat. Nos. 7,393,599; 7,534,505; U.S. Pat. No. 7,445,855; US Patent Application Publication No. 2007/0190359; US Patent Application Publication No. 2008/0297033; U.S. Pat. No. 7,338,722; US Patent Application Publication No. 2002/0134984; U.S. Pat. No. 7,279,704; US Patent Application Publication No. 2006/098120; US Patent Application Publication No. 2006/103874; International Publication No. 2005/076380; International Publication No. 2010/032663; International Publication No. 2008/140115; International Publication No. 2007/052431; International Publication No. 2011/134013; International Publication No. 2011/157339; International Publication No. 2010/086089; International Publication No. 2009/113616; International Publication No. 2012/020327; International Publication No. 2011/051404; International Publication No. 2011/004639; International Publication No. 2011/073149; US Patent Application Publication No. 2012/228583; US Patent Application Publication No. 2012/212126; Japanese Unexamined Patent Application Publication No. 2012-069737; Japanese Unexamined Patent Application Publication No. 2012-195554; Japanese Unexamined Patent Application Publication No. 2009-114086; Japanese Unexamined Patent Application Publication No. 2003-81988; Japanese Unexamined Patent Application Publication No. 2002-302671 and Japanese Unexamined Patent Application Publication No. 2002-363552 or the like.

Among all the examples, a preferable phosphorescent dopant includes an organic metal complex having Ir as a center metal. A more preferable phosphorescent dopant is a complex having at least one coordination form selected from a metal-carbon bond, a metal-nitrogen bond, and a metal-oxygen bond.

(1.2) Fluorescence Emitting Dopant

A fluorescence emitting dopant (hereinafter, also refer to as a “fluorescent dopant” used in the present invention will be described more specifically.

A fluorescent dopant used in the present invention is a compound capable of emitting light with respect to a singlet excited state, and not particularly limited as long as emission with respect to the singlet excited state is observed.

The fluorescent dopant used in the present invention includes, for example, an anthracene derivative, a pyrene derivative, a chrysene derivative, a fluoranthrene derivative, a perylene derivative, a fluorene derivative, an arylacetylene derivative, a styrylarylene derivative, a styrylamine derivative, an arylamine derivative, a boron complex, a coumarin derivative, a pyrane derivative, a cyanine derivative, a croconium derivative, a squarylium derivative, an oxobenzanthracene derivative, a fluorescein derivative, a rhodamine derivative, a pyrylium derivative, a perylene derivative, a polythiophene derivative, or a rear earth complex compound or the like.

Further, recently a luminescent dopant using delayed fluorescence has been developed. Such a luminescent dopant may be used for the fluorescent dopant.

Here, examples of the luminescent dopant using delayed fluorescence include, for example, compounds described in International Publication No. 2011/156793, Japanese Unexamined Patent Application Publication No. 2011-213643 and Japanese Unexamined Patent Application Publication No 2010-93181. However, the present invention is not limited to those examples.

(2) Host Compound

A host compound used in the present invention is a compound mainly injecting and transporting charges in the luminescent layer. Luminescence of the host compound is not substantially observed in the organic EL element.

Preferably, the host compound has a phosphorescence quantum yield at room temperature (25° C.) is less than 0.1, more preferably less than 0.01.

Further, preferably excited state energy of the host compound is higher than that of the luminescent dopant included in the same layer.

Moreover, the host compound may be used alone, or in combination with multiple types of compounds. Use of multiple types of host compounds may control charge transport, thereby allowing the organic EL element to be highly efficient.

A host compound usable ion the present invention is not particularly limited. Thus, a compound conventionally used in the organic EL elements may be used therefor. Such a host compound may be a low molecular compound or a polymer compound having a repeated unit, or a compound having a reactive group such as a vinyl group and an epoxy group.

Preferably, a known host compound has a high glass transition temperature (T_{g}) from the viewpoint of having ability of hole or electron transport and preventing a wavelength of luminescence from becoming longer, and further stably driving the organic EL element against heat during the high-temperature operation and generated during the element operation. Preferably, T_{g} is 90° C. or more, more preferably 120° C. or more.

Here, a glass transition point (T_{g}) is a value obtained by a method using Differential Scanning Colorimetry (DSC) and following JIS-K-7121.

Examples of a known host compound used in the organic EL element of the present invention include compounds described in the following documents. However, the present invention is not limited to those compounds.

Japanese Unexamined Patent Application Publication No. 2001-257076, Japanese Unexamined Patent Application Publication No. 2002-308856, Japanese Unexamined Patent Application Publication No. 2001-313179, Japanese Unexamined Patent Application Publication No. 2002-319494, Japanese Unexamined Patent Application Publication No. 2001-357977, Japanese Unexamined Patent Application Publication No. 2002-334786, Japanese Unexamined Patent Application Publication No. 2002-8860, Japanese Unexamined Patent Application Publication No. 2002-334787, Japanese Unexamined Patent Application Publication No. 2002-43056, Japanese Unexamined Patent Application Publication No. 2002-33479, Japanese Unexamined Patent Application Publication No. 2002-75645, Japanese Unexamined Patent Application Publication No. 2002-338579, Japanese Unexamined Patent Application Publication No. 2002-105445, Japanese Unexamined Patent Application Publication No. 2002-343568, Japanese Unexamined Patent Application Publication No. 2002-141173, Japanese Unexamined Patent Application Publication No. 2002-352957, Japanese Unexamined Patent Application Publication No. 2002-203683, Japanese Unexamined Patent Application Publication No. 2002-363227, Japanese Unexamined Patent Application Publication No. 2002-231453, Japanese Unexamined Patent Application Publication No. 2003-3165, Japanese Unexamined Patent Application Publication No. 2002-234888, Japanese Unexamined Patent Application Publication No. 2003-27048, Japanese Unexamined Patent Application Publication No. 2002-255934, Japanese Unexamined Patent Application Publication No. 2002-260861, Japanese Unexamined Patent Application Publication No. 2002-280183, Japanese Unexamined Patent Application Publication No. 2002-299060, Japanese Unexamined Patent Application Publication No. 2002-302516, Japanese Unexamined Patent Application Publication No. 2002-305083, Japanese Unexamined Patent Application Publication No. 2002-305084, Japanese Unexamined Patent Application Publication No. 2002-308837, US Patent Application Publication No. 2003/0175553, US Patent Application Publication No. 2006/0280965, US Patent Application Publication No. 2005/0112407, US Patent Application Publication No. 2009/0017330, US Patent Application Publication No. 2009/0030302, US Patent Application Publication No. 2005/0238919, International Publication No. 2001/039234, International Publication No. 2009/021126, International Publication No. 2008/056746, International Publication No. 2004/093207, International Publication No. 2005/089025, International Publication No. 2007/063796, International Publication No. 2007/063754, International Publication No. 2004/107822, International Publication No. 2005/030900, International Publication No. 2006/114966, International Publication No. 2009/086028, International Publication No. 2009/003898, International Publication No. 2012/023947, Japanese Unexamined Application Publication No. 2008-074939, Japanese Unexamined Application Publication No. 2007-254297, and European Patent Publication No. 2034538 or the like.

<<Electron Transport Layer>>

An electron transport layer in the present invention is made of a material having a function for transporting electrons, and just has to have a function for transporting electrons injected from a cathode to a luminescent layer.

A total thickness of the electron transport layer used in the present invention is not specifically limited. However, typically the total thickness is preferably set into the range from 2 nm to 5 □m, more preferably from 2 nm to 500 nm, further more preferably from 5 nm to 200 nm.

Further, it is known that in the organic EL element, when light generated in the luminescent layer is extracted from an electrode, light directly extracted from the luminescent layer and other light extracted after reflected by an electrode arranged opposite to the electrode from which light is directly extracted interfere each other. When light is reflected by a cathode, appropriate adjustment of the total thickness of the electron transport layer in the range from 5 nm to 1 □m enables the interference effect to be efficiently utilized.

Meanwhile, an increase in the thickness of the electron transport layer facilitates an increase in the voltage. Thus, especially when the thickness of the layer is large, preferably the electron mobility in the electron transport layer is controlled to 10⁻⁵ cm²/Vs or more.

A material used for the electron transport layer (hereinafter, refer to as an electron transport material) just has to include one of injection or transport ability for electrons and barrier ability for holes. An optional material selected from conventionally known compounds may be used for the electron transport material.

For example, such a compound includes nitrogen-containing aromatic heterocyclic derivatives (e.g., a carbazole derivative, an azacarbazole derivative (i.e., at least one carbon atom of the carbazole ring is replaced by a nitrogen atom), a pyridine derivative, a pyrimidine derivative, a pyrazine derivative, a pyridazine derivative, a triazine derivative, a quinoline derivative, a quinoxaline derivative, a phenanthroline derivative, an azatriphenylene derivative, an oxazole derivative, a thiazole derivative, an oxadiazole derivative, a thiadiazole derivative, a triazole derivative, a benzimidazole derivative, a benzoxazole derivative, and a benzothiazole derivative), a dibenzofuran derivative, a dibenzothiophene derivative, a silole derivative, and an aromatic hydrocarbon derivative (e.g., a naphthalene derivative, an anthracene derivative and a triphenylene derivative) or the like.

Further, the following compounds may be used as the electron transport material:

Metal complexes having a quinolinol skeleton or a dibenzoquinolinol skeleton in the ligand, for example, tris(8-qunolinol)aluminum (Alq), tris(5,7-dichloro-8-quinolinol)aluminum, tris(5,7-dibromo-8-quinolinol)aluminum, tris(2-methyl-8-quinolinol)aluminum, tris(5-methyl-8-quinolinpol)aluminum, bis(8-quinolinol)zinc (Znq), and a metal complex where the center metal of the above described metal complexes is replaced by In, Mg, Cu, Ca, Sn Ga, or Pb).

Further, metal-free or metal phthalocyanine, or a derivative in which the end of such phthalocyanine is substituted with an alkyl group or a sulfone acid group or the like can be preferably used as the electron transport material. Moreover, a distyrylpyrazine derivative previously exemplified as a material of the luminescent layer cab be also used as the electron transfer material. Furthermore, similarly to the hole injection layer and the hole transport layer, inorganic semiconductors such as n-type Si and n-type SiC can be used as the electron transport material.

Further, a polymer material formed by inserting the above materials into the polymer chain, or a polymer of which main chain is made of the above materials can be used as the electron transport material.

In the electron transport layer used in the present invention, a dope material may be doped as a guest material on the electron transport layer so as to form an electron transport layer with a high n-property (i.e., electron rich). Such a dope material includes an n-type dopant such as a metal compound like a metal complex and a halogenated metal. Examples of the electron transport layers having the above formations are disclosed in the following documents, for example, Japanese Unexamined Patent Application Publication No. H4-297076, Japanese Unexamined Patent Application Publication No. H10270172, Japanese Unexamined Patent Application Publication No. 2000-196140, Japanese Unexamined Patent Application Publication No. 2001-102175, and J. Appl. Phys., 95, 5773 (2004).

Examples of known and preferable electron transport materials used for the organic EL element of the present invention include compounds described in the following documents. However, the present invention is not limited to those examples.

U.S. Pat. Nos. 6,528,187, 7,230,107, US Patent Application Publication No. 2005/0025993, US Patent Application Publication No. 2004/0036077, US Patent Application Publication No. 2009/0115316, US Patent Application Publication No. 2009/0101870, US Patent Application Publication No. 2009/0179554, International Publication No. 2003/060956, International Publication No. 2008/132085, Appl. Phys. Lett., 75, 4 (1999), Appl. Phys. Lett., 79, 449 (2001), Appl. Phys. Lett., 81,162 (2002), Appl. Phys. Lett., 81, 162 (2002), Appl. Phys. Lett., 81, 162 (2002), Appl. Phys. Lett., 79, 156 (2001), U.S. Pat. No. 7,964,293, US Patent Application Publication No. 2009/030202, International Publication No. 2004/080975, International Publication No. 2004/063159, International Publication No. 2005/085387, International Publication No. 2006/067931, International Publication No. 2007/086552, International Publication No. 2008/114690, International Publication No. 2009/069442, International Publication No. 2009/066779, International Publication No. 2009/054253, International Publication No. 2011/086953, International Publication No. 2010/150593, International Publication No. 2010/047707, European Patent Publication No. 2311826, Japanese Unexamined Patent Application Publication No. 2010-251675, Japanese Unexamined Patent Application Publication No. 2009-209133, Japanese Unexamined Patent Application Publication No. 2009-124114, Japanese Unexamined Patent Application Publication No. 2008-277810, Japanese Unexamined Patent Application Publication No. 2006-156445, Japanese Unexamined Patent Application Publication No. 2005-340122, Japanese Unexamined Patent Application Publication No. 2003-45662, Japanese Unexamined Patent Application Publication No. 2003-31367, Japanese Unexamined Patent Application Publication No. 2003-28227, and International Publication No. 2012/115034 or the like.

More preferable electron transport materials in the present invention include a pyridine derivative, a pyrimidine derivative, a pyrazine derivative, a triazine derivative, a dibenzofuran derivative, a dibenzothiophene derivative, a carbazole derivative, an azacarbazole derivative, and a benzimidazole derivative.

The electron transport material may be used alone, or in combination with multiple types of materials.

<<Hole Blocking Layer>>

In a broad definition, a hole blocking layer is a layer having a function of an electron transport layer. Preferably, a hole blocking layer is formed of a material having ability for transporting electrons as well as poor ability for transporting holes. Transporting electrons as well as blocking holes can improve a recombination probability of electrons and holes.

Further, a formation of the electron transfer layer as mentioned hereinbefore may be utilized as a hole blocking layer of the present invention, where necessary.

A hole blocking layer provided in the organic EL element of the present invention is preferably arranged adjacent to a luminescent layer at a cathode side.

A thickness of the hole blocking layer used in the present invention is preferably set into the range from 3 nm to 100 nm, more preferably from 5 nm to 30 nm.

As a material used for the hole blocking layer, preferably used is a material used for the electron transport layer as mentioned hereinbefore. Further, a material used for the host compound as mentioned before is preferably used for the hole blocking layer.

<<Electron Injection Layer>>

An electron injection layer (also refer to as a “cathode buffer layer) used in the present invention is a layer provided between the cathode and the luminescent layer in order to decrease the driving voltage and improve the luminescent brightness. Such a layer is described in detail in “Organic EL Element and Frontier of Industrialization (NTS Inc., Nov. 30, 1998)”, Vol. 2, Chapter 2, “Electrode Material” (pp. 123-166).

In the present invention, the electron injection layer may be arranged as necessary, and provided between the cathode and the luminescent layer or between the cathode and the electron transport layer as described hereinbefore.

Preferably, the electron injection layer is an extremely thin layer, and has a thickness in the range from 0.1 nm to 5 nm depending on the raw material thereof. Herein, the electron injection layer may be an ununiform film where constituent materials are intermittently present.

The electron injection layers are described in detail in Japanese Unexamined Patent Application Publication No. H6-325871, Japanese Unexamined Patent Application Publication No. H9-17574 and Japanese Unexamined Patent Application Publication No. H10-74586. Examples of the material preferably used for the electron injection layer include a metal represented by strontium and aluminum; an alkali metal compound represented by lithium fluoride, sodium fluoride, potassium fluoride; an alkali earth metal compound represented by magnesium fluoride and potassium fluoride; a metal oxide represented by aluminum oxide; and a metal complex represented by lithium 8-hidroxyquinolate (Liq). Further, the above described electron transfer materials may be also used for the electron injection layer.

Moreover, a material used for the electron injection layer may be used alone, or in combination with multiple types of materials.

<<Hole Transport Layer>>

A hole transport layer in the present invention is formed of a material having a function for transporting holes, and just has to have a function for transporting holes thus injected from the anode into the luminescent layer.

A total thickness of the hole transport layer used in the present invention is not particularly limited. However, usually the thickness is in the range from 5 nm to 5 □m, preferably from 2 nm to 500 nm, and more preferably from 5 nm to 200 nm.

A material used for the hole transport layer (hereinafter, refer to as a hole transport material) just has to possess any one of injection or transport ability of holes, or barrier ability of electrons. Any one selected from conventionally known compounds used for the transport layer may be used for the material.

For example, such a material includes a porphyrin derivative, phthalocyanine derivative, an oxazole derivative, an oxadiazole derivative, a triazole derivative, an imidazole derivative, a pyrazoline derivative, a pyrazoline derivative, a phenylenediamine derivative, a hydrazone derivative, a stilbene derivative, a polyarylalkane derivative, a triarylamine derivative, a carbazole derivative, an indolocarbazole derivative, an isoindole derivative, an acene derivative such as anthracene and naphthalene, a fluorene derivative, and a polymer material or an oligomer in which polyvinylcarbazole and/or an aromatic amine are introduced into a main chain or a side chain, polysilane, a conductive polymer or oligomer (e.g., PEDOT/PSS, an aniline based co-polymer, a polyaniline, and a polythiophene) or the like.

Such a triarylamine derivative includes a benzidine type compound represented by D-NPD, a star-burst type compound represented by MTDATA, and a compound in which a triarylamine coupled core ahs fluorene or anthracene.

Further, a hexaazatriphenylene derivative described in Japanese Unexamined Patent Application Publication No. 2003-519423 (Translation of PCT Application) and Japanese Unexamined Patent Application Publication No. 2006-135145 may be used as the hole transport material.

Moreover, usable is a hole transport layer to which an impurity has been doped to have a high p-property. Such an example includes hole transport layers described in Japanese Unexamined Patent Application Publication No. H4-297076, Japanese Unexamined Patent Application Publication No. 2000-196140, Japanese Unexamined Patent Application Publication No. 2001-102175, and J. Appl. Phys., 95, 5773 (2004).

Furthermore, a so-called p-type hole transport material and inorganic compounds such as p-type Si and p-type SiC, described in the following documents: Japanese Unexamined Patent Application Publication No. H11-251067, and J. Huang, et. al., Applied Physics Letters, 80 (2002), p. 139. Further, an ortho-metalized organometallic complex having Ir or Pt for the center metal as represented by Ir(ppy)₃ is preferably utilized therefor.

As the hole transport material, the above described materials may be used. Preferably, especially usable are a triazole amine derivative, a carbazole derivative, an indolocarbazole derivative, an azatriphenylene derivative, an organometallic complex, and a polymer material or an oligomer in which an aromatic amine is introduced into the main chain or the side chain thereof.

Examples of the known and preferable hole transport material used for the organic EL element of the present invention include compounds described in the following documents besides the above cited documents. However, the present invention is not limited to those examples.

For example, Appl. Phys. Lett., 69,2160 (0996); J. Lumin., 72-74, 985 (1997); Appl. Phys. Lett., 78, 673 (2001); Appl. Phys. Lett., 90, 183503 (2007); Appl. Phys. Lett., 51, 913 (1987); Synth. Met., 87, 171 (1997); Synth. Met., 111, 421 (2000); SID Symposium Digest, 37, 923 (2006); J. Mater. Chem., 3, 319 (1993); Adv. Mater., 6, 677 (1994); Chem. Mater., 15, 3148 (2003); US Patent Application Publication No. 2003/0162053; US Patent Application Publication No. 2002/0158242; US Patent Application Publication No. 2006/0240279; US Patent Application Publication No. 2008/0220265; U.S. Pat. No. 5,061,569; International Publication No. 2007/002683; International Publication No. 2009/018009, European Patent Publication No. 650955; US Patent Application Publication No. 2008/0124575; US Patent Application Publication No. 2007/0278938; US Patent Application Publication No. 2008/0106190; US Patent Application Publication No. 2008/0018221; International Publication No. 2012/115034; Japanese Unexamined Patent Application Publication (Translation of PCT Application) No. 2003519432, Japanese Unexamined Patent Application Publication No. 2006-135145, and U.S. patent application Ser. No. 13/585,981 or the like.

The hole transport material may be used alone, or in combination with multiple types of materials.

<<Electron Blocking Layer>>

In a broad definition, an electron blocking layer is a layer having ability of the hole transport layer. Preferably, such an electron blocking layer is formed of a material having ability for transporting holes as well as poor ability for transporting electrons. Transporting holes as well as blocking electrons can increase a recombination probability between electrons and holes.

Further, a formation of the above described hole transport layer may be applied to the electron blocking layer used in the present invention, as necessary.

Preferably, the electron blocking layer provided in the organic EL element of the present invention is arranged adjacent to the luminescent layer at an anode side.

Preferably, a thickness of the electron blocking layer used in the present invention is set into the range from 3 to 100 nm, more preferably from 5 to 30 nm.

As a material used for the electron blocking layer, materials used for the above described hole transport layer are preferably utilized. Further, materials used as the above described host compounds are preferably used for the electron blocking layer.

<<Hole Injection Layer>>

A hole injection layer (also refer to as an “anode buffer layer”) used in the present invention is a layer provided between the anode and the luminescent layer in order to decrease a driving voltage and increase luminescent brightness. Such a hole injection layer is described in detail in “Organic EL Element and Frontier of Industrialization (NTS Inc., Nov. 30, 1998)”, Vol. 2, Chapter 2, “Electrode Material” (pp. 123-166).

In the present invention, the hole injection layer may be provided as necessary and present between the anode and the luminescent layer or between the anode and the hole transport layer as mentioned hereinbefore.

Such a hole injection layer is described in detail in Japanese Unexamined Patent Application Publication No. H9-45479, Japanese Unexamined Patent Application Publication No. H9-260062 and Japanese Unexamined Patent Application Publication No. H8-288069. A material used for the hole injection layer includes, for example, the materials used for the hole transport layer.

Among those materials, preferable ones include a phthalocyanine derivative represented by copper phthalocyanine; a hexaazatriphenylene derivative described in Japanese Unexamined Patent Application Publication (Translation of PCT Application) No. 2003-519432 and Japanese Unexamined Patent Application Publication No. 2006-135145; a metal oxide represented by vanadium oxide; amorphous carbon; an electric conductive polymer such as polyaniline (emeraldine) and polythiophene; an ortho-metalated complex represented by tris(2-phenylpyridine) iridium complex; and a triarylamine derivative or the like.

A material used for the hole injection layer may be used alone, or in combination with multiple types of materials.

<<Contained Compound>>

The organic layer in the present invention may further include other contained compounds.

Such a contained compound includes, for example, a halogen element or a halogenated compound; alkali metal or an alkali earth metal such as Pd, Ca and Na; a transition metal compound, complex and salt or the like.

A content of the contained compound may be optionally determined. However, a preferable content thereof is 1000 ppm or less per total mass % of the layer containing the compounds, more preferably 500 ppm or less, further more preferably 50 ppm or less.

Note, the content may be out of the above defined range for a purpose of improving the transport ability of electrons and holes, and for a purpose of advantageously taking well of the energy transfer of excitons.

<<Method for Forming Organic Layer>>

Next, a method for forming organic layers (i.e., a hole injection layer, a hole transport layer, an electron blocking layer, a luminescent layer, a hole blocking layer, an electron transport layer, and an electron injection layer) used in the present invention will be described more specifically.

A method for forming organic layers used in the present invention is not particularly limited, and conventionally known methods, for example, a vacuum vapor deposit method, a wet method (or refer to as a wet process) may be used therefor. Here, preferably an organic layer is a layer formed by a wet process. That is, preferably the organic EL element is prepared by a wet process. Preparation of the organic EL element via a wet process exerts the following effects: easily producing a uniform film (i.e., coating film), and suppressing formation of a pinhole. Here, the above described film (or coating film) is a film in a state dried after coating by a wet process.

As a solvent for dissolving or dispersing the organic EL material of the present invention, usable are, for example, a ketone derivative such as methyl ethyl ketone and cyclohexanone; a fatty acid ester derivative like ethyl acetate, aromatic hydrocarbons such as toluene, xylene, mesitylene, and cyclohexyl benzene; aliphatic hydrocarbons such as cyclohexane, decalin, and dodecane; organic solvents such as DMF and DMSO or the like.

Further, as a dispersing method, usable are ultrasonic dispersion, high shear dispersion and media dispersion or the like.

Further, different film forming methods may be used per layer. When a vapor deposition method is applied to film formation, the vapor deposition conditions are different depending on types of compounds to be used. However, generally it is preferable to appropriately select a port heat temperature in the range from 50 to 450° C., a vacuum degree in the range from 10⁻⁶ to 10⁻² Pa, a vapor deposition rate in the range from 0.01 to 50 nm/sec, a substrate temperature in the range from −50 to 300° C. and a thickness in the range from 0.1 nm to 5 □m, preferably from 5 to 200 nm.

Formation of the organic layers used in the present invention is preferably performed via consistently preparing the organic layers from the hole injection layer to the cathode via one evacuation, but may be performed via taking out the materials to perform a different film formation method. At that time, it is preferable to perform the film formation under a dry inert gas.

<<Anode>>

As an anode of the organic EL element, preferably used are electrode materials including a metal having a large work function (i.e., 4 eV or more, preferably 4.5 eV or more), an alloy, an electric conductive compound and the mixture thereof examples of those electrode materials include a metal such as Au, CuI, electric conductive material such as indium.tin oxide (ITO), SnO₂, and ZnO. Further, a material capable of preparing a transparent electric conductive film by using an amorphous material like IDIXO (In₂O₃—ZnO) may be applicable.

The cathode may be prepared by forming a thin layer in a vapor deposition or a spattering method via using the above electrode materials, then forming a pattern in a desirable shape by a photolithography method. Herein, when pattern accuracy is not required (i.e., in a case of a degree of 100 □m or more), a pattern may be formed through a mask in a desired shape when vapor deposition or spattering is performed with the electrode material.

Alternatively, when a material capable of being coated like an organic electric conductive material is used, a printing method and a wet film forming method like a coating process may be used. When luminescence is extracted from the anode, the transparent rate is set to larger than 10%, and sheet resistance of the anode is set to a several hundreds value DO/or less.

A thickness of the anode may depend on the material. However, the thickness is usually selected from the range from 10 nm to 1 □m, preferably from 10 nm to 200 nm.

<<Cathode>>

As a cathode, used are electrode materials formed of a metal with a small work function (i.e., 4 eV or less, and refer to as an electron injection metal), an alloy, an electric conductive compound and the mixture thereof. Examples of those electrode materials include sodium, a sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, an indium, a lithium/aluminum mixture, aluminum, and a rear earthy metal or the like. Among those materials, preferable one is a mixture of an electron injection metal and a second metal that is a stable and has a larger work function than the electron injection metal. For example, preferable one is a magnesium/silver mixture, a magnesium/aluminum mixture, a magnesium/indium mixture, an aluminum/aluminum oxide (Al₂O₃) mixture, a lithium/aluminum mixture and aluminum or the like.

The cathode may be prepared by forming a thin layer via vapor depositing or spattering those electrode materials. Further, the sheet resistance of the cathode is preferably set to a several hundreds value O/o or less, and the thickness is typically selected from the range from 10 nm to 5 □m, preferably from 50 nm to 200 nm.

Here, either of the anode or the cathode of the organic EL element is transparent or semi-transparent in order to transmit luminescence thus emitted. This feature is advantageous for improve the brightness of luminescence.

Further, after preparing the cathode using the metal with a thickness in the range from 1 nm to 20 nm, preparation of an electric transparent material on the metal that is listed in the description of the anode may prepare a transparent or a semi-transparent cathode. This application may prepare an element in which both anode and cathode have transparency.

<<Support Substrate>>

A support substrate usable for the organic EL element of the present invention (hereinafter, also refer to as a body, a substrate, a base material or a support) may be transparent or opaque without any limitation of types of glass or plastic. When light is extracted from a support substrate side, preferably the support substrate is transparent. A transparent support substrate preferably used includes glass, quartz, and a transparent resin film or the like. Here, particularly preferable support substrate is a resin film capable of affording flexibility to the organic EL element.

Such a resin film includes, for example, a polyester like polyethylene terephthalate (PET) and polyethylene naphthalate (PEN); polyethylene; polypropylene; a cellulose ester and the derivatives thereof such as cellophane, cellulose diacetate, cellulose triacetate (TAC), cellulose acetate butyrate, cellulose acetate propionate (CAP), cellulose acetate phthalate, and cellulose nitrate; polyvinylidene chloride; polyvinyl alcohol; polyethylene vinyl alcohol; syndiotactic polystyrene, polycarbonate, norbornene resin, polymethyl pentene, polyether ketone, polyimide, polyether sulfone (PES), polyphenylene sulfide, polysulfones, polyether imide, polyether ketone imide, polyamide, a fluororesin, nylon, polymethyl methacrylate, acryl or polyarylate, cycloolefin based resin such as Arton R (JSR Corporation) or Apel R (Mitsui Chemicals, Inc.) or the like.

On a surface of the resin film, an organic coating, an inorganic coating or a hybrid coating of organic and inorganic ones may be formed. Preferably such a coating is a barrier film having steam permeability (i.e., at 25±0.5° C. and relative humidity (90±2) % RH) is set to 0.01 g/(m²·24 h·atm) or less measured by a method following JIS K 7129-1992. Further, preferably the coating is a high barrier film having oxygen permeability measured by a method following JIS K 7126-1987 set to 10⁻³ ml/(m²·24 h·atm) or less, and stream permeability set to 10⁻⁵ g/(m²·24 h).

A material forming the barrier film is a material just having ability for suppressing invasion of water and oxygen that deteriorate the element, for example, including silicon oxide, silicon dioxide, and silicon nitride or the like. Further, preferably the barrier film has a layered structure including those inorganic layers and organic layers in order to improve fragility of the barrier film. Herein, the layering order of the organic layer and inorganic layer is not particularly limited. However, it is preferable to alternately stack the organic layer and the inorganic layer multiple times.

A method for forming the barrier film is not particularly limited. However, usable methods are a vacuum vapor deposition method, a spattering method, a reactivity spattering method, a molecular beam epitaxy method, a cluster ion beam method, an ion plating method, a plasma polymerization method, an atmospheric plasma polymerization method, a plasma CVD method, a laser CVD method, a thermal CVD method, and a coating method or the like. Particularly preferable one is an atmospheric plasma polymerization method described in Japanese Unexamined Patent Application Publication No. 2004-68143.

An opaque support substrate includes, for example, a metal plate such as aluminum or stainless steel, a film or opaque resin substrate, and a substrate made of ceramics.

Preferably, luminescence of the organic EL element of the present invention has 1% or more of externally extracting quantum efficiency at room temperature, and more preferably 5% or more.

Here, the externally extracting quantum efficiency is defined by the following equation.

“externally extracting quantum efficiency (%)”=“number of photons emitted outside organic EL element”/“number of electrons passing through organic EL element”×100

Further, a hue improving filter like a color filter may be used in combination. Alternatively, a color conversion filter converting the luminescent color from the organic EL element into multiple colors via using a fluorescent material may be also used in combination.

<<Sealing>>

A method for sealing the organic RL element of the present invention may include a method, for example, of bonding a sealing member, an electrode and a support substrate by an adhesive. Such a sealing member is just to be provided for covering a display area of the organic EL element, in a concave shape or a tabular shape. Further, transparency and electric insulation thereof are not particularly limited thereto.

More specifically, the material includes a glass plate, a polymer plate.film, and a metal plate.film or the like. The glass plate includes especially soda lime glass, barium.strontium containing glass, lead glass, alminosilicate glass, borosilicate glass, barium borosilicate glass, and quartz or the like. Further, the polymer plate includes polycarbonate, acryl, polyethylene phthalate, polyether sulfide, and a polysulphone or the like. The metal plate includes a material made of at least one kind of a metal or an alloy selected from the group of stainless steel, iron, copper, aluminum, magnesium, nickel, zinc, chrome, titanium, molybdenum, silicone, germanium, and tantalum.

In the present invention, preferably a polymer film and a metal film may be used because the organic EL element can be thinned. Further, such a polymer film is preferably a film having oxygen permeability measured by a method following JIS K 7126-1987 set to 1×10⁻³ ml/(m²·24 h·atm) or less, and stream permeability (25±0.5° C., relative humidity (90±2)%) both set to 1×10⁻³ g/(m²·24 h).

Fabricating the sealing member in a concave shape is performed by using a sandblast process, and chemical etching process or the like.

Examples of the adhesives include a photocuring and thermocuring adhesives having a reactive vinyl group of an acrylic acid oligomer and a methacrylic acid oligomer, and a moisture curing adhesive such as 2-cyanoacrylic acid ester. Further, the examples include a thermal and chemical curing type agent (i.e., two-liquid mixing one) like an epoxy based agent. Moreover, the examples include a hot-melt type polyamide, polyester, and polyolefin. Furthermore, the examples include a cation and ultraviolet curing type of epoxy resin adhesive.

Note, the organic EL element may be deteriorated by heating treatment. Thus, the adhesive is preferably a material thermocurable in the range from room temperature to 80° C. Further, a desiccant may be dispersed in the above described adhesives. The adhesives may be applied onto a sealing portion via using a commercially available dispenser, or printed as screen printing.

Moreover, it is possible to preferably coat an electrode and organic layers at an outside of the electrode that faces the support substrate via the organic layers, thereby to form inorganic and organic layers adjacent to the support substrate so that a sealing film is formed. In that case, a material for forming the above described film is just to be a material having ability for suppressing invasion of a substance that deteriorates the element such as water and oxygen. For example, silicon oxide, silicon dioxide, and silicon nitride or the like may be utilized therefor.

Further, preferably the film has a layered structure formed of the above described inorganic layers and organic materials in order to improve fragility of the film. A method for forming those films is not specifically limited, and may include a vacuum vapor deposition method, a spattering method, a reactive spattering method, a molecular beam epitaxy method, a cluster ion beam method, an ion plating method, a plasma polymerization method, an atmospheric plasma polymerization method, a plasma CVD method, a laser CVD method, a thermal CVD method and a coating method or the like.

An inert gas such as nitrogen or argon in gas and liquid phases or an inert liquid such as a fluorohydrocarbon and a silicon oil is preferably injected into a gap between the sealing member and the display area of the organic EL element. Further, the gap may be evacuated. Alternatively, a hygroscopic compound may be sealed inside the element.

Such a hygroscopic compound includes, for example, a metal oxide (e.g., sodium oxide, potassium oxide, calcium oxide, barium oxide, magnesium oxide, aluminum oxide); a sulfate salt (e.g., sodium sulfate, potassium sulfate, magnesium sulfate, cobalt sulfate); a metal halide (e.g., calcium chloride, magnesium chloride, cesium fluoride, tantalum fluoride, cerium bromide, magnesium bromide, barium iodide, magnesium iodide); and a perchlorate salt (e.g., barium perchlorate, magnesium perchlorate). Herein, an anhydrous salt is preferably used in the above described sulfate salt, metal halide and perchlorate salt.

<<Protecting Film, Protecting Plate>>

A protecting film or a protecting plate may be provided outside the protecting film or the protecting plate placed at a side facing the support substrate via the organic layers in order to increase the mechanical strength of the element. In particular, when the sealing film is used for the sealing, the mechanical strength of the sealing film is not always high. Thus, preferably the above described protecting film or protecting plate is provided therewith. A material usable for the protecting film or the protecting plate includes a glass plate, a polymer plate.film, a metal plate.film. Herein, the most preferable one is a polymer film from the viewpoint of a lighter weight and a thinner film.

<<Technology for Improving Light Extraction>>

It is generally said that an organic electroluminescent element emits light inside a layer having a refractive index higher than the air (i.e., the refractive index of the layer is in the range from about 1.6˜about 2.1), and only about 15%˜about 20% of light can be extracted from the light thus emitted from the luminescent layer. This phenomenon is caused because incident light entering an interface (i.e., an interface between a transparent substrate and the air) at an angle Q equal to or more than the critical angle cannot be extracted due to occurrence of total reflection of the light between the transparent electrode and the transparent substrate or between the luminescent layer and the transparent substrate, so that the light is guided through the transparent electrode or the luminescent layer. Hereby, the resulting light escapes in the direction of an element side.

Here, a method for improving light extraction efficiency includes, for example a method for forming concaves and convexes on a surface of a transparent substrate thereby to prevent total reflection of light between the transparent substrate and the air (e.g., U.S. Pat. No. 4,774,435); a method for providing a substrate with a light-harvesting property so as to improve the light extracting efficiency (e.g., Japanese Unexamined Patent Application Publication No. S63-314795); a method for forming a reflection surface at a side of the element (e.g., Japanese Unexamined Patent Application Publication No. H01-220394); a method for introducing a flat layer with an intermediate refractive index between a substrate and a luminescent body so as to form a reflection blocking film (e.g., Japanese Unexamined Patent Application Publication No. S62-172691); a method for introducing a flat layer with a refractive index lower than that of a substrate between the substrate and a luminescent body (e.g., Japanese Unexamined Patent Application Publication No. 2001-202827); and a method for forming a diffraction grating between any pair of layers selected from a substrate, a transparent layer and a luminescent layer (i.e., including between the substrate and external environment) (e.g., Japanese Unexamined Patent Application Publication No. H11-283751) or the like.

In the present invention, the above described methods may be used in combination with the organic electroluminescent element of the present invention. Herein, the method for introducing a flat layer with a refractive index lower than that of a substrate between the substrate and a luminescent body, or the method for forming a diffraction grating between any pair of layers selected from the group of a substrate, a transparent layer and a luminescent layer (i.e., including between the substrate and external environment) may be utilized preferably.

In the present invention, combination of those method may produce an element having high brightness and excellent in durability thereof.

When a medium layer is formed with a low refractive index that has a thickness longer than a light wavelength between a transparent electrode and a transparent substrate, the higher the light emitting from the transparent electrode to the outside has extracting efficiency, the lower the medium layer has a refractive index.

Such a medium layer with a low refractive index includes, for example, aerogel, porous silica, magnesium fluoride, and a fluoropolymer. A refractive index of the transparent substrate is generally in the range from about 1.5 to about 1.7. Thus, preferably a low refractive index of the medium layer is set to about 1.5 or less, more preferably about 1.35 or less.

Further, a thickness of the medium layer with a low refractive index is desirably set to 2-fold or more of the light wavelength. That is, when a thickness of the medium layer with a low refractive index becomes a degree of the light wavelength, evanescent electromagnetic waves ooze into the substrate, resulting in a decrease in the above described effect thus exerted by the medium layer with a low refractive index.

A method for introducing a diffraction grating into an interface causing total reflection or any one of the medium layers has characteristics of increasing an effect for improving the light extraction efficiency. This method uses a function capable of converting a direction of light to a specific direction different from refraction of the light via so-called Bragg diffraction so that a diffraction grating causes primary or secondary diffraction. Then, use of the above function diffracts the light incapable of being extracted to the outside due to total reflection between layers from all of the light thus emitted from a luminescent layer, by introducing the diffraction grating between any pair of layers or into a medium layer (i.e., inside a transparent substrate or inside a transparent electrode). Hence, the resulting diffracted light can be extracted to the outside by the above defined method.

Here, the diffraction grating to be introduced desirably has a two-dimensional periodic refractive index. That is, light emitted from the luminescent layer is randomly generated in every direction. Hereby, a general one-dimensional diffraction having a periodic distribution of a refractive index in a certain direction alone diffracts only the light proceeding in a specific direction. This phenomenon does not increase the light extracting efficiency so much.

However, a two-dimensional distribution of the diffraction grating to be introduced diffracts the light proceeding in every direction, which improves the light extracting efficiency.

A position to which the diffraction grating is introduced may be any one between the layers, or in a medium (i.e., inside a transparent substrate or inside a transparent electrode). However, a desirable position is in the vicinity of the organic luminescent layer where light emits. Herein, preferably a period of the diffraction grating is in the range from about ½ to 3-fold of a wavelength of the light in the medium. Preferably, an array of the diffraction grating is repeated 2-dimensional arrays such as a square lattice shape, a triangle lattice shape, and a honeycomb lattice shape.

<<Condensing Sheet>>

In the organic EL element of the present invention, providing a microlens array structure at a light extracting side of the support substrate (or substrate), or combining a so-called condensing sheet therewith concentrates light in the direction facing a specific direction, for example, a direction to a luminescent surface of the element. This fabrication can increase the brightness in a specific direction

Examples of the microlens array include an array thus formed by 2-dimensionally arranging quadrangular pyramids each having 30 □m on a side and 90° of the vertical angle at the light extracting side. A side thereof is preferably set into the range from 10 □m to 100 □m. A side less than 10 □m generates a diffraction effect to color the array, while a side more than 100 mm makes the thickness large. Both are not preferable.

As a condensing sheet, usable are condensing sheets practically applied to, for example, an LED backlight of a liquid crystal display. Such a sheet includes, for example, a brightness enhancement film (BEF: Sumitomo 3M Limited) or the like. A prism sheet may have a shape in which □-shaped stripes with a vertical angle of 90° and a pitch of 50 □m are formed on the substrate. Further, the shape may include round vertical angles, pitches modified at random, and may be other forms.

Moreover, a light diffusion plate.film may be used in combination with the condensing sheet in order to control a light radiation angle from the organic EL element. For example, a diffusion film (LIGHT-UP™, KIMOTO) or the like may be used.

<<Application>>

The organic EL element of the present invention may be applied to a display device, a display, and various luminescent light sources.

Such a luminescent light source includes, for example, a lighting apparatus (e.g., home lighting, vehicle interior lighting), a backlight for watch and liquid crystal, an advertisement signboard, a signal, a light source for optical storage medium, a light source for electrophotographic copier, a light source for optical communication processor, and a light source for light sensor or the like. However, the present invention is not limited to those examples. Herein, especially effective examples are application to a backlight of liquid crystal display and a light source for lighting.

The organic EL element of the present invention may be subjected to patterning treatment via a metal mask method or an ink jet printing method when producing a film as necessary. When subjected to patterning treatment, only an electrode may be subjected to patterning treatment, n electrode and a luminescent layer may be subjected to patterning treatment, and all the layers in the element may be subjected to patterning treatment. Herein, a conventionally known method may be used for preparing the element.

<<Display>>

Hereinafter, an example of a display including the organic EL of the present invention will be described more specifically referring to the attached drawings.

FIG. 7 is an approximately perspective diagram showing an example of a display structure formed of the organic EL element of the present invention. This is a schematic diagram of a display such as a mobile phone displaying image data by luminescence of the organic EL element. As shown in FIG. 7, a display 1 includes a display unit A having multiple pixels, and a control unit B performing picture scanning of the display A based on the image data.

The control unit B is electrically connected to the display unit A. The control unit B transmits a scanning signal and an image data signal based on the image data received from the outside. As a result, each pixel emits light corresponding to the image data signal per scanning line by the scanning signal, whereby image date is sequentially displayed on the display unit A.

FIG. 8 is a schematic diagram of the display A in FIG. 7.

The display A includes a wiring unit having multiple scanning lines 5 and data lines 6, and multiple pixels 3.

Next, main members of the display A will be explained more specifically.

FIG. 8 illustrates a case in which light emitted by the pixel 3 is extracted in the direction of white arrow (i.e., downward direction). The scanning lines 5 and the multiple data lines 6 in the wiring unit are formed of an electric conductive material, respectively. The scanning line 5 and the data line 6 intersect perpendicularly each other, and are connected to the pixel 3 at the perpendicularly crossing position (not shown in detail).

When a scanning signal is transmitted from the scanning line 5, the pixel 3 receives an image data signal from the data line 6, and emits light corresponding to the image data thus received.

Here, a full colored display may be achieved by appropriately arranging a pixel of which luminescent color is in a red region, a pixel of which luminescent color is in a green region, and a pixel of which luminescent color is in a blue region in parallel on the same substrate.

<<Lighting Apparatus>>

Next, an aspect of a lighting apparatus of the present invention having the organic EL element of the present invention will be described more specifically.

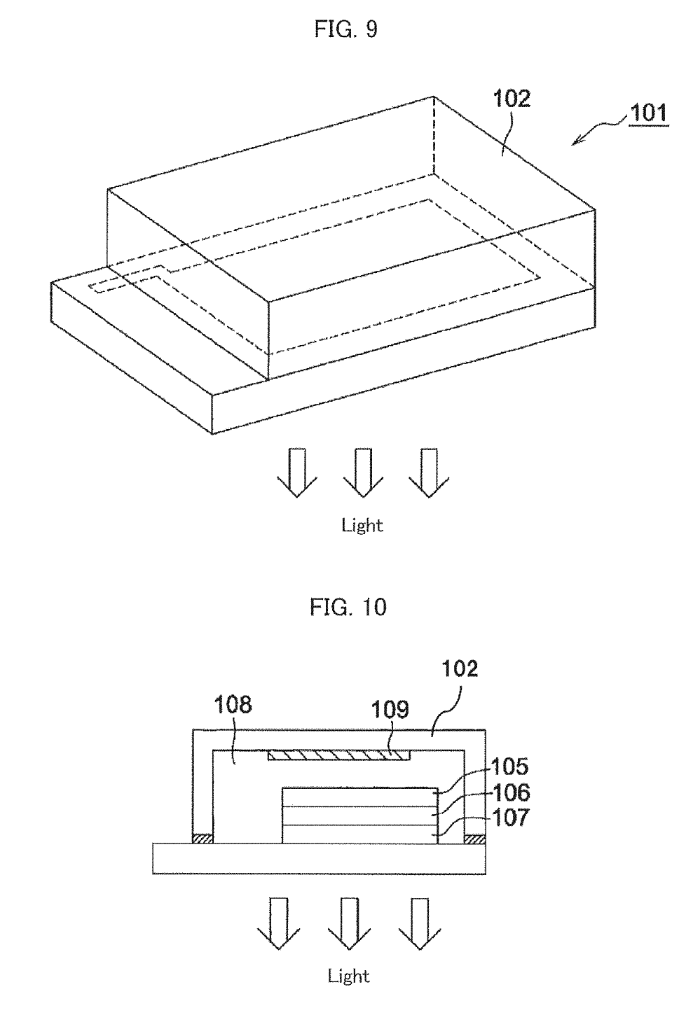

First, a lighting apparatus shown in FIGS. 9 and 10 may be formed by covering a non-luminescent surface of the organic EL element of the present invention by a glass case. Then, the glass substrate with a thickness of 300 □m, is used as a sealing substrate and put over the cathode to be tightly bonded to a transparent support substrate by applying an epoxy based photocuring adhesive (Ruxtruck LC0629B, TOAGOSEI CO., LTD.) as a sealing agent to a periphery of the glass substrate. Irradiation of UV light from a glass substrate side cures the adhesive, thereby sealing the glass case.

FIG. 9 illustrates a schematic diagram of the lighting apparatus. Herein, the organic EL element 101 of the present invention is covered by a glass case 102 (Note: sealing operation by the glass case is carried out inside a glove box under a nitrogen atmosphere (i.e., under the atmosphere of high purity nitrogen gas with the purity of 99.999% or more) without contacting the organic EL element to the air).

FIG. 10 illustrates a cross-sectional diagram of the lighting apparatus. In FIG. 10, reference No. 105 shows a cathode, reference No. 106 shows an organic EL layer (i.e., a luminescent unit), reference No. 107 shows a glass substrate provided with a transparent electrode, respectively. Here, a nitrogen gas 108 is filled inside the glass case 102, and a moisture catcher 109 is provided therein.

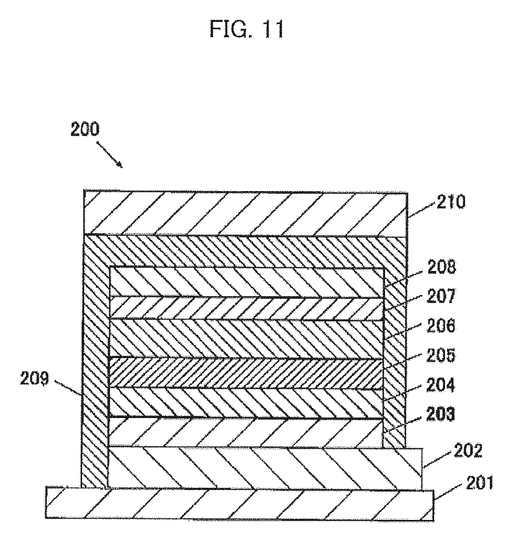

FIG. 11 is a cross-sectional diagram of the lighting apparatus having an organic EL element thus prepared by a wet-process with a coating liquid via using a flexible support substrate 201. As shown in FIG. 11, an organic EL element 200 in the preferable embodiment of the present invention includes a flexible support substrate 201. An anode 202 is formed on the flexible support substrate 201. Various organic functional layers shown below are formed on the anode 202. A cathode 208 is formed on the organic functional layers.

The organic functional layers include, for example, a hole injection layer 203, a hole transport layer 204, a luminescent layer 205, an electron transport layer 206, and an electron injection layer 207. Further, the organic functional layers may include a hole blocking layer and an electron blocking layer or the like.

The anode 202, the organic functional layers and the cathode 208 respectively stacked on the flexible support substrate 201 in this order are sealed via the sealing adhesive 209 by the flexible sealing member 210.

### EXAMPLES

Next, Examples satisfying the requirements of the present invention and Comparative Examples unsatisfying the requirements will be shown. Referring to those Examples and Comparative Examples, a thin film and an organic electroluminescent element of the present invention will be described more specifically.

### Reference Example 1

Prior to describing the present invention via using Examples and Comparative Examples, first, in Reference Example 1, a compound assuming blue luminescence was used so as to determine an energy transfer rate from a dopant to a quencher.

<<Preparation of Thin Film for Evaluation>>

A quartz substrate with a dimension of 50 mm×50 mm, a thickness of 0.7 mm was ultrasonically washed by isopropyl alcohol, dried by a dry nitrogen gas, and cleaned with UV ozone for 5 min. Then, the resulting quartz substrate serving as a transparent substrate was held in a substrate holder of a commercially available vacuum vapor deposition device. A “host” and a “dopant” listed in Table 1 and a “quencher” (Q-1) were filled respectively in each of vapor deposition crucibles of the vacuum vapor deposition device so that amounts of the compounds were set to optimal ones for preparing each element. The vapor deposition crucible thus used was produced of a resistance heating material made of molybdenum.

Next, after reducing a pressure inside the vacuum vapor deposition device down to a vacuum degree of 1×10⁻⁴ Pa, a host, a dopant and a quencher were vapor codeposited so that the contents thereof became 84 vol %, 15 vol % and 1 vol %, respectively. Accordingly, thin films for evaluation each with a thickness of 30 nm were prepared.

<<Preparation of Thin Film for Comparison>>

A thin film for comparison was prepared the same method as in the “Preparation of Thin Film for Evaluation” except that a quencher was not vapor deposited (i.e., a quencher had a content of 0 vol % and a reduced content of the quencher was converted to a content of a host compound thus used).

Here, every thin film for comparison was produced per thin film for evaluation (i.e., specifically, the thin film for comparison Ref 1-1 without vapor deposition of a quencher per thin film for evaluation 1-1; the thin film for comparison Ref. 1-2 without vapor deposition of a quencher per thin film for evaluation 1-2).

<<Measurement in Emission Lifetime of Core-Shell Type Dopant>>

Emission lifetimes (i.e., phosphorescent lifetimes) of the thin films for evaluation and the thin films for comparison were obtained by measuring transient PL properties. A small sized device for measuring a fluorescence lifetime C11367-03 (Hamamatsu Photonics K.K.) was used for measuring the transient PL properties. Decay component was measured in the TCC900 mode using 340 nm LED as an excitation light source.

Note, when the thin film for evaluation 1-1 was analyzed under oxygen free conditions, an emission lifetime thereof was 0.8 Os, while an emission lifetime of the thin film for comparison Ref. 1-1 was 1.6 Os. The results suggest that quenching generated via the energy transfer from the dopant to the quencher Q-1 partially occurs in the thin film for evaluation 1-1 added with Q-1, which results in an emission lifetime thereof shorter than that of the thin film for comparison Ref 1-1.

<<Calculation of Energy Transfer Rate (Kq) from Dopant to Quencher>>

An energy transfer rate (Kq) from the dopant to the quencher was calculated by substituting a lifetime value of the dopant in the thin film for evaluation (□□ (with Quencher) and a lifetime value of the dopant in the thin film for comparison (□0 (without Quencher) both thus obtained by the above described method into the following Equation (2) thus lead by modifying the above defined Equation (1).

Here, as to the thin film for evaluation, Kq was calculated by substituting 1 into [Q]because the content of the quencher was set to 1 vol %.

$$\frac{PL ( withQuencher )}{PL 0 ( withoutQuencher )} = \frac{τ ( withQuencher )}{τ0 ( withoutQuencher )} = \frac{1}{1 + Kq \times [ Q ] \times τ0} \qquad Equation ( 2 )$$

In Equation (2), PL (with Quencher) represents emission intensity in the presence of the quencher, PLO (without Quencher) represents emission intensity in the absence of the quencher, Kq represents an energy transfer rate from the luminescent material to the quencher, [Q](=Kd×t) represents a concentration of quencher, Kd represents a generation rate of the quencher via agglomeration/decomposition, t represents an accumulated excitation time by light or current, □ represents a phosphorescence lifetime of the dopant in the presence of the quencher, and □0 is a phosphorescence lifetime of the luminescent material in the absence of the quencher.

Kq of each thin film for evaluation was calculated by the above described method, thereby to calculate a relative rate (i.e., Kq rate) to Kq of the thin film for evaluation thus set to 1.

<<Calculation of Vₐₗₗ/V_{core} Value>>

In the calculation of a Vₐₗₗ/V_{core} value, Vₐₗₗ and V_{core} are defined the same as in the previous definition. Then, the Vₐₗₗ/V_{core} value was obtained by calculating the van der Waals molecular volumes of Vₐₗₗ and V_{core}, and then dividing Vₐₗₗ by V_{core}.

Note, the following compounds in addition to the above described compounds were applied to the respective compounds used in the present Examples (i.e., [Reference Examples 1]˜[Reference Examples 5], and [Examples 1]˜[Examples 10]).

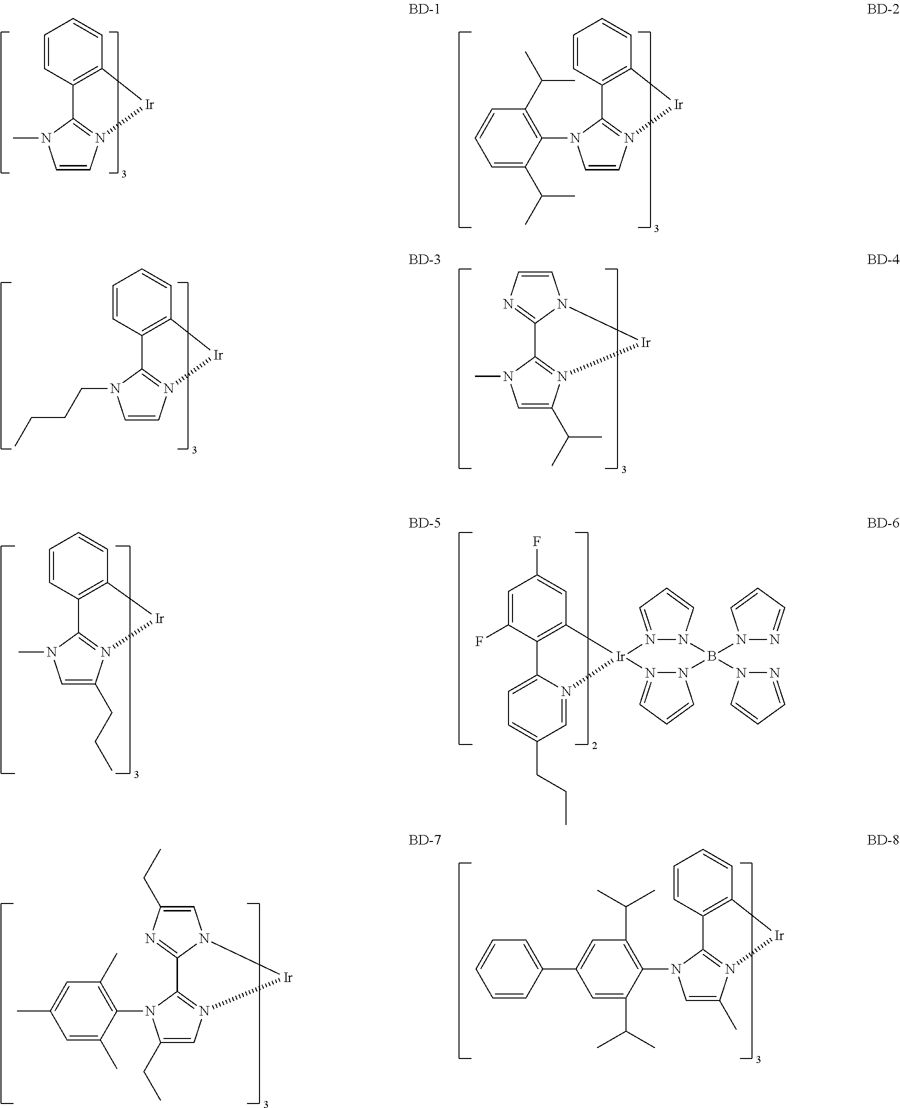

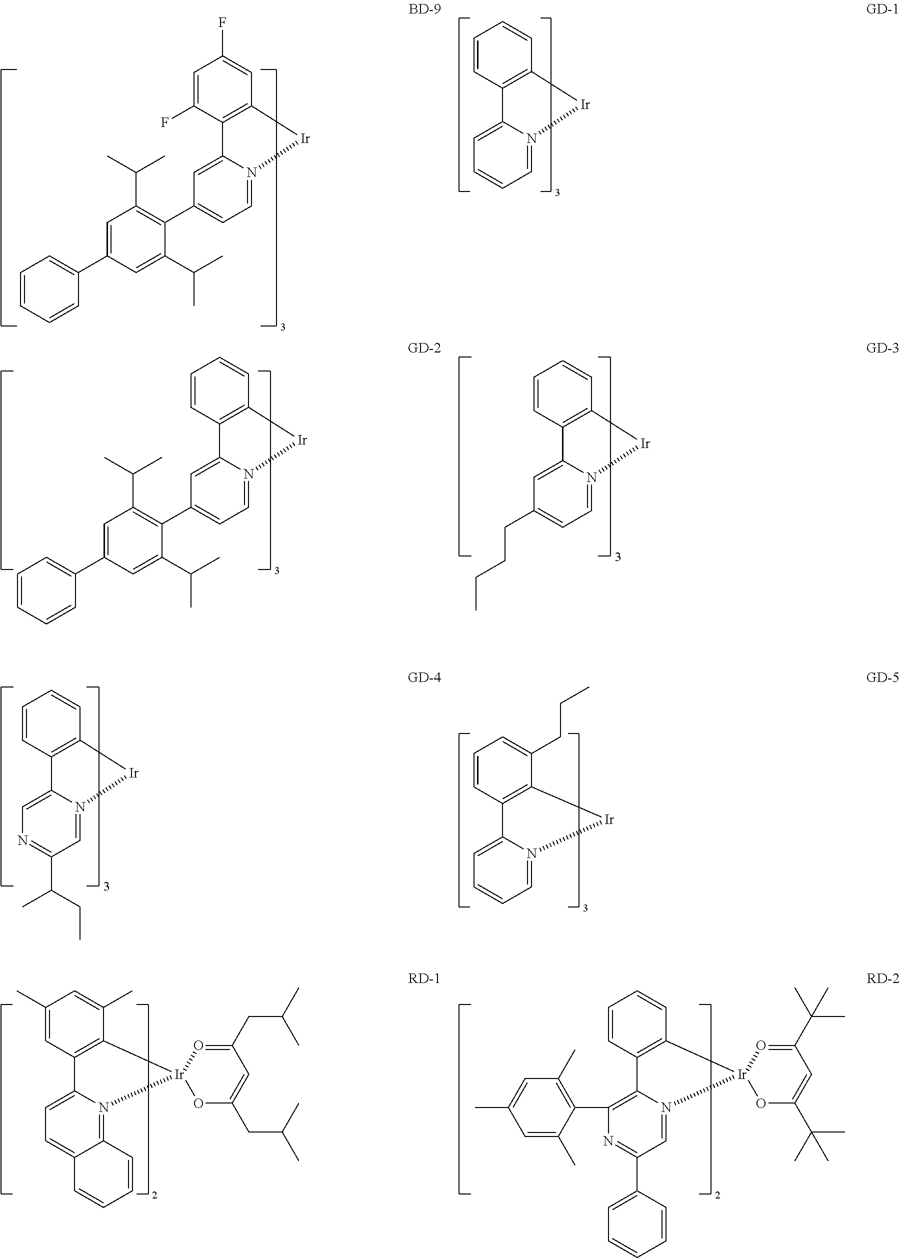

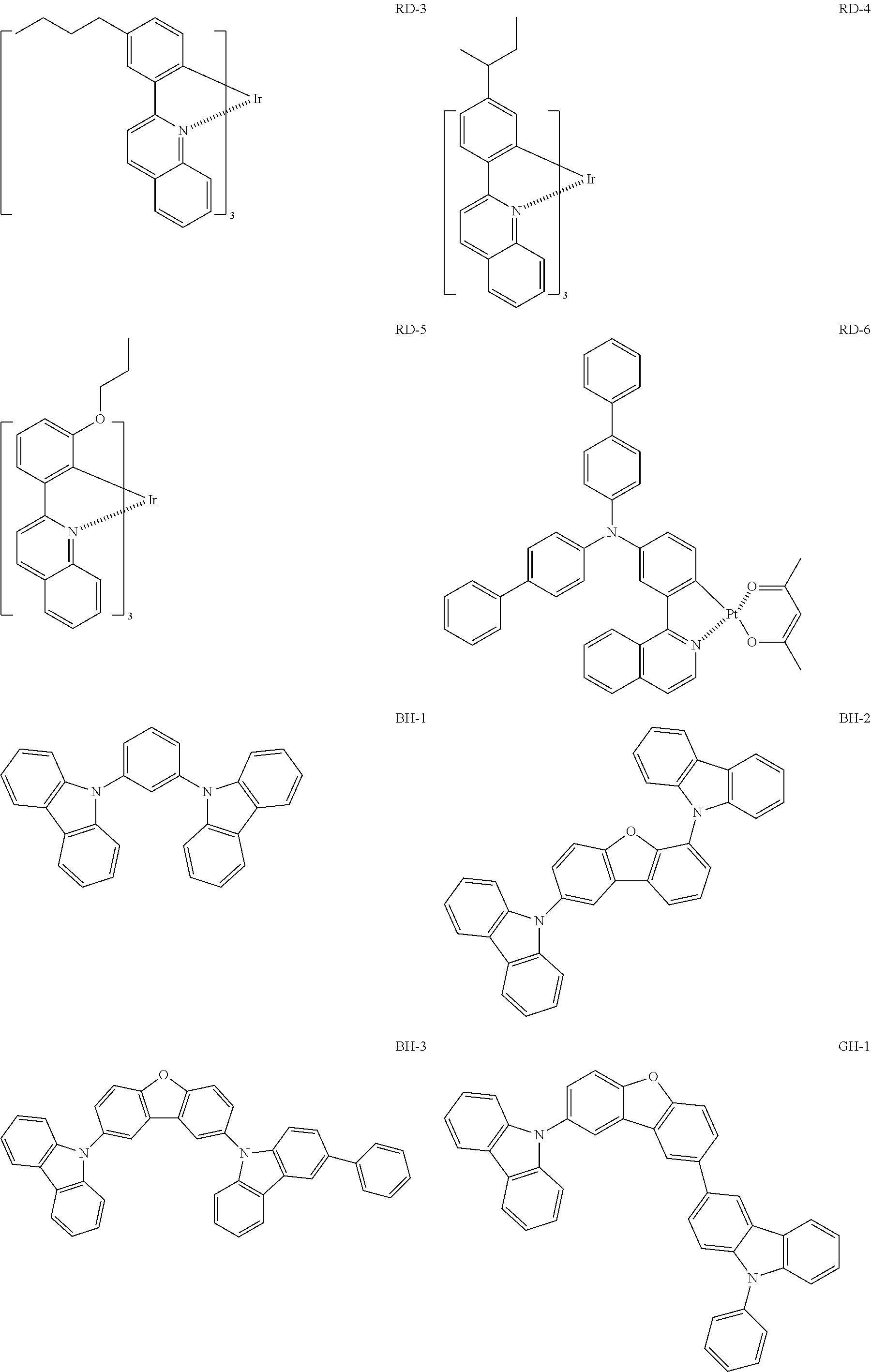

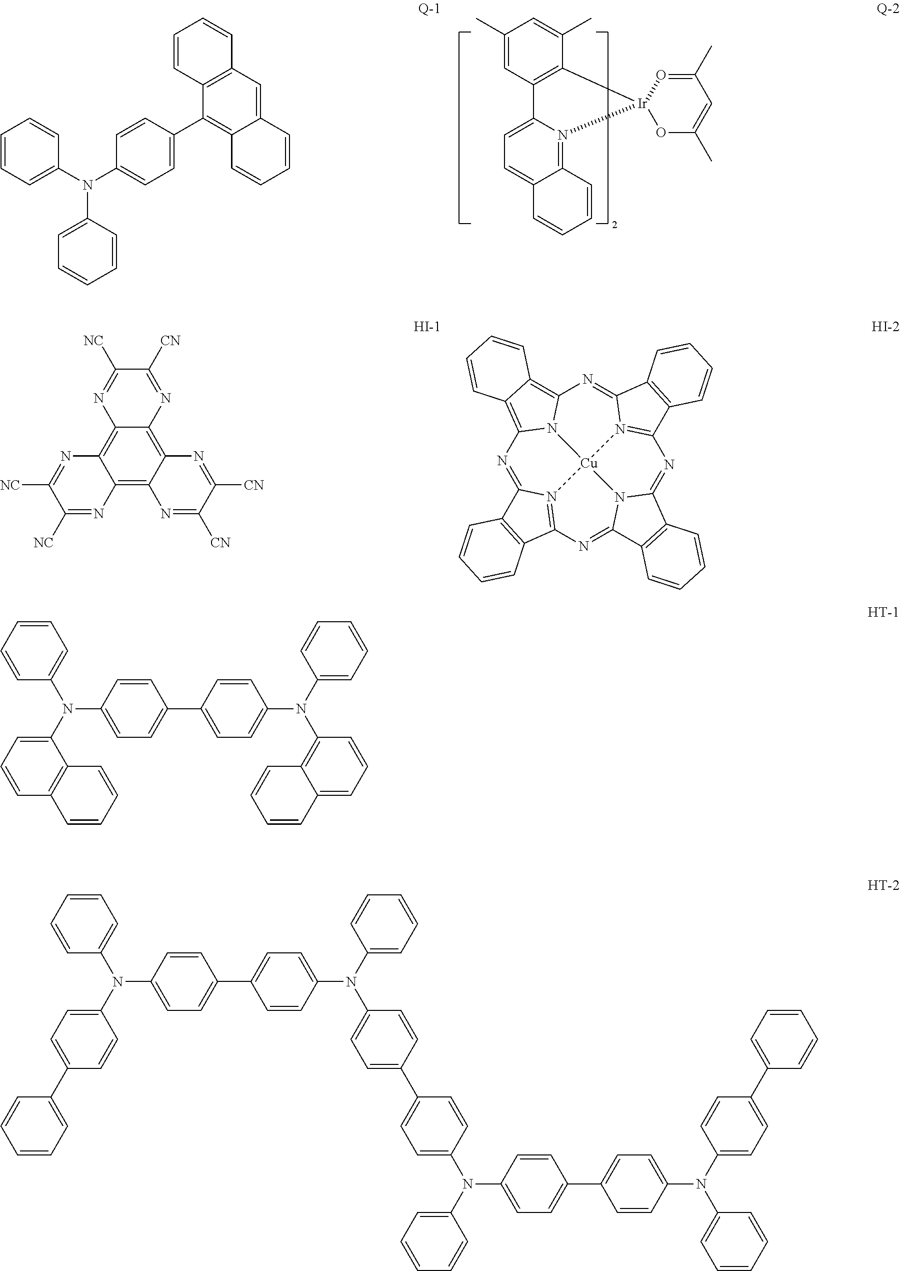

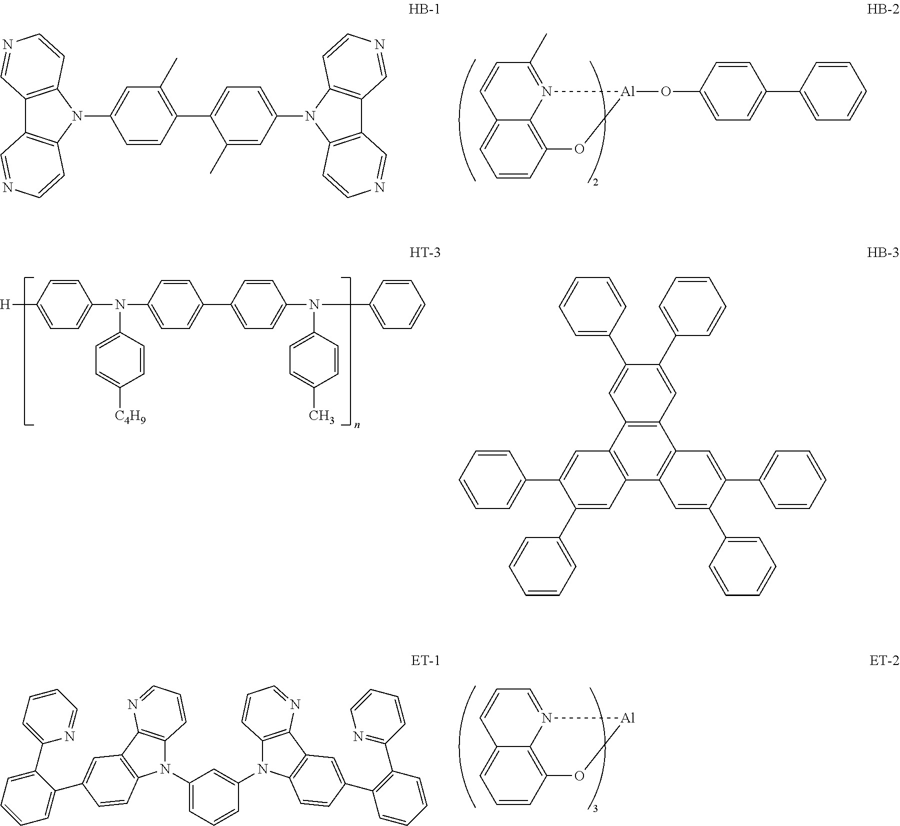

Hereinafter, results of the respective evaluations will be listed in Table 1.

Note, the number of the host and the number of the dopant in Table 1 correspond to the numbers of the above described compounds, respectively.

TABLE 1

| Thin Film | Host | Dopant | Kq Rate | Vall/Vcore |
|---|---|---|---|---|
| No. | No. | No. | Q-1 Added | Value |
| 1-1 | BH-1 | BD-1 | 1 | 1.12 |
| 1-2 | BH-1 | BD-2 | 1.06 | 2.15 |
| 1-3 | BH-1 | BD-3 | 0.94 | 1.48 |
| 1-4 | BH-1 | BD-4 | 0.92 | 1.53 |
| 1-5 | BH-1 | BD-5 | 1.02 | 1.47 |
| 1-6 | BH-1 | BD-6 | 0.99 | 1.40 |
| 1-7 | BH-1 | BD-7 | 0.95 | 2.53 |
| 1-8 | BH-1 | BD-8 | 0.91 | 2.78 |
| 1-9 | BH-1 | BD-9 | 1.01 | 2.63 |
| 1-10 | BH-1 | CD-1 | 0.76 | 2.70 |
| 1-11 | BH-1 | CD-2 | 0.68 | 2.42 |
| 1-12 | BH-1 | CD-3 | 0.71 | 2.52 |
| 1-13 | BH-1 | CD-4 | 0.73 | 3.32 |
| 1-14 | BH-1 | CD-5 | 0.62 | 2.30 |
| 1-15 | BH-1 | CD-6 | 0.69 | 2.32 |
| 1-16 | BH-1 | CD-7 | 0.7 | 2.09 |
| 1-17 | BH-1 | CD-8 | 0.66 | 2.22 |

<<Analysis of Results: Reference Example 1>>

As shown in Table 1, in the thin films for evaluation 1-10˜1-17, it was confirmed that values of Vₐₗₗ/V_{core} of the dopants exceed 2, and use of the core-shell type dopants satisfying the General Formulae defined in the present invention suppresses the energy transfer from each dopant to the quencher, thereby to afford a small Kq value (or a Kq rate).

### Reference Example 2

Next, in Reference Example 2, a compound assuming blue emission was used, and an energy transfer rate from each dopant to the quencher was determined.

<<Preparation of Thin Films for Evaluation and for Comparison>>

Every thin film for evaluation and every thin film for comparison were prepared by the same method as in Reference Example 1 except that the “hosts” and “dopants” listed in Table 2 were used.

<<Measurement and Calculation of Respective Values>>

Measurement of an emission lifetime of every core-shell type dopant, calculation of every energy transfer rate (Kq) from every dopant to the quencher, and calculation of every Vₐₗₗ/V_{core} value were carried out by the same method as in Reference Example 1.

Note, a Kq rate was calculated as a relative rate (i.e., a Kq rate) per Kq of the thin film for evaluation 2-1 thus set to 1.

TABLE 2

| Thin Film | Host | Dopant | Kq Rate | Vall/Vcore |
|---|---|---|---|---|
| No. | No. | No. | Q-1 Added | Value |
| 2-1 | BH-2 | BD-2 | 1 | 2.15 |
| 2-2 | BH-2 | CD-1 | 0.77 | 2.70 |
| 2-3 | BH-2 | CD-2 | 0.7 | 2.42 |
| 2-4 | BH-2 | CD-3 | 0.71 | 2.52 |
| 2-5 | BH-2 | CD-9 | 0.67 | 2.99 |
| 2-6 | BH-2 | CD-10 | 0.65 | 2.29 |
| 2-7 | BH-2 | CD-11 | 0.64 | 2.06 |
| 2-8 | BH-2 | CD-12 | 0.62 | 3.34 |
| 2-9 | BH-2 | CD-13 | 0.61 | 2.74 |
| 2-10 | BH-2 | CD-14 | 0.66 | 2.84 |
| 2-11 | BH-2 | CD-15 | 0.54 | 2.90 |
| 2-12 | BH-2 | CD-16 | 0.51 | 2.41 |
| 2-13 | BH-2 | CD-17 | 0.58 | 2.45 |
| 2-14 | BH-2 | CD-18 | 0.49 | 2.75 |
| 2-15 | BH-2 | CD-19 | 0.47 | 2.42 |
| 2-16 | BH-2 | CD-20 | 0.5 | 2.58 |
| 2-17 | BH-2 | CD-21 | 0.44 | 3.31 |
| 2-18 | BH-2 | CD-22 | 0.52 | 2.82 |
| 2-19 | BH-2 | CD-23 | 0.49 | 2.13 |
| 2-20 | BH-2 | CD-24 | 0.42 | 2.64 |
| 2-21 | BH-2 | CD-25 | 0.5 | 2.80 |
| 2-22 | BH-2 | CD-26 | 0.51 | 2.42 |
| 2-23 | BH-2 | CD-27 | 0.44 | 2.52 |
| 2-24 | H-6 | CD-16 | 0.48 | 2.41 |
| 2-25 | H-8 | CD-16 | 0.51 | 2.41 |
| 2-26 | H-6 | CD-19 | 0.48 | 2.42 |
| 2-27 | H-8 | CD-19 | 0.50 | 2.42 |

<<Analysis of Results: Reference Example 2>>

As shown in Table 2, in the thin films for evaluation 2-2˜2-27, it was confirmed that values of Vₐₗₗ/V_{core} of the dopants exceed 2, and use of the core-shell type dopants satisfying the General Formulae defined in the present invention suppresses the energy transfer from each dopant to the quencher, thereby to afford a small Kq value (or a Kq rate). Further, particularly it was confirmed that the thin films for evaluation each having L′ in General Formula (2) with a non-conjugated linker, or the thin films for evaluation each having a substituent with 3 or more ligands represented by the ring Z₁ and ring Z₂ have considerably small Kq values (or Kq rates), respectively.

### Reference Example 3

Next, in Reference Example 3, a compound assuming blue emission was used, and an energy transfer rate from each dopant to the quencher was determined.

<<Preparation of Thin Films for Evaluation and for Comparison>>

Every thin film for evaluation and every thin film for comparison were prepared by the same method as in Reference Example 1 except that the “hosts” and “dopants” listed in Table 3 were used, Q-2 was used as a “quencher”, and the quencher had a content of 0.1 vol % (i.e., an amount of the quencher thus reduced was changed to that of the host compound).

<<Measurement and Calculation of Respective Values>>

Measurement of an emission lifetime of every core-shell type dopant, calculation of every energy transfer rate (Kq) from each dopant to the quencher, and calculation of every Vₐₗₗ/V_{core} value were carried out by the same method as in Reference Example 1.

Note, a Kq rate was calculated as a relative rate (i.e., a Kq rate) per Kq of the thin film for evaluation 3-1 thus set to 1.

TABLE 3

| Thin Film | Host | Dopant | Kg Rate | Vall/Vcore |
|---|---|---|---|---|
| No. | No. | No. | Q-1 Added | Value |
| 3-1 | BH-3 | BD-3 | 1 | 1.48 |
| 3-2 | BH-3 | CD-4 | 0.73 | 3.32 |
| 3-3 | BH-3 | CD-5 | 0.69 | 2.30 |
| 3-4 | BH-3 | CD-7 | 0.69 | 2.09 |
| 3-5 | BH-3 | CD-28 | 0.57 | 3.08 |
| 3-6 | BH-3 | CD-29 | 0.52 | 2.41 |
| 3-7 | BH-3 | CD-30 | 0.55 | 2.24 |
| 3-8 | BH-3 | CD-31 | 0.51 | 2.51 |
| 3-9 | BH-3 | CD-32 | 0.49 | 2.20 |
| 3-10 | BH-3 | CD-33 | 0.51 | 2.43 |
| 3-11 | BH-3 | CD-34 | 0.52 | 2.78 |
| 3-12 | BH-3 | CD-35 | 0.49 | 2.76 |
| 3-13 | BH-3 | CD-36 | 0.51 | 2.66 |
| 3-14 | BH-3 | CD-37 | 0.5 | 2.43 |
| 3-15 | BH-3 | CD-38 | 0.48 | 2.43 |
| 3-16 | BH-3 | CD-39 | 0.49 | 2.39 |
| 3-17 | H-15 + H-16 | CD-29 | 0.52 | 2.41 |
| | (1:1) | | | |
| 3-18 | H-20 + H-22 | CD-29 | 0.55 | 2.41 |
| | (1:1) | | | |
| 3-19 | H-25 + H-24 | CD-29 | 0.47 | 2.41 |
| | (1:1) | | | |
| 3-20 | H-15 + H-16 | CD-36 | 0.45 | 2.66 |
| | (1:1) | | | |
| 3-21 | H-20 + H-22 | CD-36 | 0.5 | 2.66 |
| | (1:1) | | | |
| 3-22 | H-25 + H-24 | CD-36 | 0.51 | 2.66 |
| | (1:1) | | | |
| 3-23 | H-15 + H-16 | CD-39 | 0.48 | 2.39 |
| | (1:1) | | | |
| 3-24 | H-20 + H-22 | CD-39 | 0.47 | 2.39 |
| | (1:1) | | | |
| 3-25 | H-25 + H-24 | CD-39 | 0.51 | 2.39 |
| | (1:1) | | | |

<<Analysis of Results: Reference Example 3>>

As shown in Table 3, in the thin films for evaluation 3-2˜3-25, it was confirmed that values of Vₐₗₗ/V_{core} of the dopants exceed 2, and use of the core-shell type dopants satisfying the General Formulae defined in the present invention suppresses the energy transfer from each dopant to the quencher, thereby to afford a small Kq value (or a Kq rate). Further, particularly it was confirmed that the thin films for evaluation each having a substituent with 3 or more ligands represented by the ring Z₃ and ring Z₈ have considerably small Kq values (or Kq rates), respectively.

### Reference Example 4

Next, in Reference Example 4, a compound assuming green emission was used, and an energy transfer rate from each dopant to the quencher was determined.

<<Preparation of Thin Films for Evaluation and for Comparison>>

Every thin film for evaluation and every thin film for comparison were prepared by the same method as in Reference Example 1 except that the “hosts” and “dopants” listed in Table 4 were used.

<<Measurement and Calculation of Respective Values>>

Measurement of an emission lifetime of every core-shell type dopant, calculation of every energy transfer rate (Kq) from each dopant to the quencher, and calculation of every Vₐₗₗ/V_{core} value were carried out by the same method as in Reference Example 1.

Note, a Kq rate was calculated as a relative rate (i.e., a Kq rate) per Kq of the thin film for evaluation 4-1 thus set to 1.

TABLE 4

| Thin Film | Host | Dopant | Kq Rate | Vall/Vcore |
|---|---|---|---|---|
| No. | No. | No. | Q-1 Added | Value |
| 4-1 | GH-1 | GD-1 | 1 | 1.00 |
| 4-2 | GH-1 | GD-2 | 1.06 | 2.56 |
| 4-3 | GH-1 | GD-3 | 0.89 | 1.44 |
| 4-4 | GH-1 | GD-4 | 0.92 | 1.44 |
| 4-5 | GH-1 | GD-5 | 1.02 | 1.30 |
| 4-6 | GH-1 | CD-40 | 0.74 | 2.78 |
| 4-7 | GH-1 | CD-41 | 0.75 | 2.20 |
| 4-8 | GH-1 | CD-42 | 0.61 | 2.07 |
| 4-9 | GH-1 | CD-43 | 0.63 | 2.94 |
| 4-10 | GH-1 | CD-44 | 0.52 | 2.58 |
| 4-11 | GH-1 | CD-45 | 0.51 | 2.64 |
| 4-12 | H-7 | CD-40 | 0.72 | 2.78 |
| 4-13 | H-7 | CD-45 | 0.49 | 2.64 |
| 4-14 | H-20 + H-21 | CD-40 | 0.7 | 2.78 |
| | (1:1) | | | |
| 4-15 | H-20 + H-21 | CD-45 | 0.5 | 2.64 |
| | (1:1) | | | |

<<Analysis of Results: Reference Example 4>>

As shown in Table 4, in the thin films for evaluation 4-6˜4-15, it was confirmed that values of Vₐₗₗ/V_{core} of the dopants exceed 2, and use of the core-shell type dopants satisfying the General Formulae defined in the present invention suppresses the energy transfer from each dopant to the quencher even though the thin films thus used provide green emission, thereby to afford a small Kq value (or a Kq rate). Further, particularly it was confirmed that the thin films for evaluation each having L′ in General Formula (2) with a non-conjugated linker, or the thin films for evaluation each having a substituent with 3 or more ligands represented by the ring Z₁ and ring Z₂ have considerably small Kq values (or Kq rates), respectively.

### Reference Example 5

Next, in Reference Example 5, a compound assuming red emission was used, and an energy transfer rate from each dopant to the quencher was determined.

<<Preparation of Thin Films for Evaluation and for Comparison>>

Every thin film for evaluation and every thin film for comparison were prepared by the same method as in Reference Example 1 except that the “hosts” and “dopants” listed in Table 5 were used.

<<Measurement and Calculation of Respective Values>>

Measurement of an emission lifetime of every core-shell type dopant, calculation of every energy transfer rate (Kq) from every dopant to the quencher, and calculation of every Vₐₗₗ/V_{core} value were carried out by the same method as in Reference Example 1.

Note, a Kq rate was calculated as a relative rate (i.e., a Kq rate) per Kq of the thin film for evaluation 5-1 thus set to 1.

TABLE 5

| Thin Film | Host | Dopant | Kq Rate | Vall/Vcore |
|---|---|---|---|---|
| No. | No. | No. | Q-1 Added | Value |
| 5-1 | H-21 | RD-1 | 1 | 1.15 |
| 5-2 | H-21 | RD-2 | 1.01 | 2.24 |
| 5-3 | H-21 | RD-3 | 0.99 | 1.34 |
| 5-4 | H-21 | RD-4 | 0.97 | 1.33 |
| 5-5 | H-21 | RD-5 | 1 | 1.30 |
| 5-6 | H-21 | RD-6 | 0.97 | 2.52 |
| 5-7 | H-21 | CD-46 | 0.71 | 2.20 |
| 5-8 | H-21 | CD-47 | 0.68 | 2.27 |
| 5-9 | H-21 | CD-48 | 0.59 | 2.02 |
| 5-10 | H-21 | CD-49 | 0.57 | 2.08 |
| 5-11 | H-21 | CD-50 | 0.58 | 2.07 |
| 5-12 | H-2 | CD-46 | 0.69 | 2.20 |
| 5-13 | H-4 | CD-46 | 0.7 | 2.20 |
| 5-14 | H-10 | CD-46 | 0.68 | 2.20 |
| 5-15 | H-2 | CD-49 | 0.57 | 2.08 |
| 5-16 | H-4 | CD-49 | 0.53 | 2.08 |
| 5-17 | H-10 | CD-49 | 0.55 | 2.08 |

<<Analysis of Results: Reference Example 5>>

As shown in Table 5, in the thin films for evaluation 5-7˜5-17, it was confirmed that values of Vₐₗₗ/V_{core} of the dopants exceed 2, and use of the core-shell type dopants satisfying the General Formulae defined in the present invention suppresses the energy transfer from each dopant to the quencher even though the thin films thus used provide red emission, thereby to afford a small Kq value (or a Kq rate).

### Example 1

Next, in Example 1, a compound assuming blue emission was used, and an emission lifetime of each thin film was determined.

<<Preparation of Thin Film for Evaluation>>

A quartz substrate with a dimension of 50 mm×50 mm, a thickness of 0.7 mm was ultrasonically washed by isopropyl alcohol, dried by a dry nitrogen gas, and cleaned with UV ozone for 5 min. Then, the resulting quartz substrate serving as a transparent substrate was held in a substrate holder of a commercially available vacuum vapor deposition device. A “host” and a “dopant” listed in Table 6 were filled respectively in each of vapor deposition crucibles of the vacuum vapor deposition device so that amounts of the compounds were set to optimal ones for preparing each element. The vapor deposition crucible thus used was produced of a resistance heating material made of molybdenum.

Next, after reducing a pressure inside the vacuum vapor deposition device down to a vacuum degree of 1×10⁻⁴ Pa, a host and a dopant were vapor codeposited so that the respective contents thereof became 85 vol % and 15 vol %. Accordingly, thin films for evaluation each having a thickness of 30 nm were prepared.

<<Evaluation of Emission Lifetime>>

A residual rate of luminescence in the UV radiation experiment using a HgXe light source was obtained according to the following method.

In the UV radiation experiment using the HgXe light source, a mercury xenon lump UV radiation device LC8 (Hamamatsu Photonics K.K.) was used, and a UV cut filter of A9616-05 was attached thereto and used. First, an emission surface of irradiation fibers and a glass case surface for a sample (i.e., a thin film for evaluation) ware arranged in parallel, and the sample was irradiated with a distance of 1 cm so that the number of emitting photons was reduced by half. The measurement was conducted under a condition of room temperature (i.e., 300K). As to each thin film for evaluation, a time needed for the number of emitting photons being reduced by half (i.e., a half-value period) was measured. Then, a relative value (i.e., an LT50 rate) was obtained by setting the value of the thin film 6-1 at room temperature (i.e., 300K) to 1.

Note, the brightness (i.e., the number of emitting photons) was measured by using a spectral radiance meter CS-100 (Konica Minolta, Inc.) at an angle 45° against an axis of the radiation fibers.

<<Calculation of Kq>>

The energy transfer rate (Kq) from a dopant to the quencher was calculated by the same method as in Reference Example 1.

Note, a Kq rate was calculated as a relative rate (i.e., a Kq rate) per Kq of the thin film for evaluation 6-1 thus set to 1.

TABLE 6

| Thin Film | Host | Dopant | Dopant | LT50 Rate | |
|---|---|---|---|---|---|
| No. | No. | No. | Kq Rate | at RT | Note |
| 6-1 | BH-2 | BD-2 | 1 | 1 | Comparative Example |
| 6-2 | BH-2 | CD-2 | 0.7 | 0.9 | Comparative Example |
| 6-3 | BH-2 | CD-10 | 0.65 | 0.8 | Comparative Example |
| 6-4 | BH-2 | CD-16 | 0.51 | 0.8 | Comparative Example |
| 6-5 | BH-2 | CD-25 | 0.5 | 0.8 | Comparative Example |
| 6-6 | H-6 | BD-2 | 1.01 | 1.1 | Comparative Example |
| 6-7 | H-8 | BD-2 | 0.99 | 1.2 | Comparative Example |
| 6-8 | H-6 | CD-2 | 0.75 | 2.6 | Example |
| 6-9 | H-8 | CD-2 | 0.76 | 2.9 | Example |
| 6-10 | H-6 | CD-10 | 0.65 | 3.4 | Example |
| 6-11 | H-8 | CD-10 | 0.65 | 3.3 | Example |
| 6-12 | H-6 | CD-16 | 0.48 | 4.6 | Example |
| 6-13 | H-8 | CD-16 | 0.51 | 4.4 | Example |
| 6-14 | H-6 | CD-25 | 0.5 | 4.3 | Example |
| 6-15 | H-8 | CD-25 | 0.51 | 4.1 | Example |

<<Analysis of Results: Example 1>>

As shown in Table 6, in the thin films for evaluation 6-8˜6-15, a Forester type host was used as a host, and a core-shell type dopant satisfying the requirements of the present invention was used as a dopant. As a result, it was confirmed that the thin films for evaluation 6-8˜6-15 have a good energy transfer of excitons from a host to a dopant, leading to an elongated emission lifetime.

### Example 2

Next, in Example 2, a compound assuming blue emission was used, and an emission lifetime of each thin film was determined.

<<Preparation of Thin Films for Evaluation>>

Every thin film for evaluation was prepared by the same method as in Example 1 except that a “host” and a “dopant” listed in Table 7 were used.

<<Evaluation of Emission Lifetime, Calculation of Kq>>

Every emission lifetime was evaluated by the same method as in Example 1.

Note, every LT50 rate was calculated as a relative rate (i.e., an LT50 rate) per half-value period of the thin film for evaluation 7-1 thus set to 1.

Every energy transfer rate (Kq) from a dopant to the quencher was calculated by the same method as in Reference Example 1.

Here, every Kq rate was calculated as a relative rate per Kq of the thin film for evaluation 7-1 thus set to 1.

TABLE 7

| Thin | | | | LT50 | |
|---|---|---|---|---|---|
| Film | Host | Dopant | Dopant | Rate | |
| No. | No. | No. | Kq Rate | at RT | Note |
| 7-1 | BH-3 | BD-3 | 1 | 1 | Comparative Example |
| 7-2 | BH-3 | CD-5 | 0.69 | 0.9 | Comparative Example |
| 7-3 | BH-3 | CD-29 | 0.52 | 0.8 | Comparative Example |
| 7-4 | BH-3 | CD-36 | 0.51 | 0.8 | Comparative Example |
| 7-5 | BH-3 | CD-39 | 0.49 | 0.8 | Comparative Example |
| 7-6 | H-15 + H-16 | BD-3 | 1.01 | 1.1 | Comparative Example |
| | (1:1) | | | | |
| 7-7 | H-20 + H-22 | BD-3 | 1 | 1.2 | Comparative Example |
| | (1:1) | | | | |
| 7-8 | H-15 + H-16 | CD-5 | 0.69 | 3 | Example |
| | (1:1) | | | | |
| 7-9 | H-20 + H-22 | CD-5 | 0.68 | 2.9 | Example |
| | (1:1) | | | | |
| 7-10 | H-15 + H-16 | CD-29 | 0.52 | 4.3 | Example |
| | (1:1) | | | | |
| 7-11 | H-20 + H-22 | CD-29 | 0.55 | 4.1 | Example |
| | (1:1) | | | | |
| 7-12 | H-15 + H-16 | CD-36 | 0.45 | 4.4 | Example |
| | (1:1) | | | | |
| 7-13 | H-20 + H-22 | CD-36 | 0.5 | 4 | Example |
| | (1:1) | | | | |
| 7-14 | H-15 + H-16 | CD-39 | 0.48 | 4.2 | Example |
| | (1:1) | | | | |
| 7-15 | H-20 + H-22 | CD-39 | 0.47 | 4.5 | Example |
| | (1:1) | | | | |

<<Analysis of Results: Example 2>>

As shown in Table 7, in the thin films for evaluation 7-8˜7-15, two types of hosts combined to form an excited complex, and a core-shell type dopant satisfying the requirements of the present invention was used as a dopant. As a result, it was confirmed that the thin films for evaluation 7-8˜7-15 have good energy transfer of excitons from a host to a dopant, leading to an elongated emission lifetime.

### Example 3

Next, in Example 3, a compound assuming green emission was used, and an emission lifetime of every thin film was determined.

<<Preparation of Thin Films for Evaluation>>

Every thin film for evaluation was prepared by the same method as in Example 1 except that a “host” and a “dopant” listed in Table 8 were used.

<<Evaluation of Emission Lifetime, Calculation of Kq>>

Every emission lifetime was evaluated by the same method as in Example 1.

Note, every LT50 rate was calculated as a relative rate (i.e., an LT50 rate) per half-value period of the thin film for evaluation 8-1 thus set to 1.

Every energy transfer rate (Kq) from a dopant to the quencher was calculated by the same method as in Reference Example 1.

Here, every Kq rate was calculated as a relative rate per Kq of the thin film for evaluation 8-1 thus set to 1.

TABLE 8

| Thin | | | | LT50 | |
|---|---|---|---|---|---|
| Film | Host | Dopant | Dopant | Rate | |
| No. | No. | No. | Kq Rate | at RT | Note |
| 8-1 | GH-1 | GD-1 | 1 | 1 | Comparative Example |
| 8-2 | GH-1 | GD-5 | 1.02 | 0.9 | Comparative Example |
| 8-3 | GH-1 | CD-40 | 0.74 | 0.8 | Comparative Example |
| 8-4 | GH-1 | CD-47 | 0.75 | 0.9 | Comparative Example |
| 8-5 | GH-1 | CD-45 | 0.51 | 0.8 | Comparative Example |
| 8-6 | H-7 | GD-1 | 1.02 | 1.1 | Comparative Example |
| 8-7 | H-20 + H-21 | GD-1 | 0.99 | 1.2 | Comparative Example |
| | (1:1) | | | | |
| 8-8 | H-7 | GD-5 | 1 | 1 | Comparative Example |
| 8-9 | H-20 + H-21 | GD-5 | 0.99 | 1.1 | Comparative Example |
| | (1:1) | | | | |
| 8-10 | H-7 | CD-40 | 0.72 | 2.9 | Example |
| 8-11 | H-20 + H-21 | CD-40 | 0.7 | 2.8 | Example |
| | (1:1) | | | | |
| 8-12 | H-7 | CD-41 | 0.77 | 3 | Example |
| 8-13 | H-20 + H-21 | CD-41 | 0.76 | 2.7 | Example |
| | (1:1) | | | | |
| 8-14 | H-7 | CD-45 | 0.49 | 4.2 | Example |
| 8-15 | H-20 + H-21 | CD-45 | 0.5 | 4.1 | Example |
| | (1:1) | | | | |

<<Analysis of Results: Example 3>>

As shown in Table 8, in the thin films for evaluation 8-10˜8-15, a Forester type host or two types of hosts combined to form an excited complex were used as a host, and a core-shell type dopant satisfying the requirements of the present invention was used as a dopant. As a result, it was confirmed that the thin films for evaluation 8-10˜8-15 have good energy transfer of excitons from a host to a dopant, leading to an elongated emission lifetime in spite of every thin film having green emission.

### Example 4

Next, in Example 4, a compound assuming red emission was used, and an emission lifetime of every thin film was determined.

<<Preparation of Thin Films for Evaluation>>

Every thin film for evaluation was prepared by the same method as in Example 1 except that a “host” and a “dopant” listed in Table 9 were used.

<<Evaluation of Emission Lifetime, Calculation of Kq>>

Every emission lifetime was evaluated by the same method as in Example 1.

Note, every LT50 rate was calculated as a relative rate (i.e., an LT50 rate) per half-value period of the thin film for evaluation 9-1 thus set to 1.

Every energy transfer rate (Kq) from a dopant to the quencher was calculated by the same method as in Reference Example 1.

Here, every Kq rate was calculated as a relative rate per Kq of the thin film for evaluation 9-1 thus set to 1.

TABLE 9

| Thin | | | | LT50 | |
|---|---|---|---|---|---|
| Film | Host | Dopant | Dopant | Rate | |
| No. | No. | No. | Kq Rate | at RT | Note |
| 9-1 | H-21 | RD-1 | 1 | 1 | Comparative Example |
| 9-2 | H-21 | RD-2 | 1.01 | 0.9 | Comparative Example |
| 9-3 | H-21 | CD-46 | 0.71 | 0.8 | Comparative Example |
| 9-4 | H-21 | CD-48 | 0.59 | 0.9 | Comparative Example |
| 9-5 | H-21 | CD-49 | 0.57 | 0.8 | Comparative Example |
| 9-6 | H-2 | RD-1 | 1.01 | 1.1 | Comparative Example |
| 9-7 | H-4 | RD-1 | 0.98 | 1.2 | Comparative Example |
| 9-8 | H-17 + H-18 | RD-1 | 1 | 1 | Comparative Example |
| | (1:1) | | | | |
| 9-9 | H-2 | RD-2 | 1 | 1.1 | Comparative Example |
| 9-10 | H-4 | RD-2 | 1.02 | 1 | Comparative Example |
| 9-11 | H-17 + H-18 | RD-2 | 0.99 | 0.9 | Comparative Example |
| | (1:1) | | | | |
| 9-12 | H-2 | CD-46 | 0.69 | 3 | Example |
| 9-13 | H-4 | CD-46 | 0.68 | 2.7 | Example |
| 9-14 | H-17 + H-18 | CD-46 | 0.71 | 2.9 | Example |
| | (1:1) | | | | |
| 9-15 | H-2 | CD-48 | 0.6 | 3.9 | Example |
| 9-16 | H-4 | CD-48 | 0.58 | 4.3 | Example |
| 9-17 | H-17 + H-18 | CD-48 | 0.58 | 4.2 | Example |
| | (1:1) | | | | |
| 9-18 | H-2 | CD-49 | 0.57 | 4.3 | Example |
| 9-19 | H-4 | CD-49 | 0.53 | 4.1 | Example |
| 9-20 | H-17 + H-18 | CD-49 | 0.56 | 4.5 | Example |
| | (1:1) | | | | |

<<Analysis of Results: Example 4>>

As shown in Table 9, in the thin films for evaluation 9-12˜9-20, a Forester type host or two types of hosts combined to form an excited complex were used as a host, and a core-shell type dopant satisfying the requirements of the present invention was used as a dopant. As a result, it was confirmed that the thin films for evaluation 9-12˜9-20 have good energy transfer of excitons from a host to a dopant, leading to an elongated emission lifetime in spite of every thin film having red emission.

### Example 5

Next, in Example 5, a compound assuming blue emission was used, and a lifetime of every lighting apparatus (and element) was determined.

<<Preparation of Lighting Apparatus for Evaluation>>

A glass substrate with a dimension of 50 mm×50 mm, a thickness of 0.7 mm was vapor deposited with ITO (indium.tin oxide) serving as an anode with a thickness of 150 nm, and subjected to patterning. Then, a transparent substrate attached with the ITO transparent electrode was ultrasonically washed by isopropyl alcohol, dried by a dry nitrogen gas, and cleaned with UV ozone for 5 min. Then, the resulting transparent substrate was held in a substrate holder of a commercially available vacuum vapor deposition device.

Constituent materials of each layer were filled in each resistance heating boat for vapor deposition thus placed inside the vacuum vapor deposition device at optimal amounts respectively for preparing each element. The resistance heating boat thus used was made of molybdenum or tungsten.

Next, HT-1 was vapor deposited at a vapor deposition rate of 0.1 nm/s on the ITO transparent electrode, to form a hole injection layer with a thickness of 30 nm. Next, the resistance heating boat filled with a “host” and a “dopant” listed in Table 10 were heated by carrying a current, and the host and the dopant were vapor codeposited on the hole transport layer so that the respective contents thereof became 85 vol % and 15 vol %, thereby to form a luminescent layer with a thickness of 40 nm.

Then, HB-1 was vapor deposited at a vapor deposition rate of 0.1 nm/s so as to form a first electron transport layer with a thickness of 5 nm. Further, on that layer, ET-1 was vapor deposited at a vapor deposition rate of 0.1 nm/s, to form a second electron transport layer with a thickness of 45 nm. After that, lithium fluoride was vapor deposited to have a thickness of 0.5 nm, and subsequently aluminum was vapor deposed with a thickness of 100 nm to form a cathode. As a result, an organic EL element for evaluation was prepared.

After preparation of the organic EL element, a non-light emitting surface of the organic EL element was covered by a glass case under the atmosphere of high purity nitrogen gas with the purity of 99.999% or more. Then, a glass substrate with a thickness of 300 □m was used as a sealing substrate, and an epoxy based photocurable adhesive (Ruxtruck TOAGOSEI CO., LTD.) serving as a sealing material was applied to a periphery of the glass case. Next, the resulting glass case was put over the cathode to be tightly attached to the sealing substrate, and UV light was irradiated from a glass substrate side to cure the adhesive and seal the glass case. Accordingly, a lighting apparatus having the formation illustrated in FIGS. 9 and 10 was prepared.

<<Evaluation of Continuous Driving Stability (Half-Life)>>

In every lighting apparatus for evaluation, brightness was measured by a spectral radiance meter CS-2000, and a time in which the brightness thus measured was reduced by half (i.e., LT50) was obtained as a half-life. A current value of 15 mA/cm² was set to the driving condition.

Then, as to every lighting apparatus for evaluation, a relative value (i.e., a half-life: a relative value) per half-life of the lighting apparatus for evaluation 10-1 thus set to 1 was calculated.

TABLE 10

| Device No. | Host No. | Dopant No. | Halflife | Note |
|---|---|---|---|---|
| 10-1 | BH-2 | BD-2 | 1 | Comparative Example |
| 10-2 | BH-2 | CD-2 | 0.8 | Comparative Example |
| 10-3 | BH-2 | CD-10 | 0.9 | Comparative Example |
| 10-4 | BH-2 | CD-16 | 0.8 | Comparative Example |
| 10-5 | BH-2 | CD-25 | 0.7 | Comparative Example |
| 10-6 | H-6 | BD-2 | 1 | Comparative Example |
| 10-7 | H-8 | BD-2 | 1.2 | Comparative Example |
| 10-8 | H-6 | CD-2 | 2.9 | Example |
| 10-9 | H-8 | CD-2 | 2.8 | Example |
| 10-10 | H-6 | CD-10 | 3.2 | Example |
| 10-11 | H-8 | CD-10 | 3.6 | Example |
| 10-12 | H-6 | CD-16 | 4.6 | Example |
| 10-13 | H-8 | CD-16 | 4.7 | Example |
| 10-14 | H-6 | CD-25 | 4.9 | Example |
| 10-15 | H-8 | CD-25 | 4.5 | Example |

<<Analysis of Results: Example 5>>

As shown in Table 10, in the lighting apparatuses for evaluation 10-8˜10-15, a Forester type host was used as a host, and a core-shell type dopant satisfying the requirements of the present invention was used as a dopant. As a result, it was confirmed that the lighting apparatuses for evaluation 10-8˜10-15 are excellent in continuous driving stability.

### Example 6

Next, in Example 6, a compound assuming blue emission was used, and a lifetime of every lighting apparatus (and element) was determined.

<<Preparation of Lighting Apparatus for Evaluation>>

A glass substrate with a dimension of 50 mm×50 mm, a thickness of 0.7 mm was vapor deposited with ITO (indium.tin oxide) serving as an anode with a thickness of 150 nm, and subjected to patterning. Then, a transparent substrate attached with the ITO transparent electrode was ultrasonically washed by isopropyl alcohol, dried by a dry nitrogen gas, and cleaned with UV ozone for 5 min. Then, the resulting transparent substrate was held in a substrate holder of a commercially available vacuum vapor deposition device.

Constituent materials of each layer were filled in each resistance heating boat for vapor deposition thus placed inside the vacuum vapor deposition device at optimal amounts respectively for preparing each element. The resistance heating boat thus used was made of molybdenum or tungsten

After reducing the pressure down to a degree of vacuum of 1×10⁻⁴ Pa, a resistance heating boat filled with HI-2 was heated by carrying a current so that HI-2 was vapor deposited at a vapor deposition rate of 0.1 nm/s on the ITO transparent electrode, to form a hole injection layer with a thickness of 10 nm

Next, HT-2 was vapor deposited at a vapor deposition rate of 0.1 nm/s on the above hole injection layer, to form a hole transport layer with a thickness of 30 nm.

Next, HB-2 was vapor deposited at a vapor deposition rate of 0.1 nm/s on the above hole transport layer, to form a first electron transport layer with a thickness of 5 nm. Further, on the first electron transport layer, ET-2 was vapor deposited at a vapor deposition rate of 0.1 nm/s, to form a second electron transport layer with a thickness of 45 nm. After that, lithium fluoride was vapor deposited with a thickness of 0.5 nm, and subsequently aluminum was vapor deposited with a thickness of 100 nm to form a cathode. Accordingly, an organic EL element for evaluation was prepared.

After preparation of the organic EL element, a non-light emitting surface of the organic EL element was covered by a glass case under the atmosphere of high purity nitrogen gas with the purity of 99.999% or more. Then, a glass substrate was used as a sealing substrate with a thickness of 300 □m, and an epoxy based photocurable adhesive (Ruxtruck TOAGOSEI CO., LTD.) serving as a sealing material was applied to a periphery of the glass case. Next, the resulting glass case was put over the cathode to be tightly attached to the sealing substrate, and UV light was irradiated from a glass substrate side to cure the adhesive and seal the glass case. Accordingly, a lighting apparatus having the formation illustrated in FIGS. 9 and 10 was prepared.

<<Evaluation of Continuous Driving Stability (Half-Life)>>

Continuous driving stability (i.e., a half-life) was evaluated by the same method as in Example 5. Note, every “half-life: relative value” was calculated as a relative value per half-life of the lighting apparatus 11-1 thus set to 1.

TABLE 11

| Device | | | | |
|---|---|---|---|---|
| No. | Host No. | Dopant No. | Halflife | Note |
| 11-1 | BH-3 | BD-3 | 1 | Comparative Example |
| 11-2 | BH-3 | CD-5 | 0.8 | Comparative Example |
| 11-3 | BH-3 | CD-29 | 0.9 | Comparative Example |
| 11-4 | BH-3 | CD-36 | 1.1 | Comparative Example |
| 11-5 | BH-3 | CD-39 | 0.9 | Comparative Example |
| 11-6 | H-15 + H-16 | BD-3 | 1 | Comparative Example |
| | (1:1) | | | |
| 11-7 | H-20 + H-22 | BD-3 | 1.1 | Comparative Example |
| | (1:1) | | | |
| 11-8 | H-15 + H-16 | CD-5 | 3.2 | Example |
| | (1:1) | | | |
| 11-9 | H-20 + H-22 | CD-5 | 3 | Example |
| | (1:1) | | | |
| 11-10 | H-15 + H-16 | CD-29 | 4.2 | Example |
| | (1:1) | | | |
| 11-11 | H-20 + H-22 | CD-29 | 4.4 | Example |
| | (1:1) | | | |
| 11-12 | H-15 + H-16 | CD-36 | 4.5 | Example |
| | (1:1) | | | |
| 11-13 | H-20 + H-22 | CD-36 | 4.1 | Example |
| | (1:1) | | | |
| 11-14 | H-15 + H-16 | CD-39 | 4.6 | Example |
| | (1:1) | | | |
| 11-15 | H-20 + H-22 | CD-39 | 4.3 | Example |
| | (1:1) | | | |

<<Analysis of Results: Example 6>>

As shown in Table 11, in the lighting apparatuses for evaluation 11-8˜11-15, a core-shell type dopant satisfying the requirements of the present invention was used as a dopant, and two types of hosts combined to form an excited complex were used as a host. As a result, it was confirmed that the lighting apparatuses for evaluation 11-8˜11-15 are excellent in continuous driving stability.

### Example 7

Next, in Example 6, a compound assuming green emission was used, and a lifetime of every lighting apparatus (and element) was determined.

<<Preparation of Lighting Apparatus for Evaluation>>

A glass substrate with a dimension of 50 mm×50 mm, a thickness of 0.7 mm was vapor deposited with ITO (indium.tin oxide) serving as an anode with a thickness of 150 nm, and subjected to patterning. Then, a transparent substrate attached with the ITO transparent electrode was ultrasonically washed by isopropyl alcohol, dried by a dry nitrogen gas, and cleaned with UV ozone for 5 min. Then, the resulting transparent substrate was held in a substrate holder of a commercially available vacuum vapor deposition device.

Constituent materials of each layer were filled in each resistance heating boat for vapor deposition thus placed inside the vacuum vapor deposition device at optimal amounts respectively for preparing each element. The resistance heating boat thus used was made of molybdenum or tungsten

After reducing the pressure down to a degree of vacuum of 1×10⁻⁴ Pa, a resistance heating boat filled with HI-2 was heated by carrying a current so that HI-2 was vapor deposited at a vapor deposition rate of 0.1 nm/s on the ITO transparent electrode, to form a hole injection layer with a thickness of 20 nm

Next, HT-1 was vapor deposited at a vapor deposition rate of 0.1 nm/s, to form a hole transport layer with a thickness of 20 nm.

Next, a resistance heating boat filled with a “host” and a “dopant” listed in Table 12 was heated by carrying a current, and the host and the dopant were vapor codeposited on the hole transport layer so that the contents of the host and the dopant were set to 85 vol % and 15 vol %, respectively, thereby to form a luminescent layer with a thickness of 30 nm.

Next, HB-3 was vapor deposited at a vapor deposition rate of 0.1 nm/s to form a first electron transport layer with a thickness of 10 nm. Further, on the first electron transport layer, ET-2 was vapor deposited at a vapor deposition rate of 0.1 nm/s to form a second electron transport layer with a thickness of 40 nm. After that, lithium fluoride was vapor deposited with a thickness of 0.1 nm, and subsequently aluminum was vapor deposited with a thickness of 100 nm to form a cathode. Accordingly, an organic EL element for evaluation was prepared.

After preparation of the organic EL element, a non-light emitting surface of the organic EL element was covered by a glass case under the atmosphere of high purity nitrogen gas with the purity of 99.999% or more. Then, a glass substrate was used as a sealing substrate with a thickness of 300 □m, and an epoxy based photocurable adhesive (Ruxtruck TOAGOSEI CO., LTD.) serving as a sealing material was applied to a periphery of the glass case. Next, the resulting glass case was put over the cathode to be tightly attached to the sealing substrate, and UV light was irradiated from a glass substrate side to cure the adhesive and seal the glass case. Accordingly, a lighting apparatus having the formation illustrated in FIGS. 9 and 10 was prepared.

<<Evaluation of Continuous Driving Stability (Half-Life)>>

The continuous driving stability (i.e., a half-life) was evaluated by the same method as in Example 5.

Note, a “half-life: a relative value” was calculated as a relative value per half-life of the lighting apparatus for evaluation 12-1 thus set to 1.

TABLE 12

| Device | | | | |
|---|---|---|---|---|
| No. | Host No. | Dopant No. | Halflife | Note |
| 12-1 | GH-1 | GD-1 | 1 | Comparative Example |
| 12-2 | GH-1 | GD-5 | 1 | Comparative Example |
| 12-3 | GH-1 | CD-40 | 0.9 | Comparative Example |
| 12-4 | GH-1 | CD-41 | 0.7 | Comparative Example |
| 12-5 | GH-1 | CD-45 | 0.8 | Comparative Example |
| 12-6 | H-7 | GD-1 | 1 | Comparative Example |
| 12-7 | H-20 + H-21 | GD-1 | 1.1 | Comparative Example |
| | (1:1) | | | |
| 12-8 | H-7 | GD-5 | 1.2 | Comparative Example |
| 12-9 | H-20 + H-21 | GD-5 | 1.1 | Comparative Example |
| | (1:1) | | | |
| 12-10 | H-7 | CD-40 | 3 | Example |
| 12-11 | H-20 + H-21 | CD-40 | 2.8 | Example |
| | (1:1) | | | |
| 12-12 | H-7 | CD-41 | 2.7 | Example |
| 12-13 | H-20 + H-21 | CD-41 | 3 | Example |
| | (1:1) | | | |
| 12-14 | H-7 | CD-45 | 4.4 | Example |
| 12-15 | H-20 + H-21 | CD-45 | 4.2 | Example |
| | (1:1) | | | |

<<Analysis of Results: Example 7>>

As shown in Table 12, in the lighting apparatuses for evaluation 12-10˜12-15, a core-shell type dopant satisfying the requirements of the present invention was used as a dopant, and a Forester type host or two types of hosts combined to form an excited complex were used as a host. As a result, it was confirmed that the lighting apparatuses for evaluation 12-10˜12-15 are excellent in continuous driving stability even as a device with green emission.

### Example 8

Next, in Example 8, a compound assuming red emission was used, and a lifetime of every lighting apparatus (and element) was determined.

<<Preparation of Lighting Apparatus for Evaluation>>

A glass substrate with a dimension of 50 mm×50 mm, a thickness of 0.7 mm was vapor deposited with ITO (indium.tin oxide) serving as an anode with a thickness of 120 nm, and subjected to patterning. Then, a transparent substrate attached with the ITO transparent electrode was ultrasonically washed by isopropyl alcohol, dried by a dry nitrogen gas, and cleaned with UV ozone for 5 min.

Then, a thin film was deposited on the resulting transparent substrate by a spin coating method under the conditions of 3000 rpm and 30 sec via using a solution prepared by diluting poly(3,4-ethylenedioxythiophene)-polystyrene sulfonate (PEDOT/PSS, Bayer Ltd., Baytron PAI 4083) with pure water to be a 70% solution. After forming a thin film, the resulting substrate was dried at 200° C. for 1 hr, thereby to form a hole injection layer with a thickness of 20 nm. Next, the resulting transparent substrate was held in a substrate holder of a commercially available vacuum vapor deposition device.

Constituent materials of each layer were filled in each resistance heating boat for vapor deposition thus placed inside the vacuum vapor deposition device at optimal amounts respectively for preparing each element. The resistance heating boat thus used was made of molybdenum or tungsten

After reducing the pressure down to a degree of vacuum of 1×10⁻⁴ Pa, a resistance heating boat filled with HI-2 was heated by carrying a current so that HI-2 was vapor deposited at a vapor deposition rate of 0.1 nm/s on the hole injection layer, to form a hole transport layer with a thickness of 20 nm.

Next, a resistance heating boat filled with a “host” and a “dopant” listed in Table 13 was heated by carrying a current, and the host and the dopant were vapor codeposited on the hole transport layer so that the contents of the host and the dopant were set to 85 vol % and 15 vol %, respectively, thereby to form a luminescent layer with a thickness of 40 nm.

Next, ET-1 was vapor deposited at a vapor deposition rate of 0.1 nm/s to form an electron transport layer with a thickness of 40 nm.

Further, on the electron transport layer, lithium fluoride was vapor deposited with a thickness of 0.5 nm, and subsequently aluminum was vapor deposited with a thickness of 100 nm to form a cathode. Accordingly, an organic EL element for evaluation was prepared.

After preparation of the organic EL element, a non-light emitting surface of the organic EL element was covered by a glass case under the atmosphere of high purity nitrogen gas with the purity of 99.999% or more. Then, a glass substrate with a thickness of 300 □m was used as a sealing substrate, and an epoxy based photocurable adhesive (Ruxtruck TOAGOSEI CO., LTD.) serving as a sealing material was applied to a periphery of the glass case. Next, the resulting glass case was put over the cathode and tightly attached to the sealing substrate, and UV light was irradiated from a glass substrate side to cure the adhesive and seal the glass case. Accordingly, a lighting apparatus having the formation illustrated in FIGS. 9 and 10 was prepared.

<<Evaluation of Continuous Driving Stability (Half-Life)>>

The continuous driving stability (i.e., a half-life) was evaluated by the same method as in Example 5.

Note, a “half-life: a relative value” was calculated as a relative value per half-life of the lighting apparatus for evaluation 13-1 thus set to 1.

TABLE 13

| Device | | | | |
|---|---|---|---|---|
| No. | Host No. | Dopant No. | Halflife | Note |
| 13-1 | H-21 | RD-1 | 1 | Comparative Example |
| 13-2 | H-21 | RD-2 | 1 | Comparative Example |
| 13-3 | H-21 | CD-46 | 0.9 | Comparative Example |
| 13-4 | H-21 | CD-48 | 1 | Comparative Example |
| 13-5 | H-21 | CD-49 | 0.8 | Comparative Example |
| 13-6 | H-2 | RD-1 | 1.2 | Comparative Example |
| 13-7 | H-4 | RD-1 | 1 | Comparative Example |
| 13-8 | H-17 + H-18 | RD-1 | 0.9 | Comparative Example |
| | (1:1) | | | |
| 13-9 | H-2 | RD-2 | 0.8 | Comparative Example |
| 13-10 | H-4 | RD-2 | 1 | Comparative Example |
| 13-11 | H-17 + H-18 | RD-2 | 0.9 | Comparative Example |
| | (1:1) | | | |
| 13-12 | H-2 | CD-46 | 3.1 | Example |
| 13-13 | H-4 | CD-46 | 2.9 | Example |
| 13-14 | H-17 + H-18 | CD-46 | 3 | Example |
| | (1:1) | | | |
| 13-15 | H-2 | CD-48 | 4.2 | Example |
| 13-16 | H-4 | CD-48 | 4 | Example |
| 13-17 | H-17 + H-18 | CD-48 | 4.4 | Example |
| | (1:1) | | | |
| 13-18 | H-2 | CD-49 | 4.1 | Example |
| 13-19 | H-4 | CD-49 | 4.5 | Example |
| 13-20 | H-17 + H-18 | CD-49 | 4.3 | Example |
| | (1:1) | | | |

<<Analysis of Results: Example 8>>

As shown in Table 13, in the lighting apparatuses for evaluation 13-12˜13-20, a core-shell type dopant satisfying the requirements of the present invention was used as a dopant, and a Forester type host or two types of hosts combined to form an excited complex were used as a host. As a result, it was confirmed that the lighting apparatuses for evaluation 13-12˜13-20 are excellent in continuous driving stability even as a device with red emission.

### Example 9

Next, in Example 9, a lifetime of every lighting apparatus (and element) thus prepared by a wet-process using a coating liquid was evaluated.

<<Preparation of Lighting Apparatus for Evaluation>>

(Preparation of Base Material)

First, an inorganic gas barrier layer made of SiOₓ was formed to have a thickness of 500 nm on the entire surface of an anode forming side, the anode made of a polyethylene naphthalate film (hereinafter, refer to as PEN: Teijin DuPont Films), by using an atmospheric plasma electric discharge treating device described in Japanese Unexamined Patent Application Publication No. 2004-68143. In the above process, produced was a flexible base material having gas barrier properties with oxygen permeability of 0.001 mL/(m²·24 hr) or less and steam permeability of 0.001 g/(m²·24 hr) or less.

(Formation of Anode)

ITO (indium.tin oxide) was deposited on the above base material thus prepared to have a thickness of 120 nm by a spattering method. The resulting layer was subjected to patterning via a photolithography method, to form an anode. Note, a pattern thus formed was made to have an area of the light-emitting region with a dimension of 5 cm×5 cm.

(Formation of Hole Injection Layer)

The base material forming the anode was ultrasonically washed by isopropyl alcohol, dried by a dry nitrogen gas, and cleaned with UV ozone for 5 min. Then, a 2 mass % (PEDOT/PSS) solution prepared by diluting a dispersing liquid of poly(3,4-ethylenedioxy thiophene)/polystyrene sulfonate (PEDOT/PSS) thus prepared the same as in Example 16 of Japanese Patent Publication No. 4509787 was applied onto the base material thus forming the anode via a die coating method. The resulting base material was naturally dried to form a hole injection layer with a thickness of 40 nm.

(Formation of Hole Transport Layer)

Next, the base material forming the hole injection layer was placed under the nitrogen atmosphere using nitrogen gas (Grade G1), and applied with a coating liquid for forming a hole transport layer having the following composition by a die coating method at 5 m/min. After subjected to natural drying, the resultant base material was kept at 130° C. for 30 min to form a hole transport layer having a thickness of 30 nm.

(Coating Liquid for Forming Hole Transport Layer)
Hole transport material, HT-3 (weight average molecular weight Mw=80000): 10 parts by mass.
Chlorobenzene: 3000 parts by mass

(Formation of Luminescent Layer)

Next, the base material thus forming the hole transport layer was applied with a coating liquid for forming luminescent layer with the following composition by a die coating method at an applying rate of 5 m/min. The resultant base material was naturally dried, and kept at 120° C. for 30 min, thereby to form a luminescent layer with a thickness of 50 nm.

<Coating Liquid for Forming Luminescent Layer>

Host compound listed in Table 14: 9 parts by mass.

Dopant compound listed in Table 14: 1 part by mass.

Isopropyl acetate: 2000 parts by mass.

(Formation of Electron Transport Layer) Next, the base material thus forming a block layer was applied with a coating liquid for forming electron transport layer with the following composition by a die coating method at an applying rate of 5 m/min. The resultant base material was naturally dried, and kept at 80° C. for 30 min, thereby to form an electron transport layer with a thickness of 30 nm.

<Coating Liquid for Forming Electron Transport Layer>

ET-1: 6 parts by mass.

1H, 1H, 3H-tetrafluoropropanol (TFPO): 2000 parts by mass.

(Formation of Electron Injection Layer and Cathode>

Next, the resulting base material was attached to the vacuum vapor deposition device without exposed to the air. Further, resistance heating boats both made of molybdenum respectively filled with sodium fluoride and potassium fluoride were attached to the vacuum vapor deposition device, and the vacuum vessel was decompressed down to 4×10⁻⁵ Pa. After that, one of the boats was heated by carrying a current, and sodium fluoride was vapor deposited on the electron transport layer at 0.02 nm/sec to form a thin film with a thickness of 1 nm. Similarly, potassium fluoride was vapor deposited on the sodium fluoride thin film at 0.02 nm/sec to form an electron injection layer with a thickness of 1.5 nm.

After that, aluminum was vapor deposited to form a cathode with a thickness of 100 nm.

(Sealing)

Next, a sealing base material was bonded to a layered body thus formed by the above process via using a commercially available roll laminator.

As a sealing base material, an adhesive layer with a thickness of 1.5 □m was provided on flexible aluminum foil with a thickness of 30 □m (TOYO ALUMINUM K.K.) via using a two-component reaction type urethane based adhesive for dry lamination. Hereby, a sealing base material laminated with a polyethylene terephthalate (PET) having a thickness of 12 □m was prepared.

As a sealing adhesive, a thermocuring adhesive was uniformly applied with a thickness of 20 □m to an adhesive surface (i.e., a glazed surface) of aluminum foil serving as a sealing base material using a dispenser. Further, the resultant material was transferred under a nitrogen atmosphere with an oxygen concentration of 0.8 ppm, at the dew-point temperature of −80° C. or less, and dried for 12 hr or more so that a water content of the sealing adhesive was adjusted to 100 ppm or less.

As the thermocuring adhesive, used was an epoxy base adhesive prepared by mixed with the following (A)˜(C).

(A) Bisphenol A diglycidyl ether (DGEBA)

(B) Dicyandiamide (DICY)

(C) Epoxy adduct based curing promoter

The above sealing base material was closely attached to the layered body and arranged. Then, the material and the body were closely attached and sealed under the conditions of a pressure-bonding temperature of 100° C., a pressure of 0.5 Mpa and a device rate of 0.3 m/min via using a pressure roller. Hereby, a lighting apparatus for evaluation shown in FIG. 11 was prepared.

<<Evaluation of Continuous Driving Stability (Half-Life)>>

Continuous driving stability (i.e., a half-life) was evaluated by the same method as in Example 5.

Note, a “half-life: a relative value” was calculated as a relative rate per half-life of the lighting apparatus for evaluation 14-1 thus set to 1.

TABLE 14

| Device | | | | |
|---|---|---|---|---|
| No. | Host No. | Dopant No. | Halflife | Note |
| 14-1 | BH-2 | BD-2 | 1 | Comparative Example |
| 14-2 | BH-2 | CD-2 | 0.8 | Comparative Example |
| 14-3 | BH-2 | CD-13 | 0.9 | Comparative Example |
| 14-4 | BH-2 | CD-19 | 1.1 | Comparative Example |
| 14-5 | BH-2 | CD-26 | 0.9 | Comparative Example |
| 14-6 | H-15 + H-16 | BD-2 | 1 | Comparative Example |
| | (1:1) | | | |
| 14-7 | H-20 + H-22 | BD-2 | 1.1 | Comparative Example |
| | (1:1) | | | |
| 14-8 | H-15 + H-16 | CD-2 | 3.3 | Example |
| | (1:1) | | | |
| 14-9 | H-20 + H-22 | CD-2 | 3 | Example |
| | (1:1) | | | |
| 14-10 | H-15 + H-16 | CD-13 | 4 | Example |
| | (1:1) | | | |
| 14-11 | H-20 + H-22 | CD-13 | 4.1 | Example |
| | (1:1) | | | |
| 14-12 | H-15 + H-16 | CD-19 | 5.2 | Example |
| | (1:1) | | | |
| 14-13 | H-20 + H-22 | CD-19 | 5 | Example |
| | (1:1) | | | |
| 14-14 | H-15 + H-16 | CD-26 | 4.9 | Example |
| | (1:1) | | | |
| 14-15 | H-20 + H-22 | CD-26 | 5.2 | Example |
| | (1:1) | | | |

<<Analysis of Results: Example 9>>

As shown in Table 14, in the lighting apparatuses for evaluation 14-8˜14-15, a core-shell type dopant satisfying the requirements of the present invention was used as a dopant, and two types of hosts combined to form an excited complex were used as a host. As a result, it was confirmed that the lighting apparatuses for evaluation 14-8˜14-15 are excellent in continuous driving stability even in an element prepared by a coating process.

### Example 9

Next, in Example 10, a lifetime of every lighting apparatus (and element) thus prepared by an inkjet process using a coating liquid was evaluated.

<<Preparation of Lighting Apparatus for Evaluation>>

(Preparation of Base Material)

First, an inorganic gas barrier layer made of SiOₓ was formed to have a thickness of 500 nm on the entire surface of an anode forming side, the anode made of a polyethylene naphthalate film (hereinafter, refer to as PEN: Teijin DuPont Films), by using an atmospheric plasma electric discharge treating device described in Japanese Unexamined Patent Application Publication No. 2004-68143. In the above process, produced was a flexible base material having gas barrier properties with oxygen permeability of 0.001 mL/(m²·24 hr) or less and steam permeability of 0.001 g/(m²·24 hr) or less.

(Formation of Anode)

ITO (indium.tin oxide) was deposited on the above base material thus prepared to have a thickness of 120 nm by a spattering method. The resulting layer was subjected to patterning via a photolithography method, to form an anode. Note, a pattern thus formed was made so that have the light-emitting region had an area with a dimension of 5 cm×5 cm.

(Formation of Hole Injection Layer)

The base material forming the anode was ultrasonically washed by isopropyl alcohol, dried by a dry nitrogen gas, and cleaned with UV ozone for 5 min. Then, a 2 mass % (PEDOT/PSS) solution prepared by diluting a dispersing liquid of poly(3,4-ethylenedioxy thiophene)/polystyrene sulfonate (PEDOT/PSS) thus prepared the same as in Example 16 of Japanese Patent Publication No. 4509787 was applied onto the base material thus forming the anode via a die coating method. The resulting base material was dried at 80° C. for 5 min to form a hole injection layer with a thickness of 40 nm.

(Formation of Hole Transport Layer)

Next, the base material forming the hole injection layer was placed under the nitrogen atmosphere using nitrogen gas (Grade G1), and applied with a coating liquid for forming a hole transport layer having the following composition by an inkjet method. Then, the resultant base material was dried at 150° C. for 30 min to form a hole transport layer with a thickness of 30 nm.

(Coating Liquid for Forming Hole Transport Layer)
Hole transport material, HT-3 (weight average molecular weight Mw=80000): 10 parts by mass.
P-xylene: 3000 parts by mass

(Formation of Luminescent Layer)

Next, the base material thus forming the hole transport layer was applied with a coating liquid for forming luminescent layer with the following composition by an inkjet method. The resultant base material was dried at 130° C. for 30 min, thereby to form a luminescent layer with a thickness of 50 nm.

<Coating Liquid for Forming Luminescent Layer>

Host compound listed in Table 15: 9 parts by mass.

Dopant compound listed in Table 15: 1 part by mass.

n-butyl acetate: 2000 parts by mass.

(Formation of Electron Transport Layer)

Next, the base material thus forming a block layer was applied with a coating liquid for forming electron transport layer with the following composition by an inkjet method. The resultant base material was dried at 80° C. for 30 min, thereby to form an electron transport layer with a thickness of 30 nm.

<Coating Liquid for Forming Electron Transport Layer>

ET-1: 6 parts by mass.

1H, 1H, 3H-tetrafluoropropanol (TFPO): 2000 parts by mass.

(Formation of Electron Injection Layer and Cathode>

Next, the resulting base material was attached to the vacuum vapor deposition device without exposed to the air. Further, resistance heating boats both made of molybdenum respectively filled with sodium fluoride and potassium fluoride were attached to the vacuum vapor deposition device, and the vacuum vessel was decompressed down to 4×10⁻⁵ Pa. After that, one of the boats was heated by carrying a current, and sodium fluoride was vapor deposited on the electron transport layer at 0.02 nm/sec to form a thin film with a thickness of 1 nm. Similarly, potassium fluoride was vapor deposited on the sodium fluoride thin film at 0.02 nm/sec to form an electron injection layer with a thickness of 1.5 nm.

After that, aluminum was vapor deposited to form a cathode with a thickness of 100 nm.

(Sealing)

Next, a sealing base material was bonded to a layered body thus formed by the above process via using a commercially available roll laminator.

As a sealing base material, an adhesive layer with a thickness of 1.5 □m was provided on flexible aluminum foil with a thickness of 30 □m (TOYO ALUMINUM K.K.) via using a two-component reaction type urethane based adhesive for dry lamination. Hereby, a sealing base material laminated with a polyethylene terephthalate (PET) having a thickness of 12 □m was prepared.

As a sealing adhesive, a thermocuring adhesive was uniformly applied with a thickness of 20 □m to an adhesive surface (i.e., a glazed surface) of aluminum foil serving as a sealing base material using a dispenser. Further, the resultant material was transferred under a nitrogen atmosphere with an oxygen concentration of 0.8 ppm, at a dew-point temperature of −80° C. or less, and dried for 12 he or more so that a water content of the sealing adhesive was adjusted to 100 ppm or less.

As the thermocuring adhesive, used was an epoxy base adhesive prepared by mixed with the following (A)˜(C).

(A) Bisphenol A diglycidyl ether (DGEBA)

(B) Dicyandiamide (DICY)

(C) Epoxy adduct based curing promoter

The above sealing base material was closely attached to the layered body and arranged. Then, the material and the body was closely attached and sealed under the conditions of a pressure-bonding temperature of 100° C., a pressure of 0.5 Mpa and a device rate of 0.3 m/min via using a pressure roller. Hereby, a lighting apparatus for evaluation shown in FIG. 11 was prepared.

<<Evaluation of Continuous Driving Stability (Half-life) Continuous driving stability (i.e., a half-life) was evaluated by the same method as in Example 5.

Note, a “half-life: a relative value” was calculated as a relative rate per half-life of the lighting apparatus for evaluation 15-1 thus set to 1.

TABLE 15

| Device No. | Host No. | Dopant No. | Halflife | Note |
|---|---|---|---|---|
| 15-1 | BH-3 | BD-2 | 1 | Comparative Example |
| 15-2 | BH-3 | CD-2 | 0.8 | Comparative Example |
| 15-3 | BH-3 | CD-10 | 0.9 | Comparative Example |
| 15-4 | BH-3 | CD-16 | 1.1 | Comparative Example |
| 15-5 | BH-3 | CD-25 | 0.9 | Comparative Example |
| 15-6 | H-6 | BD-2 | 1 | Comparative Example |
| 15-7 | H-8 | BD-2 | 1.1 | Comparative Example |
| 15-8 | H-6 | CD-2 | 3.1 | Example |
| 15-9 | H-8 | CD-2 | 2.9 | Example |
| 15-10 | H-6 | CD-10 | 4.2 | Example |
| 15-11 | H-8 | CD-10 | 4 | Example |
| 15-12 | H-6 | CD-16 | 5 | Example |
| 15-13 | H-8 | CD-16 | 4.9 | Example |
| 15-14 | H-6 | CD-25 | 4.8 | Example |
| 15-15 | H-8 | CD-25 | 5.1 | Example |

<<Analysis of Results: Example 10>>

As shown in Table 15, in the lighting apparatuses for evaluation 15-8˜15-15, a core-shell type dopant satisfying the requirements of the present invention was used as a dopant, and a Forester type dopant was used as a host. As a result, it was confirmed that the lighting apparatuses for evaluation 15-8˜15-15 are excellent in continuous driving stability even in an element prepared by an inkjet process.

### DESCRIPTION OF REFERENCE NUMERALS

1: Display
3: Pixel
5: Scanning Line
6: Data Line
A: Display Unit
B: Control Unit
10: Core-Shell Type Dopant
11: Core Part
12: Shell Part
13: Quencher
14: Host
20: Typical Dopant
101: Organic EL Element
102: Glass Cover
105: Cathode
106: Organic EL Element
107: Glass Substrate provided with Transparent Electrode
108: Nitrogen gas
109: Moisture Catcher
201: Flexible Support Substrate
202: Anode
203: Hole Injection Layer
204: Hole Transport Layer
205: Luminescent Layer
206: Electron Transport Layer
207: Electron Injection Layer
208: Cathode
209: Sealing Adhesive
210: Flexible Sealing Member
200: Organic EL Element

1. A thin film containing a light-emitting metal complex and a host, wherein
the light-emitting metal complex is represented by the following General Formula (1) and satisfies the following Equation (1), and
the host is a non-metallic organic compound showing phosphorescence at room temperature, a compound showing thermally activated delayed fluorescence, or a compound expressing an inverse intersystem crossing phenomenon between a singlet excited state showing a level higher than a lowest singlet excited state and a triplet excited state showing a level higher than a lowest triplet excited state. 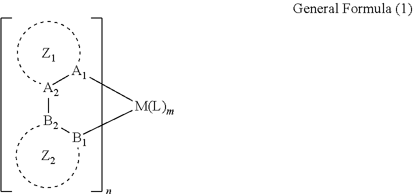
[In General Formula (1), M represents Ir or Pt; A₁, A₂, B₁, B₂ respectively represent a carbon atom or a nitrogen atom;
ring Z₁ represents a 6-membered aromatic hydrocarbon ring formed with A₁ and A₂, a 5- or a 6-membered aromatic heterocyclic ring formed with A₁ and A₂, or an aromatic fused ring including at least one of the aromatic hydrocarbon ring and the aromatic heterocyclic rings;
ring Z₂ is a 5- or a 6-membered aromatic heterocyclic ring formed with B₁ and B₂, or an aromatic fused ring including at least one of the aromatic heterocyclic rings;
one of a bond between A₁ and M and a bond between B₁ and M represents a coordinate bond, and the other is a covalent bond;
the ring Z₁ and the ring Z₂ may respectively have a substituent, but have at least one substituent represented by the following General Formula (2);
a fused ring structure may be formed by a substituent of the ring Z₁ and a substituent of the ring Z₂ being bound to each other, or ligands represented by the ring Z₁ and the ring Z₂ may be bound to each other;
L represents a monoanionic bidentate ligand coordinated with M, and may have a substituent;
m represents an integer from 0 to 2, and n represents an integer from 1 to 3; when M is Ir, m+n is 3; when M is Pt, m+n is 2; when m or n is 2 or more, L(s) or the ligands represented by the ring Z₁ and the ring Z₂ may be the same or different respectively; and
L and the ligand represented by the ring Z₁ and the ring Z₂ may be bound to each other.]
*-L′-(CR₂)_{n′}-A General Formula (2)
[In General Formula (2), * represents a binding position with the ring Z₁ or the ring Z₂ in General Formula (1); L′ represents a single bond or a linker; R represents a hydrogen atom or a substituent; n′ represents an integer of 3 or more; a plurality of R(s) may be the same or different; and A represents a hydrogen atom or a substituent.]
$$\frac{{V}_{all}}{{V}_{core}} > 2 \qquad Equation ( 1 )$$
[In Equation (1), Vₐn represents a molecular volume of a structure including substituents bound to the ring Z₁ and the ring Z₂, wherein it is assumed that n=3 and m=0 when M is Ir, and n=2 and m=0 when M is Pt; and V_{co}re represents a molecular volume of a structure where the substituents bound to the ring Z₁ and the ring Z₂ in the structure having the molecular volume of Vₐₗₗ are replaced by hydrogen atoms. Note, when there are a plurality of ligands represented by the ring Z₁ and the ring Z₂, Vₐₗₗ and V_{core} satisfy Equation (1) in all the cases represented by the above described assumption.]

2. A thin film containing a light-emitting metal complex and two kinds of hosts, wherein
the light-emitting metal complex is represented by the following General Formula (1) and satisfies Equation (1), and
the two kinds of hosts are combined to form an excited complex. 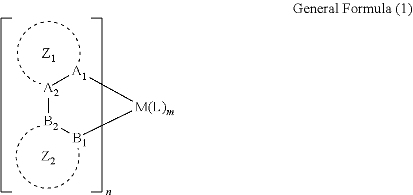
[In General Formula (1), M represents Ir or Pt; and A₁, A₂, B₁, B₂ respectively represent a carbon atom or a nitrogen atom;
ring Z₁ represents a 6-membered aromatic hydrocarbon ring formed with A₁ and A₂, a 5- or a 6-membered aromatic heterocyclic ring formed with A₁ and A₂, or an aromatic fused ring including at least one of the aromatic hydrocarbon ring and the aromatic heterocyclic rings;
one of a bond between A₁ and M and a bond between B₁ and M represents a coordinate bond, and the other is a covalent bond;
ring Z₁ and ring Z₂ may independently have a substituent, but have at least one substituent represented by the following General Formula (2);
a fused ring structure may be formed by a substituent of the ring Z₁ and a substituent of the ring Z₂ being bound to each other, or ligands represented by the ring Z₁ and the ring Z₂ may be bound to each other;
L represents a monoanionic bidentate ligand coordinated with M, and may have a substituent; m represents an integer from 0 to 2, and n represents an integer from 1 to 3; when M is Ir, m+n is 3; when M is Pt, m+n is 2; when m or n is 2 or more, L(s) or the ligands represented by the ring Z₁ and the ring Z₂ may be the same or different respectively; and L and the ligand represented by the ring Z₁ and the ring Z₂ may be bound to each other.]
*-L′-(CR₂)_{n′}-A General Formula (2)
[In General Formula (2), * represents a binding position on the ring Z₁ or the ring Z₂ in General Formula (1); L′ represents a single bond or a linker; R represents a hydrogen atom or a substituent; n′ represents an integer of 3 or more; a plurality of R(s) may be the same or different; and A represents a hydrogen atom or a substituent.]
$$\frac{{V}_{all}}{{V}_{core}} > 2 \qquad Equation ( 1 )$$
[In Equation (1), Vₐn represents a molecular volume of a structure including substituents bound to the ring Z₁ and the ring Z₂, wherein it is assumed that n=3 and m=0 when M is Ir, and n=2 and m=0 when M is Pt; and V_{co}re represents a molecular volume of a structure where the substituents bound to the ring Z₁ and the ring Z₂ in the structure having the molecular volume of Vₐₗₗ are replaced by hydrogen atoms. Note, when there are a plurality of ligands represented by the ring Z₁ and the ring Z₂, Vₐₗₗ and V_{core} satisfy Equation (1) in all the cases represented by the above described assumption.]

3. The thin film according to claim 1, wherein L′ in General Formula (2) is a non-covalent linker.

4. The thin film according to claim 1, wherein a ligand represented by the ring Z₁ and the ring Z₂ in General Formula (1) has 3 or more substituents.

5. A thin film containing a light-emitting metal complex and a host, wherein
the light-emitting metal complex is represented by any one of the following General Formulae (3)˜(5) and satisfies the following Equation (1); and
the host is a non-metallic organic compound showing phosphorescence at room temperature, a compound showing thermally activated delayed fluorescence, or a compound expressing an inverse intersystem crossing phenomenon between a singlet excited state showing a level higher than a lowest singlet excited state and a triplet excited state showing a level higher than a lowest triplet excited state. 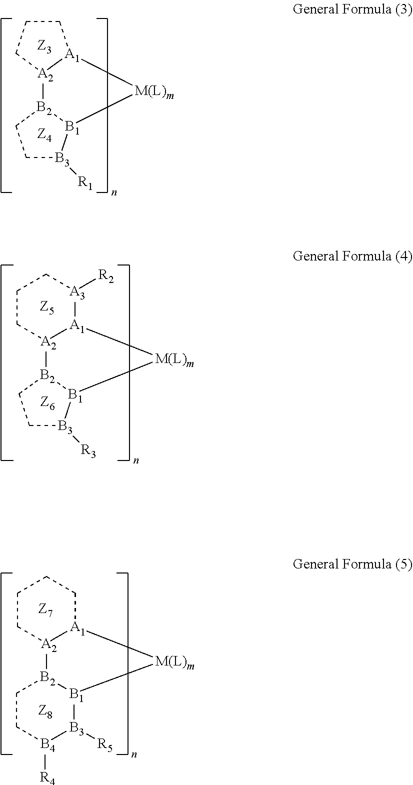
[In General Formulae (3)˜(5), M represents Ir or Pt; A₁˜A₃ and B₁˜B₄ respectively represent a carbon atom or a nitrogen atom;
one of a bond between A₁ and M and a bond between B₁ and M represents a coordinate bond, and the other is a covalent bond.
L represents a monoanionic bidentate ligand coordinated with M, and may have a substituent;
m represents an integer from 0 to 2, and n represents an integer from 1 to 3; when M is Ir, m+n is 3; when M is Pt, m+n is 2; when m or n is 2 or more, ligands represented by ring Z₃ and ring Z₄, ligands represented by ring Z₅ and ring Z₆, ligands represented by ring Z₇ and ring Z₈, or L(s) may be the same or different respectively, and L and those ligands may be bound to each other.
In General Formula (3), the ring Z₃ represents a 5-membered aromatic heterocyclic ring formed with A₁ and A₂, or an aromatic fused ring including the 5-membered aromatic heterocyclic ring;
the ring Z₄ represents a 5-membered aromatic heterocyclic ring formed with B₁˜B₃, or an aromatic fused ring including the 5-membered aromatic heterocyclic ring;
R₁ represents a substituent having 2 or more carbon atoms;
the ring Z₃ and the ring Z₄ may include a substituent besides R₁; and
a fused ring structure may be formed by a substituent of the ring Z₃ and a substituent of the ring Z₄ being bound to each other; and ligands represented by the ring Z₃ and the ring Z₄ may be bound to each other.
In General Formula (4), the ring Z₅ represents a 6-membered aromatic hydrocarbon ring formed with A₁˜A₃, a 6-membered aromatic heterocyclic ring formed with A₁˜A₃, or an aromatic fused ring including at least one of the 6-membered aromatic hydrocarbon and heterocyclic rings;
the ring Z₆ represents a 5-membered aromatic heterocyclic ring formed with B₁˜B₃, or an aromatic fused ring including the 5-membered aromatic heterocyclic ring;
R₂ and R₃ independently represent a hydrogen atom or a substituent, and at least either of R₂ or R₃ represents a substituent having 2 or more carbon atoms;
the ring Z₅ and the ring Z₆ may have a substituent besides R₂ and R₃; and
a fused ring structure may be formed by a substituent of the ring Z₅ and a substituent of the ring Z₆ being bound to each other, and ligands represented by the ring Z₅ and the ring Z₆ may be bound to each other.
In General Formula (5), the ring Z₇ represents a 6-membered aromatic hydrocarbon ring formed with A₁ and A₂, a 6-membered aromatic heterocyclic ring formed with A₁ and A₂, or an aromatic fused ring including at least one of the 6-membered aromatic hydrocarbon and heterocyclic rings;
the ring Z₈ represents a 6-membered aromatic hydrocarbon ring formed with B₁˜B₄, a 6-membered aromatic heterocyclic ring formed with B₁˜B₄, or an aromatic fused ring including the 6-membered aromatic hydrocarbon and heterocyclic rings;
R₄ and R₅ respectively represent a hydrogen atom or a substituent, and at least either of R₄ or R₅ represents a substituent having 2 or more carbon atoms;
the ring Z₇ and the ring Z₈ may include a substituent besides R₄ and R₅; and
a fused ring structure may be formed by a substituent of the ring Z₇ and a substituent of the ring Z₈ being bound to each other, and ligands represented by the ring Z₇ and the ring Z₈ may be bound to each other.
$$\frac{{V}_{all}}{{V}_{core}} > 2 \qquad Equation ( 1 )$$
[In Equation (1), Vₐₗₗ represents a molecular volume of a structure including substituents bound to the rings Z₃˜Z₈, wherein it is assumed that n=3 and m=0 when M is Ir, and n=2 and m=0 when M is Pt; and V_{core} represents a molecular volume of a structure where the substituents bound to the rings Z₃˜Z₈ in the structure having the molecular volume of Vₐₗₗ are replaced by hydrogen atoms; Note, when there are a plurality of ligands represented by the ring Z₃ and the ring Z₄, represented by the ring Z₅ and the ring Z₆, and represented by the ring Z₇ and the ring Z₈, Vₐₗₗ and V_{core} satisfy Equation (1) in all the cases represented by the above described assumption.]

6. A thin film containing a light-emitting metal complex and two kinds of hosts, wherein
the light-emitting metal complex is represented by any one of the following General Formulae (3)˜(5) and satisfies the following Equation (1), and
the two kinds of hosts are combined to form an excited complex. 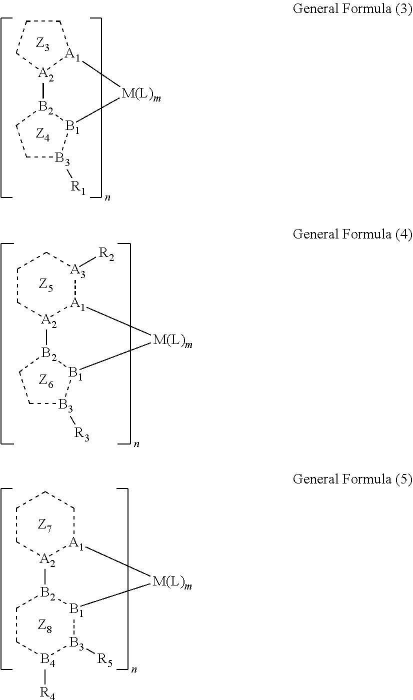
[In General Formulae (3)˜(5), M represents Ir or Pt; A₁˜A₃ and B₁˜B₄ respectively represent a carbon atom or a nitrogen atom;
one of a bond between A₁ and M and a bond between B₁ and M represents a coordinate bond, and the other represents a covalent bond;
L represents a monoanionic bidentate ligand coordinated with M, and may have a substituent; and
m represents an integer from 0 to 2, and n represents an integer from 1 to 3; when M is Ir, m+n is 3; when M is Pt, m+n is 2; when m or n is 2 or more, a ligand represented by ring Z₃ and ring Z₄, a ligand represented by ring Z₅ and ring Z₆, a ligand represented by ring Z₇ and ring Z₈, or L(s) may be the same or different respectively; and L and those ligands may be bound each other.
In General Formula (3), the ring Z₃ represents a 5-membered aromatic heterocyclic ring formed with A₁ and A₂, or an aromatic fused ring including the 5-membered aromatic heterocyclic ring;
the ring Z₄ represents a 5-membered aromatic heterocyclic ring formed with B₁˜B₃, or an aromatic fused ring including the 5-membered aromatic heterocyclic ring;
R₁ represents a substituent having 2 or more carbon atoms;
the ring Z₃ and the ring Z₄ may include a substituent besides R₁;
a fused ring structure may be formed by a substituent of the ring Z₅ and a substituent of the ring Z₆ being bound each other; and ligands represented by the ring Z₅ and the ring Z₆ may be bound to each other;
In General Formula (5), the ring Z₇ represents a 6-membered aromatic hydrocarbon ring formed with A₁ and A₂, a 6-membered aromatic heterocyclic ring formed with A₁ and A₂, or an aromatic fused ring including at least one of the 6-membered aromatic hydrocarbon and heterocyclic rings;
the ring Z₈ represents a 6-membered aromatic hydrocarbon ring formed with B₁˜B₄, a 6-membered aromatic heterocyclic ring formed with B₁˜B₄, or an aromatic fused ring including the 6-membered aromatic hydrocarbon and heterocyclic rings;
R₄ and R₅ respectively represent a hydrogen atom or a substituent, and at least either of R₄ or R₅ represents a substituent having 2 or more carbon atoms;
the ring Z₇ and the ring Z₈ may include a substituent besides R₄ and R₅; and
a fused ring structure may be formed by a substituent of the ring Z₇ and a substituent of the ring Z₈ being bound to each other; and ligands represented by the ring Z₇ and the ring Z₈ may be bound to each other.
$$\frac{{V}_{all}}{{V}_{core}} > 2 \qquad Equation ( 1 )$$
[In Equation (1), Vₐₗₗ represents a molecular volume of a structure including substituents bound to the rings Z₃˜Z₈, wherein it is assumed that n=3 and m=0 when M is Ir, and n=2 and m=0 when M is Pt; V_{core} represents a molecular volume of a structure where the substituents bound to the rings Z₃˜Z₈ in the structure having the molecular volume of Vₐₗₗ are replaced by hydrogen atoms; Note, when there are a plurality of ligands represented by the ring Z₃ and the ring Z₄, represented by the ring Z₅ and the ring Z₆, and represented by the ring Z₇ and the ring Z₈, Vₐₗₗ and V_{core} satisfy Equation (1) in all the cases represented by the above described assumption.]

7. The thin film according to claim 6, wherein a ligand represented by the ring Z₃ and the ring Z₄ in General Formula (3), a ligand represented by the ring Z₅ and the ring Z₆ in General Formula (4), or a ligand represented by the ring Z₇ and the ring Z₈ in General Formula (5) has 3 or more substituents.

8. An organic electroluminescent element comprising at least one luminescent layer between an anode and a cathode, wherein the organic electroluminescent element comprises a thin film claimed in claim 1.

9. The organic electroluminescent element according to claim 8, wherein the luminescent layer is a single layer consisting of the thin film.

10. The thin film according to claim 2, wherein L′ in General Formula (2) is a non-covalent linker.

11. The thin film according to claim 2, wherein a ligand represented by the ring Z1 and the ring Z2 in General Formula (1) has 3 or more substituents.

12. The thin film according to claim 6, wherein a ligand represented by the ring Z3 and the ring Z4 in General Formula (3), a ligand represented by the ring Z5 and the ring Z6 in General Formula (4), or a ligand represented by the ring Z7 and the ring Z8 in General Formula (5) has 3 or more substituents.

13. An organic electroluminescent element comprising at least one luminescent layer between an anode and a cathode, wherein the organic electroluminescent element comprises a thin film as claimed in claim 2.

14. An organic electroluminescent element comprising at least one luminescent layer between an anode and a cathode, wherein the organic electroluminescent element comprises a thin film as claimed in claim 5.

15. An organic electroluminescent element comprising at least one luminescent layer between an anode and a cathode, wherein the organic electroluminescent element comprises a thin film as claimed in claim 6.

16. The organic electroluminescent element according to claim 13, wherein the luminescent layer is a single layer consisting of the thin film.

17. The organic electroluminescent element according to claim 14, wherein the luminescent layer is a single layer consisting of the thin film.

18. The organic electroluminescent element according to claim 15, wherein the luminescent layer is a single layer consisting of the thin film.
